(19) United States
(12) Patent Application Publication
(10) Pub. No.: US 2024/0381702 A1
(43) Pub. Date: Nov. 14, 2024

(54) DISPLAY APPARATUS

(71) Applicant: SEMICONDUCTOR ENERGY LABORATORY CO., LTD., Atsugi-shi, Kanagawa-ken (JP)

(72) Inventors: Koji KUSUNOKI, Isehara, Kanagawa (JP); Daisuke KUBOTA, Atsugi, Kanagawa (JP); Kensuke YOSHIZUMI, Atsugi, Kanagawa (JP); Junpei SUGAO, Isehara, Kanagawa (JP)

(21) Appl. No.: 18/690,383

(22) PCT Filed: Sep. 8, 2022
(86) PCT No.: PCT/IB2022/058444

§ 371 Date: Mar. 8, 2024

(30) Foreign Application Priority Data
Sep. 24, 2021 (JP) 2021-155060

(51) Int. Cl. H10K 59/122; H10K 59/35

(52) U.S. Cl. CPC H10K 59/122; H10K 59/353

(57) ABSTRACT

A display apparatus with a high aperture ratio is provided. The display apparatus includes first and second light-emitting devices, a first conductive layer, a second conductive layer, and a first insulating layer. The first light-emitting device includes a first pixel electrode, a first EL layer, and a common electrode over the first EL layer. The second light-emitting device includes a second pixel electrode, a second EL layer, and the common electrode over the second EL layer. The first conductive layer is provided over the common electrode. The first insulating layer is provided over the first conductive layer. The second conductive layer is provided over the first insulating layer. Any one or both of the first and second conductive layers overlap with a region interposed between the first EL layer and the second EL layer. One side surface of the first EL layer and one side surface of the second EL layer are provided to face each other. The first light-emitting device emits light of a color that is different from a color of light emitted from the second-light-emitting device. The first EL layer includes a first light-emitting unit, a first charge-generation layer, and a second light-emitting unit. The second EL layer includes a third light-emitting unit, a second charge-generation layer, and a fourth light-emitting unit.

### TECHNICAL FIELD

One embodiment of the present invention relates to a display apparatus. One embodiment of the present invention relates to an electronic device.

Note that one embodiment of the present invention is not limited to the above technical field. Examples of a technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, higher-resolution display panels have been required. Examples of devices that require high-resolution display panels include a smartphone, a tablet terminal, and a notebook computer. Furthermore, higher resolution has been required for a stationary display apparatus such as a television device or a monitor device along with an increase in definition. An example of a device required to have the highest resolution is a device for virtual reality (VR) or augmented reality (AR).

Examples of a display apparatus that can be used for a display panel include, typically, a liquid crystal display apparatus, a light-emitting apparatus provided with a light-emitting element such as an organic EL (Electro Luminescence) element or a light-emitting diode (LED), and electronic paper performing display by an electrophoretic method or the like.

For example, the basic structure of an organic EL element is a structure where a layer containing a light-emitting organic compound is provided between a pair of electrodes. By voltage application to this element, light emission can be obtained from the light-emitting organic compound. A display apparatus containing such an organic EL element does not need a backlight that is necessary for a liquid crystal display apparatus and the like; thus, a thin, lightweight, high-contrast, and low-power-consumption display apparatus can be achieved. Patent Document 1, for example, discloses an example of a display apparatus containing an organic EL element.

### REFERENCE

### Patent Document

[Patent Document 1] Japanese Published Patent Application No. 2002-324673

### SUMMARY OF THE INVENTION

### Problems to be Solved by the Invention

An object of one embodiment of the present invention is to provide a display apparatus with a high aperture ratio. Another object of one embodiment of the present invention is to provide a display apparatus with high display quality. Another object of one embodiment of the present invention is to provide a highly reliable display apparatus. Another object of one embodiment of the present invention is to provide a display apparatus that can easily achieve a higher resolution. Another object of one embodiment of the present invention is to provide a display apparatus with low power consumption.

Another object of one embodiment of the present invention is to at least reduce at least one of problems of the conventional technique.

Note that the description of these objects does not preclude the existence of other objects. One embodiment of the present invention does not have to achieve all of these objects. Note that objects other than these can be derived from the description of the specification, the drawings, the claims, and the like.

### Means for Solving the Problems

One embodiment of the present invention is a display apparatus including a first light-emitting device, a second light-emitting device provided to be adjacent to the first light-emitting device, a first conductive layer, a second conductive layer, and a first insulating layer. The first light-emitting device includes a first pixel electrode, a first EL layer over the first pixel electrode, and a common electrode over the first EL layer. The second light-emitting device includes a second pixel electrode, a second EL layer over the second pixel electrode, and the common electrode over the second EL layer. The first conductive layer is provided over the common electrode. The first insulating layer is provided over the first conductive layer. The second conductive layer is provided over the first insulating layer. Any one or both of the first conductive layer and the second conductive layer overlap with a region interposed between the first EL layer and the second EL layer. One side surface of the first EL layer and one side surface of the second EL layer are provided to face each other. The first light-emitting device emits light a color that is different from a color of light emitted from the second light-emitting device. The first EL layer includes a first light-emitting unit over the first pixel electrode, a first charge-generation layer over the first light-emitting unit, and a second light-emitting unit over the first charge-generation layer. The second EL layer includes a third light-emitting unit over the second pixel electrode, a second charge-generation layer over the third light-emitting unit, and a fourth light-emitting unit over the second charge-generation layer.

In the above, preferably, the display apparatus includes a second insulating layer and a third insulating layer over the second insulating layer; the second insulating layer contains an inorganic material; the third insulating layer contains an organic material; part of the second insulating layer and part of the third insulating layer are provided at a position interposed between an end portion of a side surface of the first EL layer and an end portion of a side surface of the second EL layer; and another part of the third insulating layer overlaps with part of a top surface of the first EL layer and part of a top surface of the second EL layer with the second insulating layer therebetween.

In the above, any one or both of the first conductive layer and the second conductive layer preferably include a region overlapping with the third insulating layer.

In the above, a side surface of the first conductive layer and a side surface of the second conductive layer are each preferably positioned inward from an end portion of the third insulating layer in a cross-sectional view.

In the above, the common electrode is preferably provided over the third insulating layer.

In the above, preferably, the display apparatus includes a first substrate and a second substrate; the first light-emitting device and the second light-emitting device are provided over the first substrate; and the second substrate is bonded to a plane of the first substrate where the first insulating layer and the second conductive layer are provided with an adhesive layer therebetween.

In the above, preferably, the first light-emitting device includes a common layer provided between the first EL layer and the common electrode, and the second light-emitting device includes the common layer provided between the second EL layer and the common electrode.

In the above, preferably, a distance between the first pixel electrode and the second pixel electrode is less than or equal to 8 μm.

In the above, preferably, the display apparatus includes a first coloring layer provided to overlap with the first light-emitting device and a second coloring layer provided to overlap with the second light-emitting device, the first coloring layer transmits at least part of light in a wavelength range emitted from the first light-emitting device, and the second coloring layer transmits at least part of light in a wavelength range emitted from the second light-emitting device.

In the above, the first coloring layer and the second coloring layer are each preferably provided between the common electrode and the first insulating layer.

### Effect of the Invention

According to one embodiment of the present invention, a display apparatus with a high aperture ratio can be provided. A display apparatus with high display quality can be provided. A highly reliable display apparatus can be provided. A display apparatus that can easily achieve a higher resolution can be provided. A display apparatus with low power consumption can be provided. At least one of problems of the conventional technique can be at least reduced.

Note that the description of these effects does not preclude the existence of other effects. One embodiment of the present invention does not need to have all of these effects. Note that effects other than these can be derived from the description of the specification, the drawings, the claims, and the like.

### BRIEF DESCRIPTION OF THE DRAWINGS

FIG. 1A is a top view illustrating an example of a display apparatus. FIG. 1B is a cross-sectional view illustrating an example of the display apparatus.

FIG. 2A and FIG. 2B are enlarged cross-sectional views illustrating examples of a display apparatus.

FIG. 3A to FIG. 3C are cross-sectional views illustrating examples of a display apparatus.

FIG. 4A and FIG. 4B are cross-sectional views illustrating examples of a display apparatus.

FIG. 5A and FIG. 5B are cross-sectional views illustrating examples of a display apparatus.

FIG. 6A to FIG. 6C are cross-sectional views illustrating examples of a display apparatus.

FIG. 7A and FIG. 7B are cross-sectional views illustrating examples of a display apparatus.

FIG. 8A to FIG. 8C are cross-sectional views illustrating examples of a display apparatus.

FIG. 9A to FIG. 9C are cross-sectional views illustrating examples of a display apparatus.

FIG. 10A to FIG. 10F are cross-sectional views illustrating examples of a display apparatus.

FIG. 11A and FIG. 11B are cross-sectional views illustrating examples of a display apparatus.

FIG. 12A and FIG. 12B are cross-sectional views illustrating examples of a display apparatus.

FIG. 13A to FIG. 13G are top views illustrating examples of pixels.

FIG. 14A to FIG. 14I are top views illustrating examples a pixel.

FIG. 15A to FIG. 15K are top views illustrating examples of pixels.

FIG. 16A to FIG. 16C are diagrams illustrating structure examples of a touch sensor.

FIG. 17 is a diagram illustrating a structure example of a touch sensor and a pixel.

FIG. 18A and FIG. 18B are diagrams illustrating structure examples of a touch sensor and a pixel.

FIG. 19 is a diagram illustrating a structure example of a touch sensor and a pixel.

FIG. 20 is a diagram illustrating a structure example of a touch sensor and a pixel.

FIG. 21 is a perspective view illustrating an example of a display apparatus.

FIG. 22A to FIG. 22C are cross-sectional views illustrating examples of a display apparatus.

FIG. 23A and FIG. 23B are cross-sectional views illustrating an example of a display apparatus.

FIG. 24A and FIG. 24B are cross-sectional views illustrating examples of transistors. FIG. 24C to FIG. 24E are cross-sectional views illustrating examples of a display apparatus.

FIG. 25A is a block diagram illustrating an example of a display apparatus. FIG. 25B to FIG. 25E are circuit diagrams illustrating examples of a pixel.

FIG. 26A to FIG. 26D are diagrams illustrating examples of transistors.

FIG. 27A to FIG. 27D are diagrams illustrating examples of an electronic device.

FIG. 28A to FIG. 28D are diagrams illustrating examples of electronic devices.

FIG. 29A to FIG. 29G are diagrams illustrating examples of electronic devices.

FIG. 30A1 to FIG. 30B3 are cross-sectional views illustrating examples of a sensor module.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same reference numerals are commonly used for the same portions or portions having similar functions in different drawings, and a repeated description thereof is omitted. Furthermore, the same hatch pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that ordinal numbers such as “first” and “second” in this specification and the like are used in order to avoid confusion among components and do not limit the number of components.

In this specification and the like, a display apparatus may be rephrased as an electronic device.

In this specification and the like, a device manufactured using a metal mask or an FMM (a fine metal mask or a high-resolution metal mask) is sometimes referred to as a device having an MM (metal mask) structure. In this specification and the like, a device manufactured without using a metal mask or an FMM is sometimes referred to as a device having an MML (metal maskless) structure.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that in some cases, the above-described carrier-injection layer, carrier-transport layer, and carrier-blocking layer cannot be distinguished from one another on the basis of the cross-sectional shape, properties, or the like. Furthermore, one layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Examples of the layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

### Embodiment 1

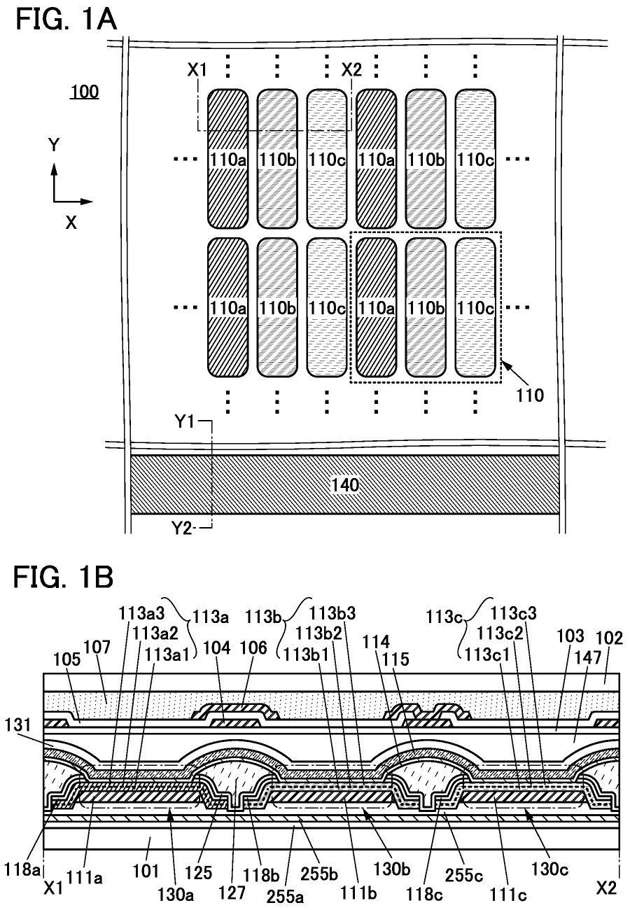

In this embodiment, a display apparatus of one embodiment of the present invention is described with reference to FIG. 1 to FIG. 10.

One embodiment of the present invention is a display apparatus that includes a display portion capable of full-color display. The display portion includes a first subpixel and a second subpixel that emit light of different colors. The first subpixel includes a first light-emitting device that emits blue light and the second subpixel includes a second light-emitting device that emits light of a color different from the color of light emitted by the first light-emitting device. At least one kind of material is different between the first light-emitting device and the second light-emitting device; for example, the light-emitting devices contain different light-emitting materials. That is, light-emitting devices separately formed for different emission colors are used in the display apparatus of one embodiment of the present invention.

In the display apparatus of one embodiment of the present invention, a light-emitting device with a tandem structure (a structure including a plurality of light-emitting units) is used. Each light-emitting unit includes at least one light-emitting layer. Each light-emitting unit may include one or more of a hole-injection layer, a hole-transport layer, a hole-blocking layer, an electron-blocking layer, an electron-transport layer, and an electron-injection layer. A charge-generation layer (also referred to as an intermediate layer) is preferably provided between the light-emitting units.

A structure in which light-emitting layers in light-emitting devices of different emission wavelengths (e.g., blue (B), green (G), and red (R)) are separately formed or separately patterned is sometimes referred to as an SBS (Side By Side) structure. The SBS structure allows optimization of materials and structures of light-emitting devices and thus can extend freedom of choice of the materials and the structures, which makes it easy to improve the luminance and the reliability.

In the case of manufacturing a display apparatus that includes a plurality of light-emitting devices with different emission colors, the light-emitting layers with different emission colors each need to be formed into an island shape. Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

For example, an island-shaped light-emitting layer can be formed by a vacuum evaporation method using a metal mask (also referred to as a shadow mask). However, this method causes a deviation from the designed shape and position of an island-shaped light-emitting layer due to various influences such as the accuracy of the metal mask, the positional deviation between the metal mask and a substrate, a warp of the metal mask, and the vapor-scattering-induced expansion of outline of the formed film; accordingly, it is difficult to achieve high resolution and a high aperture ratio of the display apparatus. In addition, the outline of the layer may blur during vapor deposition, whereby the thickness of an end portion may be reduced. That is, the thickness of the island-shaped light-emitting layer may vary from area to area. In the case of manufacturing a display apparatus with a large size, high definition, or high resolution, the manufacturing yield might be reduced because of low dimensional accuracy of the metal mask and deformation due to heat or the like.

In a method for manufacturing a display apparatus of one embodiment of the present invention, a first layer (also referred to as an EL layer or part of an EL layer) including a light-emitting layer emitting light of a first color is formed over the entire surface, and then a first mask layer is formed over the first layer. Then, a first resist mask is formed over the first mask layer and the first layer and the first mask layer are processed using the first resist mask, so that the first layer is formed into an island shape. Next, in a manner similar to that for the first layer, a second layer (also referred to as an EL layer or part of an EL layer) including a light-emitting layer emitting light of a second color is formed into an island shape using a second mask layer and a second resist mask. Note that in this specification and the like, a mask layer may be referred to as a sacrificial layer.

Note that in this specification and the like, each mask layer is positioned above at least a light-emitting layer (specifically, a layer processed into an island shape among layers included in an EL layer) and has a function of protecting the light-emitting layer in the manufacturing process. The mask layer may be removed in the manufacturing process or at least part of the mask layer may remain.

In the case of processing the light-emitting layer into an island shape, a conceivable structure is such that the light-emitting layer is processed by performing a photolithography method directly on the light-emitting layer. In the case of this structure, damage to the light-emitting layer (damage or the like caused by processing (e.g., etching process) might significantly degrade the reliability. In view of the above, in the manufacture of the display apparatus of one embodiment of the present invention, a mask layer or the like is preferably formed over a functional layer positioned above the light-emitting layer (e.g., a carrier-blocking layer, a carrier-transport layer, or a carrier-injection layer, specifically, a hole-blocking layer, an electron-transport layer, or an electron-injection layer), followed by the processing of the light-emitting layer into an island shape. Such a method can provide a highly reliable display apparatus.

As described above, the island-shaped EL layers manufactured in the method for manufacturing a display apparatus of one embodiment of the present invention are formed not by using a metal mask having a fine pattern but by processing an EL layer formed over the entire surface. Accordingly, a high-resolution display apparatus or a display apparatus with a high aperture ratio, which has been difficult to achieve, can be achieved. Moreover, EL layers of different colors can be formed separately, which enables the display apparatus to perform extremely clear display with high contrast and high display quality. In addition, a mask layer provided over an EL layer can reduce damage to the EL layer in the manufacturing process of the display apparatus, increasing the reliability of the light-emitting device.

It is difficult to reduce the distance between adjacent light-emitting devices to less than 10 μm with a formation method using a fine metal mask, for example. However, the method using a photolithography method of one embodiment of the present invention can shorten the distance between adjacent light-emitting devices, the distance between adjacent EL layers, or the distance between adjacent pixel electrodes to less than 10 μm, less than or equal to 8 μm, less than or equal to 5 μm, less than or equal to 3 μm, less than or equal to 2 μm, less than or equal to 1.5 μm, less than or equal to 1 μm, or even less than or equal to 0.5 μm, for example, in a process over a glass substrate. Using a light exposure apparatus for LSI can further shorten the distance between adjacent light-emitting devices, the distance between adjacent EL layers, or the distance between adjacent pixel electrodes to less than or equal to 500 nm, less than or equal to 200 nm, less than or equal to 100 nm, or even less than or equal to 50 nm, for example, in a process over a Si wafer. Accordingly, the area of a non-light-emitting region that could exist between two light-emitting devices can be significantly reduced, and the aperture ratio can be close to 100%. For example, the aperture ratio of the display apparatus of one embodiment of the present invention is higher than or equal to 40%, higher than or equal to 50%, higher than or equal to 60%, higher than or equal to 70%, higher than or equal to 80%, or higher than or equal to 90%; that is, an aperture ratio lower than 100% can be achieved.

Increasing the aperture ratio of the display apparatus can improve the reliability of the display apparatus. More specifically, with reference to the lifetime of a display apparatus including a light-emitting device and having an aperture ratio of 10%, a display apparatus having an aperture ratio of 20% (that is, two times the aperture ratio of the reference) has a lifetime approximately 3.25 times as long as that of the reference, and a display apparatus having an aperture ratio of 40% (that is, four times the aperture ratio of the reference) has a lifetime approximately 10.6 times as long as that of the reference. Thus, the density of current flowing to the light-emitting device can be reduced with increasing aperture ratio, and accordingly the lifetime of the display apparatus can be increased. The display apparatus of one embodiment of the present invention can have a higher aperture ratio and thus the display apparatus can have higher display quality. Furthermore, an excellent effect that the reliability (especially the lifetime) of the display apparatus is significantly improved with increasing aperture ratio of the display apparatus can be produced.

In the case where the light-emitting layer is processed into an island shape, a layer positioned below the light-emitting layer (e.g., a carrier-injection layer or a carrier-transport layer, more specifically, a hole-injection layer, a hole-transport layer, or the like) is preferably processed into an island shape with the same pattern as the light-emitting layer. When the layer positioned below the light-emitting layer is processed into an island shape with the same pattern as the light-emitting layer, leakage current that would be generated between adjacent subpixels (sometimes referred to as horizontal-direction leakage current, horizontal leakage current, or lateral leakage current) can be reduced. For example, in the case where a hole-injection layer is shared by adjacent subpixels, horizontal leakage current would be generated because of the hole-injection layer. In contrast, in the display apparatus of one embodiment of the present invention, the hole-injection layer can be processed into an island shape with the same pattern as the light-emitting layer; hence, horizontal leakage current between adjacent subpixels is not substantially generated or horizontal leakage current can be extremely small.

Furthermore, a pattern of the EL layer itself (also referred to as a processing size) can be made much smaller than that in the case of using a metal mask. For example, in the case of using a metal mask for forming EL layers separately, a variation in the thickness occurs between the center and the edge of the EL layer, which causes a reduction in an effective area that can be used as a light-emitting region with respect to the area of the EL layer. In contrast, in the above manufacturing method, a film formed to have a uniform thickness is processed, so that island-shaped EL layers can be formed to have a uniform thickness. Accordingly, even in a fine pattern, almost the whole area can be used as a light-emitting region. Consequently, a display apparatus having both high resolution and a high aperture ratio can be manufactured.

In addition, in a method for manufacturing a display apparatus of one embodiment of the present invention, it is preferable that a layer including a light-emitting layer (that can be referred to as an EL layer or part of an EL layer) be formed over the entire surface, and then a mask layer be formed over the EL layer. Next, preferably, a resist mask is formed over the mask layer, and the EL layer and the mask layer are processed using the resist mask, whereby an island-shaped EL layer is formed.

Provision of a mask layer over an EL layer can reduce damage to the EL layer in the manufacturing process of the display apparatus and increase the reliability of the light-emitting device.

Each of the first layer and the second layer described above includes at least a light-emitting layer and preferably is composed of a plurality of layers. Specifically, each of the first layer and the second layer preferably includes one or more layers over the light-emitting layer. A layer between the light-emitting layer and the mask layer can inhibit the light-emitting layer from being exposed on the outermost surface in the manufacturing process of the display apparatus and can reduce damage to the light-emitting layer. Thus, the reliability of the light-emitting device can be increased. Thus, each of the first layer and the second layer preferably includes the light-emitting layer and a carrier-blocking layer (a hole-blocking layer or an electron-blocking layer) over the light-emitting layer or a carrier-transport layer (an electron-transport layer or a hole-transport layer).

Note that it is not necessary to form all layers included in the EL layers separately for the respective light-emitting devices emitting light of different colors, and some layers can be formed in the same step. Here, examples of the layers included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In the method for manufacturing a display apparatus of one embodiment of the present invention, after some layers included in the EL layer are formed into an island shape separately for each color, the mask layer is removed at least partly; then, the other layers included in the EL layers and a common electrode (also referred to as an upper electrode) are each formed (as a single film) to be shared by the light-emitting devices of different colors. For example, a carrier-injection layer and a common electrode can be formed to be shared by the light-emitting devices of different colors.

Meanwhile, the carrier-injection layer often has relatively high conductivity in the EL layer. Therefore, when the carrier-injection layer is in contact with a side surface of some layers of the EL layer formed into an island shape or a side surface of the pixel electrode, the light-emitting device might be short-circuited. Note that also in the case where the carrier-injection layer is provided in an island shape and the common electrode is formed to be shared by the light-emitting devices of different colors, the light-emitting device might be short-circuited when the common electrode is in contact with the side surface of the EL layer or the side surface of the pixel electrode.

In view of the above, the display apparatus of one embodiment of the present invention includes an insulating layer covering at least a side surface of an island-shaped light-emitting layer. Note that the side surface of the island-shaped light-emitting layer here refers to the plane that is not parallel to the substrate (or the surface where the light-emitting layer is formed) among the interfaces between the island-shaped light-emitting layer and other layers. The side surface is not necessarily one of a flat plane or a curved plane in an exactly mathematical perspective.

This can inhibit at least some layers in the EL layer formed in an island shape and the pixel electrode from being in contact with the carrier-injection layer or the common electrode. Hence, a short circuit of the light-emitting device is inhibited, and the reliability of the light-emitting device can be increased.

The insulating layer preferably has a function of a barrier insulating layer against at least one of water and oxygen. Alternatively, the insulating layer preferably has a function of inhibiting diffusion of at least one of water and oxygen. Alternatively, the insulating layer preferably has a function of capturing or fixing (also referred to as gettering) at least one of water and oxygen.

Note that in this specification and the like, a barrier insulating layer refers to an insulating layer having a barrier property. A barrier property in this specification and the like refers to a function of inhibiting diffusion of a particular substance (also referred to as having low permeability). Alternatively, a barrier property refers to a function of capturing or fixing (also referred to as gettering) a particular substance.

With the use of an insulating layer having a function of the barrier insulating layer or a gettering function, entry of impurities (typically, at least one of water and oxygen) that might diffuse into the light-emitting devices from the outside can be inhibited. With this structure, a highly reliable light-emitting device and a highly reliable display apparatus can be provided.

The display apparatus of one embodiment of the present invention includes a pixel electrode, a first light-emitting unit over the pixel electrode, a charge-generation layer over the first light-emitting unit, a second light-emitting unit over the charge-generation layer, an insulating layer provided to cover side surfaces of the first light-emitting unit, the charge-generation layer, and the second light-emitting unit, and a common electrode provided over the second light-emitting unit. Note that a layer common to light-emitting devices of different colors may be provided between the second light-emitting unit and the common electrode.

The hole-injection layer, the electron-injection layer, and the charge-generation layer, for example, often have relatively high conductivity in the EL layer. Since the side surfaces of these layers are covered with the insulating layer in the display apparatus of one embodiment of the present invention, these layers can be inhibited from being in contact with the common electrode or the like. Consequently, a short circuit of the light-emitting device can be inhibited, and the reliability of the light-emitting device can be increased.

The insulating layer covering the side surface of the island-shaped EL layer may have a single-layer structure or a stacked-layer structure.

When an insulating layer is formed to have a single-layer structure using an inorganic material, for example, the insulating layer can be used as a protective insulating layer for the EL layer. This can increase the reliability of the display apparatus.

In the case where an insulating layer having a stacked-layer structure is used, a first layer of the insulating layer is preferably formed using an inorganic insulating material because it is formed in contact with the EL layer. In particular, the first layer is preferably formed by an atomic layer deposition (ALD) method, which causes less deposition damage. Alternatively, an inorganic insulating layer is preferably formed by a sputtering method, a chemical vapor deposition (CVD) method, or a plasma-enhanced chemical vapor deposition (PECVD: Plasma Enhanced CVD) method, which has higher deposition rate than an ALD method. In this case, a highly reliable display apparatus can be manufactured with high productivity. A second layer of the insulating layer is preferably formed using an organic material to fill a depressed portion formed in the first layer of the insulating layer.

For example, an aluminum oxide film formed by an ALD method can be used as the first layer of the insulating layer, and an organic resin film can be used as the second layer of the insulating layer.

In the case where the side surface of the EL layer and the organic resin film are in direct contact with each other, the EL layer might be damaged by an organic solvent or the like that might be contained in the organic resin film. The use of an inorganic insulating film such as an aluminum oxide film formed by an ALD method as the first layer of the insulating layer enables a structure where the organic resin film and the side surface of the EL layer are not in direct contact with each other. Thus, the EL layer can be inhibited from being dissolved by the organic solvent, for example.

The display apparatus of one embodiment of the present invention includes a touch sensor that obtains the positional data of an object that touches or approaches a display surface. A touch sensor of any of various types such as a resistive type, a capacitive type, an infrared ray type, an electromagnetic induction type, and a surface acoustic wave type can be used as the touch sensor. As the touch sensor, a capacitive touch sensor is particularly preferably used.

Examples of the capacitive touch sensor include a surface capacitive touch sensor and a projected capacitive touch sensor. Examples of the projected capacitive type include a self-capacitive type and a mutual capacitive type. The use of a mutual capacitive type is preferable because multiple points can be sensed simultaneously.

A mutual capacitive touch sensor can have a structure where a plurality of electrodes to which pulse potentials are supplied and a plurality of electrodes to which a sensing circuit is connected are included. The touch sensor can sense the approach of a finger or the like using a change in capacitance between the electrodes. The electrodes included in the touch sensor are preferably provided closer to the display surface side than the light-emitting device.

At least part of the electrode of the touch sensor overlaps with a region interposed between two adjacent light-emitting devices or a region interposed between two adjacent EL layers. Furthermore, at least part of the electrode of the touch sensor preferably includes a region overlapping with the organic resin film provided between two adjacent EL layers. With such a structure, a touch sensor can be provided above the display apparatus without a reduction in the light-emitting area of the light-emitting device. Thus, a display apparatus having both a high aperture ratio and a high resolution can be provided.

Here, a metal or an alloy material is preferably used for a conductive layer functioning as the electrode of the touch sensor. When the electrode of the touch sensor is provided as described above, a metal or an alloy material that does not have a light-transmitting property can be used for the electrode of the touch sensor without a reduction in the aperture ratio of the display apparatus. When a metal or an alloy material with low resistivity is used for the electrode of the touch sensor, touch sensing with high sensitivity can be achieved.

Note that a light-transmitting electrode that transmits light emitted from the light-emitting device can be used as the electrode of the touch sensor. In that case, the light-transmitting electrode can be provided to overlap with the light-emitting device.

The light-emitting device can be provided between a pair of substrates. As the substrate, a rigid substrate such as a glass substrate or a flexible film may be used. Here, the electrode of the touch sensor can be formed over the substrate positioned on the display surface side. Alternatively, the electrode of the touch sensor may be formed over another substrate and bonded to the display surface side.

The electrode of the touch sensor is preferably provided between the pair of substrates. In that case, a structure can be employed where a protective layer that covers the light-emitting device is provided, and the electrode of the touch sensor is provided over the protective layer. Thus, the number of components can be reduced, whereby the manufacturing process can be simplified. In addition, such a structure is particularly suitable for the display apparatus that is used as a flexible display using a flexible film for a substrate because the thickness of the display apparatus can be small.

### [Structure Example 1 of Display Apparatus]

FIG. 1 to FIG. 10 illustrate a display apparatus of one embodiment of the present invention.

FIG. 1A is a top view of a display apparatus 100. The display apparatus 100 includes a display portion in which a plurality of pixels 110 are arranged, and a connection portion 140 outside the display portion. A plurality of subpixels are arranged in a matrix in the display portion. FIG. 1A illustrates subpixels arranged in two rows and six columns, which form pixels in two rows and two columns. The connection portion 140 can also be referred to as a cathode contact portion.

The pixel 110 illustrated in FIG. 1A employs stripe arrangement. The pixel 110 illustrated in FIG. 1A is composed of three subpixels 110a, 110b, and 110c. The subpixels 110a, 110b, and 110c include light-emitting devices that emit light of different colors. As the subpixels 110a, 110b, and 110c, subpixels of three colors of red (R), green (G), and blue (B) or subpixels of three colors of yellow (Y), cyan (C), and magenta (M) can be given, for example. The number of types of subpixels is not limited to three, and may be four or more. As four subpixels, subpixels of four colors of R, G, B, and white (W), subpixels of four colors of R, G, B, and Y, and four subpixels of R, G, B, and infrared light (IR) can be given, for example.

In this specification and the like, the row direction and the column direction are sometimes referred to as the X direction and the Y direction, respectively. The X direction and the Y direction intersect with each other and are, for example, orthogonal to each other (see FIG. 1A).

FIG. 1A illustrates an example where subpixels of different colors are arranged in the X direction and subpixels of the same color are arranged in the Y direction.

Although FIG. 1A illustrates an example where the connection portion 140 is positioned on the lower side of the display portion in the top view, one embodiment of the present invention is not particularly limited. The connection portion 140 only needs to be provided on at least one of the upper side, the right side, the left side, and the lower side of the display portion in the top view, and may be provided to surround the four sides of the display portion. The top surface shape of the connection portion 140 can be a belt-like shape, an L shape, a U shape, a frame-like shape, or the like. The number of the connection portions 140 can be one or more.

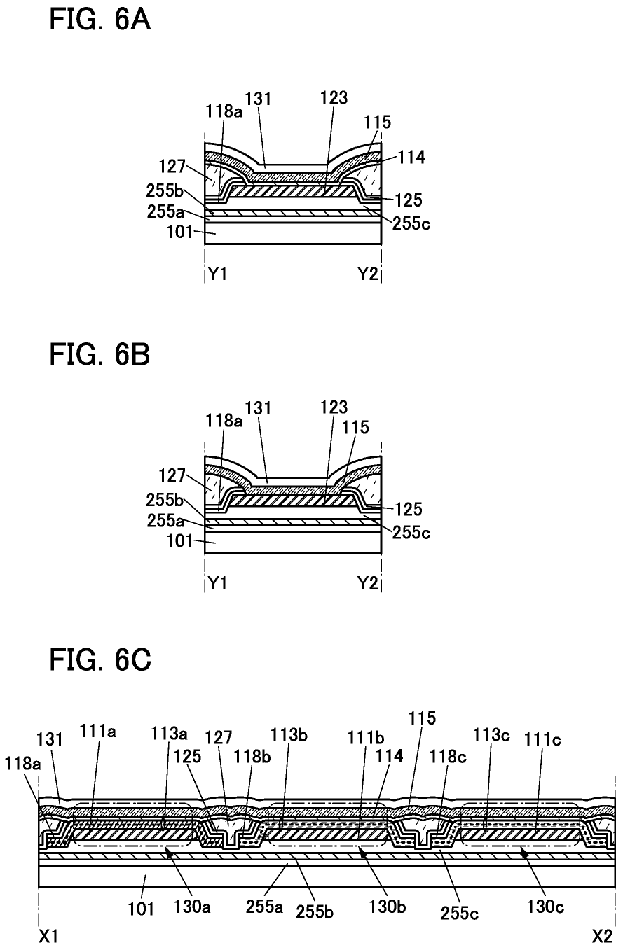

FIG. 1B and FIG. 6C each illustrate a cross-sectional view taken along the dashed-dotted line X1-X2 in FIG. 1A. In the display apparatus 100, a layer including a transistor is provided over a substrate 101, insulating layers 255a, 255b, and 255c are provided over the layer including the transistor, light-emitting devices 130a, 130b, and 130c are provided over the insulating layers 255a, 255b, and 255c, and a protective layer 131 is provided to cover these light-emitting devices. In a region between adjacent light-emitting devices, an insulating layer 125 and an insulating layer 127 over the insulating layer 125 are provided. Hereinafter, the light-emitting devices 130a, 130b, and 130c are collectively referred to as a “light-emitting device 130” in some cases.

Although FIG. 1B and the like illustrate a plurality of cross sections of the insulating layers 125 and the insulating layers 127, when the display apparatus 100 is seen from above, the insulating layers 125 and the insulating layers 127 are each one continuous layer. In other words, the display apparatus 100 can have a structure including one insulating layer 125 and one insulating layer 127, for example. Note that the display apparatus 100 may include a plurality of insulating layers 125 which are separated from each other and a plurality of insulating layers 127 which are separated from each other.

As illustrated in FIG. 1B, in the display apparatus 100, a resin layer 147, an insulating layer 103, a conductive layer 104, an insulating layer 105, a conductive layer 106, an adhesive layer 107, and a substrate 102 are provided over the protective layer 131. On the substrate 101 side of the display apparatus 100 illustrated in FIG. 1B, the resin layer 147 is provided over the protective layer 131, the insulating layer 103 is provided over the resin layer 147, the conductive layer 104 is provided over the insulating layer 103, the insulating layer 105 is provided over the insulating layer 103 and the conductive layer 104, and the conductive layer 106 is provided over the insulating layer 105. The substrate 102 is bonded to the substrate 101 with the adhesive layer 107 therebetween. Here, the adhesive layer 107 is in contact with the conductive layer 106, the insulating layer 105, and the substrate 102.

The conductive layer 104 and the conductive layer 106 function as the electrode of the touch sensor. In the case of using a mutual capacitive touch sensor as the touch sensor, a pulse potential may be supplied to one of the conductive layer 104 and the conductive layer 106, and an analog-digital (A-D) conversion circuit, a sensing circuit such as a sense amplifier, or the like may be connected to the other of the conductive layer 104 and the conductive layer 106, for example. In that case, capacitance is formed between the conductive layer 104 and the conductive layer 106. When the finger or the like approaches, the size of the capacitance changes (specifically, the capacitance is reduced). This change in the capacitance appears, when a pulse potential is supplied to one of the conductive layer 104 and the conductive layer 106, as a change in the amplitude of a signal that occurs in the other of the conductive layer 104 and the conductive layer 106. Accordingly, the touch and approach of the finger or the like can be sensed.

Note that one of the conductive layer 104 and the conductive layer 106 may function as both electrodes of the touch sensor, and the other of the conductive layer 104 and the conductive layer 106 may function as a connection portion of the electrode of the touch sensor. In this case, as illustrated in FIG. 1B, a portion where the conductive layer 104 and the conductive layer 106 are in contact with each other through an opening formed in the insulating layer 105 is formed.

The display apparatus of one embodiment of the present invention can have any of the following structures: a top-emission structure in which light is emitted in a direction opposite to the substrate where the light-emitting devices are formed, a bottom-emission structure in which light is emitted toward the substrate where the light-emitting devices are formed, and a dual-emission structure in which light is emitted toward both surfaces.

The layer including a transistor above the substrate 101 can have a stacked-layer structure in which a plurality of transistors are provided over a substrate and an insulating layer is provided to cover these transistors, for example. The insulating layer over the transistors may have a single-layer structure or a stacked-layer structure. In FIG. 1B and the like, the insulating layer 255a, the insulating layer 255b over the insulating layer 255a, and the insulating layer 255c over the insulating layer 255b are illustrated as the insulating layer over the transistors. These insulating layers may have a depressed portion between adjacent light-emitting devices. In the example illustrated in FIG. 1B and the like, the insulating layer 255c is provided with a depressed portion.

As each of the insulating layer 255a, the insulating layer 255b, and the insulating layer 255c, any of a variety of inorganic insulating films such as an oxide insulating film, a nitride insulating film, an oxynitride insulating film, and a nitride oxide insulating film can be suitably used. As each of the insulating layer 255a and the insulating layer 255c, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as each of the insulating layer 255a and the insulating layer 255c and a silicon nitride film be used as the insulating layer 255b. The insulating layer 255b preferably has a function of an etching protective film.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

Structure examples of the layer including a transistor above the substrate 101 are described in detail in Embodiment 5 and Embodiment 6.

The light-emitting devices 130a, 130b, and 130c emit light of different colors. Preferably, the light-emitting devices 130a, 130b, and 130c are a combination of light-emitting devices emitting light of three colors, red (R), green (G), and blue (B), for example.

As the light-emitting devices 130a, 130b, and 130c, a light-emitting device such as an OLED (Organic Light Emitting Diode) or a QLED (Quantum-dot Light Emitting Diode) is preferably used. Examples of a light-emitting substance contained in the light-emitting device include a substance that emits fluorescent light (a fluorescent material), a substance that emits phosphorescent light (a phosphorescent material), a substance that exhibits thermally activated delayed fluorescence (a thermally activated delayed fluorescent (TADF) material), and an inorganic compound (e.g., a quantum dot material). As the TADF material, a material in which the singlet excited state and the triplet excited state are in thermal equilibrium may be used. Since such a TADF material has a short emission lifetime (excitation lifetime), it can inhibit a reduction in the efficiency of a light-emitting device in a high-luminance region. In addition, an LED (Light Emitting Diode) such as a micro LED can also be used as the light-emitting device.

Embodiment 2 can be referred to for the structure and materials of the light-emitting device.

The light-emitting device includes an EL layer between a pair of electrodes. The EL layer includes at least a light-emitting layer. In this specification and the like, one of the pair of electrodes is referred to as a pixel electrode and the other is referred to as a common electrode in some cases.

One of the pair of electrodes of the light-emitting device functions as an anode, and the other electrode functions as a cathode. The case where the pixel electrode functions as an anode and the common electrode functions as a cathode will be described below as an example in some cases. Note that Embodiment 2 can be referred to for the details of structures and materials of the pixel electrode and the common electrode.

End portions of a pixel electrode 11a, a pixel electrode 111b, and a pixel electrode 111c each preferably have a tapered shape. When the end portions of these pixel electrodes have a tapered shape, the shape of each of the EL layers provided along the side surfaces of the pixel electrodes is also reflected by the tapered shape. When the side surfaces of the pixel electrodes have a tapered shape, coverage with the EL layers provided along the side surfaces of the pixel electrodes can be improved. Furthermore, when the side surfaces of the pixel electrodes have a tapered shape, a material (for example, also referred to as dust or particles) in the manufacturing process is easily removed by processing such as cleaning, which is preferable.

Note that in this specification and the like, a tapered shape refers to a shape such that at least part of a side surface of a component is inclined to a substrate surface. For example, a tapered shape preferably includes a region where the angle between the inclined side surface and the substrate surface (such an angle is also referred to as a taper angle) is less than 90°. Note that the side surface of a component and the substrate surface are not necessarily completely flat and may be substantially flat with a slight curvature or substantially flat with slight unevenness.

The light-emitting device 130a includes the pixel electrode 111a over the insulating layer 255c, a first layer 113a with an island shape over the pixel electrode 111a, a common layer 114 over the first layer 113a with an island shape, and a common electrode 115 over the common layer 114. In the light-emitting device 130a, the first layer 113a and the common layer 114 can also be collectively referred to as an EL layer.

The light-emitting device 130b includes the pixel electrode 111b over the insulating layer 255c, a second layer 113b with an island shape over the pixel electrode 111b, the common layer 114 over the second layer 113b with an island shape, and the common electrode 115 over the common layer 114. In the light-emitting device 130b, the second layer 113b and the common layer 114 can also be collectively referred to as an EL layer.

The light-emitting device 130c includes the pixel electrode 111c over the insulating layer 255c, a third layer 113c with an island shape over the pixel electrode 111c, the common layer 114 over the third layer 113c with an island shape, and the common electrode 115 over the common layer 114. In the light-emitting device 130c, the third layer 113c and the common layer 114 can also be collectively referred to as an EL layer.

In this embodiment, in the EL layers included in the light-emitting devices, the island-shaped layers provided in the light-emitting devices are referred to as the first layer 113a, the second layer 113b, and the third layer 113c, and the layer shared by the plurality of light-emitting devices is referred to as the common layer 114.

The first layer 113a, the second layer 113b, and the third layer 113c are each processed into an island shape by a photolithography method. Thus, in each of end portions of the first layer 113a, the second layer 113b, and the third layer 113c, an angle formed between the top surface and the side surface is approximately 90°. Meanwhile, an organic film formed using an FMM (Fine Metal Mask) or the like tends to be gradually thinner toward the end portion. For example, since the top surface is formed in a slope shape in the range of greater than or equal to 1 μm and less than or equal to 10 μm in the vicinity of the end portion, the top surface and the side surface are difficult to be distinguished from each other.

A top surface and a side surface of each of the first layer 113a, the second layer 113b, and the third layer 113c are clearly distinguished from one another. Accordingly, as for the first layer 113a and the second layer 113b which are adjacent to each other, one of the side surfaces of the first layer 113a and one of the side surfaces of the second layer 113b are provided to face each other. Similarly, as for the first layer 113a and the third layer 113c which are adjacent to each other, one of the side surfaces of the first layer 113a and one of the side surfaces of the third layer 113c are provided to face each other, and as for the second layer 113b and the third layer 113c which are adjacent to each other, one of the side surfaces of the second layer 113b and one of the side surfaces of the third layer 113c are provided to face each other.

The first layer 113a, the second layer 113b, and the third layer 113c each include a plurality of light-emitting units and a charge-generation layer. Each of the light-emitting units includes at least one light-emitting layer. Each light-emitting unit may include one or more of a hole-injection layer, a hole-transport layer, a hole-blocking layer, an electron-blocking layer, an electron-transport layer, and an electron-injection layer. The charge-generation layer is preferably provided between the light-emitting units.

For example, the first layer 113a has a structure including a plurality of light-emitting units that emit red light, the second layer 113b has a structure including a plurality of light-emitting units that emit green light, and the third layer 113c has a structure including a plurality of light-emitting units that emit blue light.

The first layer 113a includes a first light-emitting unit 113a1, a charge-generation layer 113a2 over the first light-emitting unit 113a1, and a second light-emitting unit 113a3 over the charge-generation layer 113a2, for example. The second layer 113b includes a first light-emitting unit 113b1, a charge-generation layer 113b2 over the first light-emitting unit 113b1, and a second light-emitting unit 113b3 over the charge-generation layer 113b2, for example. The third layer 113c includes a first light-emitting unit 113c1, a charge-generation layer 113c2 over the first light-emitting unit 113c1, and a second light-emitting unit 113c3 over the charge-generation layer 113c2, for example. Here, the charge-generation layers 113a2, 113b2, and 113c2 each include at least a charge-generation region. In FIG. 1B and the like, the charge-generation layers 113a2, 113b2, and 113c2 are denoted by dashed lines.

Note that in the following drawings and the like, the first light-emitting unit 113a1, the charge-generation layer 113a2, and the second light-emitting unit 113a3 are collectively referred to as the “first layer 113a” in some cases. The first light-emitting unit 113b1, the charge-generation layer 113b2, and the second light-emitting unit 113b3 are collectively referred to as the “second layer 113b” in some cases. The first light-emitting unit 113c1, the charge-generation layer 113c2, and the second light-emitting unit 113c3 are collectively referred to as the “third layer 113c” in some cases.

It is preferable that the second light-emitting units 113a3, 113b3, and 113c3 each preferably include a light-emitting layer and a carrier-transport layer (an electron-transport layer or a hole-transport layer) over the light-emitting layer. The second light-emitting units 113a3, 113b3, and 113c3 each preferably include a light-emitting layer and a carrier-blocking layer (a hole-blocking layer or an electron-blocking layer) over the light-emitting layer. The second light-emitting units 113a3, 113b3, and 113c3 each preferably include a light-emitting layer, a carrier-blocking layer over the light-emitting layer, and a carrier-transport layer over the carrier-blocking layer. Since the surfaces of the second light-emitting units 113a3, 113b3, and 113c3 are exposed in the manufacturing process of the display apparatus, providing one or both of the carrier-transport layer and the carrier-blocking layer over each of the light-emitting layers inhibits the light-emitting layer from being exposed on the outermost surface, so that damage to the light-emitting layer can be reduced. Thus, the reliability of the light-emitting device can be increased. Note that in the case where three or more light-emitting units are included, the uppermost light-emitting unit preferably includes a light-emitting layer and one or both of a carrier-transport layer and a carrier-blocking layer over the light-emitting layer.

The common layer 114 includes an electron-injection layer or a hole-injection layer, for example. Alternatively, the common layer 114 may be a stack of an electron-transport layer and an electron-injection layer, and may be a stack of a hole-transport layer and a hole-injection layer. The common layer 114 is shared by the light-emitting devices 130a, 130b, and 130c.

The common electrode 115 is shared by the light-emitting devices 130a, 130b, and 130c. As illustrated in FIG. 6A and FIG. 6B, the common electrode 115 shared by the plurality of light-emitting devices is electrically connected to a conductive layer 123 provided in the connection portion 140. Here, FIG. 6A and FIG. 6B are each a cross-sectional view taken along the dashed-dotted line Y1-Y2 in FIG. 1A. Although a structure above the protective layer 131 is not illustrated in FIG. 6A and FIG. 6B, at least one or more of the resin layer 147, the insulating layer 103, the conductive layer 104, the insulating layer 105, the conductive layer 106, the adhesive layer 107, and the substrate 102 can be provided as appropriate. As the conductive layer 123, a conductive layer formed using the same material in the same step as the pixel electrode 11a to the pixel electrode 111c is preferably used.

Note that FIG. 6A illustrates an example in which the common layer 114 is provided over the conductive layer 123 and the conductive layer 123 and the common electrode 115 are electrically connected to each other through the common layer 114. The common layer 114 is not necessarily provided in the connection portion 140. In FIG. 6B, the conductive layer 123 and the common electrode 115 are directly connected to each other. For example, by using a mask for specifying a film formation area (also referred to as an area mask, a rough metal mask, or the like to be distinguished from a fine metal mask), the common layer 114 and the common electrode 115 can be formed in different regions.

The protective layer 131 is preferably provided over the light-emitting devices 130a, 130b, and 130c. Providing the protective layer 131 can improve the reliability of the light-emitting devices. The protective layer 131 may have a single-layer structure or a stacked-layer structure of two or more layers.

There is no limitation on the conductivity of the protective layer 131. As the protective layer 131, at least one kind of an insulating film, a semiconductor film, and a conductive film can be used.

The protective layer 131 including an inorganic film can inhibit deterioration of the light-emitting devices by preventing oxidation of the common electrode 115 and inhibiting entry of impurities (e.g., moisture and oxygen) into the light-emitting devices, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, the protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high property of transmitting visible light. For example, ITO, IGZO, and aluminum oxide are preferable because they are inorganic materials having a high property of transmitting visible light.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) into the EL layer.

Furthermore, the protective layer 131 may include an organic film. For example, the protective layer 131 may include both an organic film and an inorganic film. Examples of an organic material that can be used for the protective layer 131 include organic insulating materials that can be used for an insulating layer 121 described later.

The protective layer 131 may have a stacked-layer structure of two layers which are formed by different deposition methods. Specifically, the first layer of the protective layer 131 may be formed by an ALD method and the second layer of the protective layer 131 may be formed by a sputtering method.

In FIG. 1B and the like, an insulating layer covering an end portion of the top surface of the pixel electrode 111a is not provided between the pixel electrode 111a and the first layer 113a. An insulating layer covering an end portion of the top surface of the pixel electrode 111b is not provided between the pixel electrode 111b and the second layer 113b. An insulating layer covering an end portion of the top surface of the pixel electrode 111c is not provided between the pixel electrode 111c and the third layer 113c. Thus, the distance between adjacent light-emitting devices can be extremely shortened. Accordingly, the display apparatus can have high resolution or high definition.

In FIG. 1B and the like, a mask layer 118a is positioned over the first layer 113a included in the light-emitting device 130a, a mask layer 118b is positioned over the second layer 113b included in the light-emitting device 130b, and a mask layer 118c is positioned over the third layer 113c included in the light-emitting device 130c. The mask layer 118a is a remaining portion of the mask layer provided over the first layer 113a when the first layer 113a is processed. Similarly, the mask layer 118b and the mask layer 118c are remaining portions of the mask layers provided when the second layer 113b and the third layer 113c are formed, respectively. Thus, in the display apparatus of one embodiment of the present invention, the mask layer used to protect the EL layer in manufacture of the display apparatus may partly remain. For any two or all of the mask layer 118a to the mask layer 118c, the same or different materials may be used. Note that the mask layer 118a, the mask layer 118b, and the mask layer 118c are hereinafter collectively referred as a “mask layer 118” in some cases.

In FIG. 1B, one end portion of the mask layer 118a is aligned or substantially aligned with the end portion of the first layer 113a, and the other end portion of the mask layer 118a is positioned over the first layer 113a. Here, the other end portion of the mask layer 118a preferably overlaps with the first layer 113a and the pixel electrode 111a. In that case, the other end portion of the mask layer 118a is likely to be formed over a substantially flat surface of the first layer 113a. The same applies to the mask layer 118b and the mask layer 118c. The mask layer 118 remains between, for example, the EL layer processed into an island shape (the first layer 113a, the second layer 113b, or the third layer 113c) and the insulating layer 125 in some cases.

As the mask layer 118, one or more kinds of a metal film, an alloy film, a metal oxide film, a semiconductor film, an organic insulating film, and an inorganic insulating film can be used, for example. As the mask layer 118, any of a variety of inorganic insulating films that can be used as the protective layer 131 can be used. For example, an inorganic insulating material such as aluminum oxide, hafnium oxide, or silicon oxide can be used.

There is no particular limitation on the size relationship between the widths of the pixel electrode and the island-shaped EL layer. The pixel electrode 111a and the first layer 113a are given as an example in the following description. The same applies to the pixel electrode 111b and the second layer 113b, and the pixel electrode 111c and the third layer 113c.

FIG. 1B and the like illustrate an example where the end portion of the first layer 113a is positioned outward from the end portion of the pixel electrode 111a. In FIG. 1B and the like, the first layer 113a is formed to cover the end portion of the pixel electrode 111a. Such a structure can increase the aperture ratio compared with the structure in which an end portion of the island-shaped EL layer is positioned inward from the end portion of the pixel electrode.

Covering the side surface of the pixel electrode with the EL layer can inhibit contact between the pixel electrode and the common electrode 115 (or the common layer 114); thus, a short circuit in the light-emitting device can be inhibited. Furthermore, the distance between the light-emitting region (i.e., the region overlapping with the pixel electrode) in the EL layer and the end portion of the EL layer can be increased. The end portion of the first layer 113a, the end portion of the second layer 113b, and the end portion of the third layer 113c include a portion that might be damaged in the manufacturing process of the display apparatus. By not using the portion as the light-emitting region, a variation in characteristics of the light-emitting devices can be inhibited, and the reliability can be improved.

As illustrated in FIG. 1B, the side surfaces of the first layer 113a, the second layer 113b, and the third layer 113c are each covered with the insulating layer 127 and the insulating layer 125. Each of the top surfaces of the first layer 113a, the second layer 113b, and the third layer 113c is partly covered with the insulating layer 127, the insulating layer 125, and the mask layer 118.

The insulating layer 125 preferably covers at least one of the side surfaces of the island-shaped EL layers, and further preferably covers both of the side surfaces of the island-shaped EL layers. The insulating layer 125 can be in contact with the side surfaces of the island-shaped EL layers.

In FIG. 1B and the like illustrate a structure where the end portion of the pixel electrode 111a is covered with the first layer 113a and the insulating layer 125 is in contact with the side surface of the first layer 113a. Similarly, the end portion of the pixel electrode 111b is covered with the second layer 113b, the end portion of the pixel electrode 111c is covered with the third layer 113c, and the insulating layer 125 is in contact with the side surface of the second layer 113b and the side surface of the third layer 113c.

With the above-described structure, the common layer 114 (or the common electrode 115) can be inhibited from being in contact with the side surfaces of the pixel electrodes 111a, 111b, and 111c, the first layer 113a, the second layer 113b, and the third layer 113c, whereby a short circuit in the light-emitting device can be inhibited. Thus, the reliability of the light-emitting device can be increased.

The insulating layer 127 is provided over the insulating layer 125 to fill a depressed portion of the insulating layer 125. The insulating layer 127 can overlap with the side surfaces and parts of the top surfaces of each of the first layer 113a, the second layer 113b, and the third layer 113c (in other words, the insulating layer 127 can cover the side surfaces) with the insulating layer 125 therebetween.

The insulating layer 125 and the insulating layer 127 can fill a space between adjacent island-shaped layers, whereby unevenness with a large level difference on the formation surface of a layer (e.g., the carrier-injection layer and the common electrode) provided over the island-shaped layers can be reduced and the formation surface can be flatter. Thus, the coverage with the carrier-injection layer, the common electrode, and the like can be increased and disconnection of the carrier-injection layer, the common electrode, and the like can be prevented.

The common layer 114 and the common electrode 115 are provided over the first layer 113a, the second layer 113b, the third layer 113c, the mask layer 118, the insulating layer 125, and the insulating layer 127. At the stage before the insulating layer 125 and the insulating layer 127 are provided, a level difference due to a region where the pixel electrode and the EL layer are provided and a region where the pixel electrode and the EL layer are not provided (a region between the light-emitting devices) is caused. The display panel of one embodiment of the present invention can eliminate the level difference by including the insulating layer 125 and the insulating layer 127, whereby the coverage with the common layer 114 and the common electrode 115 can be improved. Consequently, it is possible to inhibit a connection defect due to disconnection. Alternatively, it is possible to inhibit an increase in electric resistance due to local thinning of the common electrode 115 caused by the level difference.

A top surface of the insulating layer 127 preferably has higher flatness, but may include a projected portion, a convex curved surface, a concave curved surface, or a depressed portion. For example, the top surface of the insulating layer 127 preferably has a smooth convex curved surface shape with high flatness.

The insulating layer 125 can be provided in contact with the island-shaped EL layers. Thus, peeling of the island-shaped EL layers can be prevented. Close contact between the insulating layer and the EL layer has an effect of fixing or bonding the adjacent island-shaped EL layers to each other. Thus, the reliability of the light-emitting device can be increased. In addition, the manufacturing yield of the light-emitting device can be increased.

The insulating layer 125 includes a region in contact with the side surface of the island-shaped EL layer and functions as a protective insulating layer of the EL layer. Providing the insulating layer 125 can inhibit entry of impurities (e.g., oxygen and moisture) into the inside of the island-shaped EL layer through its side surface, resulting in a highly reliable display panel.

Next, examples of materials and formation methods of the insulating layer 125 and the insulating layer 127 are described.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Aluminum oxide is particularly preferable because it has high selectivity with the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. For example, the insulating layer 125 may have a stacked-layer structure of an aluminum oxide film formed by an ALD method and a silicon nitride film formed by a sputtering method.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of a barrier insulating layer or a gettering function, entry of impurities (typically, at least one of water and oxygen) that might diffuse into the light-emitting devices from the outside can be inhibited. With this structure, a highly reliable light-emitting device and a highly reliable display panel can be provided.

The insulating layer 125 preferably has a low impurity concentration. In this case, deterioration of the EL layer due to entry of impurities from the insulating layer 125 into the EL layer can be inhibited. In addition, when having a low impurity concentration, the insulating layer 125 can have a high barrier property against at least one of water and oxygen. For example, the insulating layer 125 preferably has one of a sufficiently low hydrogen concentration and a sufficiently low carbon concentration, desirably has both of them.

Examples of the formation method of the insulating layer 125 include a sputtering method, a CVD method, a pulsed laser deposition (PLD) method, and an ALD method. The insulating layer 125 is preferably formed by an ALD method achieving good coverage.

When the substrate temperature in forming the insulating layer 125 is increased, the formed insulating layer 125, even with a small thickness, can have a low impurity concentration and a high barrier property against at least one of water and oxygen. Therefore, the substrate temperature is preferably higher than or equal to 60° C., more preferably higher than or equal to 80° C., further preferably higher than or equal to 100° C., still further preferably higher than or equal to 120° C. Meanwhile, the insulating layer 125 is formed after formation of an island-shaped EL layer, and thus is preferably formed at a temperature lower than the upper temperature limit of the EL layer. Therefore, the substrate temperature is preferably lower than or equal to 200° C., more preferably lower than or equal to 180° C., further preferably lower than or equal to 160° C., still further preferably lower than or equal to 150° C., yet still further preferably lower than or equal to 140° C.

Examples of indicators of the upper temperature limit include the glass transition point, the softening point, the melting point, the thermal decomposition temperature, and the 5% weight loss temperature. The upper temperature limit of the EL layer can be, for example, any of the above temperatures, preferably the lowest temperature thereof.

As the insulating layer 125, an insulating film is preferably formed to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The insulating layer 127 provided over the insulating layer 125 has a planarization function for unevenness with a large level difference on the insulating layer 125 formed between adjacent light-emitting devices. In other words, the insulating layer 127 has an effect of improving the planarity of the surface where the common electrode 115 is formed.

As the insulating layer 127, an insulating layer containing an organic material can be suitably used. As the organic material, a photosensitive organic resin is preferably used; for example, a photosensitive resin composition containing an acrylic resin may be used. The viscosity of the material for the insulating layer 127 is greater than or equal to 1 cP and less than or equal to 1500 cP, and is preferably greater than or equal to 1 cP and less than or equal to 12 cP. By setting the viscosity of the material for the insulating layer 127 in the above range, the insulating layer 127 having a tapered shape, which is to be described later, can be formed relatively easily. Note that in this specification and the like, an acrylic resin refers to not only a polymethacrylic acid ester or a methacrylic resin, but also all the acrylic polymer in a broad sense in some cases.

Note that the organic material usable for the insulating layer 127 is not limited to the above-described materials as long as a side surface of the insulating layer 127 has a tapered shape as described later. For example, the insulating layer 127 can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like in some cases. Alternatively, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin can be used for the insulating layer 127 in some cases. As the photosensitive resin, a photoresist can be used in some cases. As the photosensitive resin, a positive material or a negative material can be used in some cases.

The insulating layer 127 may be formed using a material absorbing visible light. When the insulating layer 127 absorbs light emitted from the light-emitting device, leakage of light (stray light) from the light-emitting device to an adjacent light-emitting device through the insulating layer 127 can be inhibited. Thus, display quality of the display panel can be improved. Since the display quality of the display panel can be improved without using a polarizing plate, the weight and thickness of the display panel can be reduced.

Examples of the material absorbing visible light include a material containing a pigment of black or any other color, a material containing a dye, a light-absorbing resin material (e.g., polyimide), and a resin material that can be used for color filters (a color filter material). It is particularly preferable to use a resin material obtained by stacking or mixing color filter materials of two or three or more colors to enhance the effect of blocking visible light. In particular, mixing color filter materials of three or more colors enables the formation of a black or nearly black resin layer.

For example, the insulating layer 127 can be formed by a wet film formation method such as spin coating, dipping, spray coating, ink-jetting, dispensing, screen printing, offset printing, doctor knife coating, slit coating, roll coating, curtain coating, or knife coating. Specifically, an organic insulating film that is to be the insulating layer 127 is preferably formed by spin coating.

The insulating layer 127 is formed at a temperature lower than the upper temperature limit of the EL layer. The typical substrate temperature in formation of the insulating layer 127 is lower than or equal to 200° C., preferably lower than or equal to 180° C., further preferably lower than or equal to 160° C., still further preferably lower than or equal to 150° C., yet still further preferably lower than or equal to 140° C.

Hereinafter, a structure of the insulating layer 127 and the like is described using the structure of the insulating layer 127 between the light-emitting device 130a and the light-emitting device 130b as an example. Note that the same can apply to the insulating layer 127 between the light-emitting device 130b and the light-emitting device 130c, the insulating layer 127 between the light-emitting device 130c and the light-emitting device 130a, and the like. In the description below, an end portion of the insulating layer 127 over the second layer 113b is used as an example in some cases, and the same can apply to an end portion of the insulating layer 127 over the first layer 113a, an end portion of the insulating layer 127 over the third layer 113c, and the like.

In a cross-sectional view of the display apparatus, the side surface of the insulating layer 127 preferably has a tapered shape with the taper angle θ1. The taper angle θ1 is an angle formed by the side surface of the insulating layer 127 and the substrate surface. Note that the taper angle 01 is not limited to the angle with the substrate surface, and may be an angle formed by the side surface of the insulating layer 127 and a top surface of the flat portion of the insulating layer 125, a top surface of the flat portion of the second layer 113b, a top surface of the flat portion of the pixel electrode 111b, or the like. In this specification and the like, the side surface of the insulating layer 127 sometimes refers to the side surface of a portion having a convex curved surface shape above the flat portion of the first layer 113a, the second layer 113b, or the third layer 113c as illustrated in FIG. 1B. When the side surface of the insulating layer 127 has a tapered shape, a side surface of the insulating layer 125 and a side surface of the mask layer 118 also have a tapered shape in some cases.

The taper angle θ1 of the insulating layer 127 is less than 90°, preferably less than or equal to 60°, and further preferably less than or equal to 45°. Such a forward tapered shape of the end portion of the side surface of the insulating layer 127 can prevent disconnection, local thinning, or the like from occurring in the common layer 114 and the common electrode 115 which are provided over the end portion of the side surface of the insulating layer 127, leading to film formation with good coverage. The common layer 114 and the common electrode 115 can have improved in-plane uniformity in this manner, whereby the display apparatus can have improved display quality.

The top surface of the insulating layer 127 preferably has a convex curved surface shape in a cross-sectional view of the display apparatus. The top surface of the insulating layer 127 preferably has a convex curved surface shape that bulges gradually toward the center. The insulating layer 127 preferably has a shape such that the convex curved surface portion at the center portion of the top surface is connected smoothly to the tapered portion of the end portion of the side surface. When the insulating layer 127 has such a shape, the common layer 114 and the common electrode 115 can be formed with good coverage over the whole the insulating layer 127.

The insulating layer 127 is formed in a region between two EL layers (e.g., a region between the first layer 113a and the second layer 113b). In that case, at least part of the insulating layer 127 is provided at a position interposed between an end portion of a side surface of one of the EL layers (e.g., the first layer 113a) and an end portion of a side surface of the other of the EL layers (e.g., the second layer 113b).

It is preferable that one end portion of the insulating layer 127 overlap with the pixel electrode 111a and that the other end portion of the insulating layer 127 overlap with the pixel electrode 111b. With such a structure, the end portion of the insulating layer 127 can be formed over a substantially flat region of the first layer 113a (the second layer 113b). This makes it relatively easy to process the tapered shape of the insulating layer 127, as described above.

By providing the insulating layer 127 and the like as described above, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115. Accordingly, the display quality of the display apparatus of one embodiment of the present invention can be improved.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between the light-emitting devices is shortened in this manner, whereby a display apparatus with high resolution and a high aperture ratio can be provided.

Although the structure where one end portion of the insulating layer 127 overlaps with the pixel electrode 111a and the other end portion of the insulating layer 127 overlaps with the pixel electrode 11b is described above, the present invention is not limited thereto. For example, as illustrated in FIG. 6C, a structure may be employed where the insulating layer 127 does not overlap with the pixel electrode 111a or the pixel electrode 111b.

Although FIG. 1B and the like illustrate the structure where the end portion of the insulating layer 127 is substantially aligned with the end portion of the mask layer 118 and an end portion of the insulating layer 125, the present invention is not limited thereto. For example, a structure may be employed where the end portion of the insulating layer 127 is positioned outward from the end portion of the mask layer 118 and the end portion of the insulating layer 125. In other words, a structure may be employed where the end portion of the mask layer 118 and the end portion of the insulating layer 125 are covered with the insulating layer 127. With such a structure, the end portion of the insulating layer 127 and a top surface of the EL layer can be smoothly connected, so that the common layer 114 and the common electrode 115 which are provided over the insulating layer 127 can be formed with good coverage.

Although the thicknesses of the first layer 113a to the third layer 113c are equal in FIG. 1B and the like, the present invention is not limited thereto. The first layer 113a to the third layer 113c may have different thicknesses. The thicknesses may be set in accordance with the optical path lengths that intensify light emitted by the first layer 113a to the third layer 113c. This achieves a microcavity structure, so that the color purity in each light-emitting device can be increased.

For example, when the third layer 113c emits light with the longest wavelength and the second layer 113b emits light with the shortest wavelength, the third layer 113c can have the largest thickness and the second layer 113b can have the smallest thickness. Note that without limitation to this, the thicknesses of the EL layers can be adjusted in consideration of the wavelengths of light emitted by the light-emitting devices, the optical characteristics of the layers included in the light-emitting devices, the electrical characteristics of the light-emitting devices, and the like.

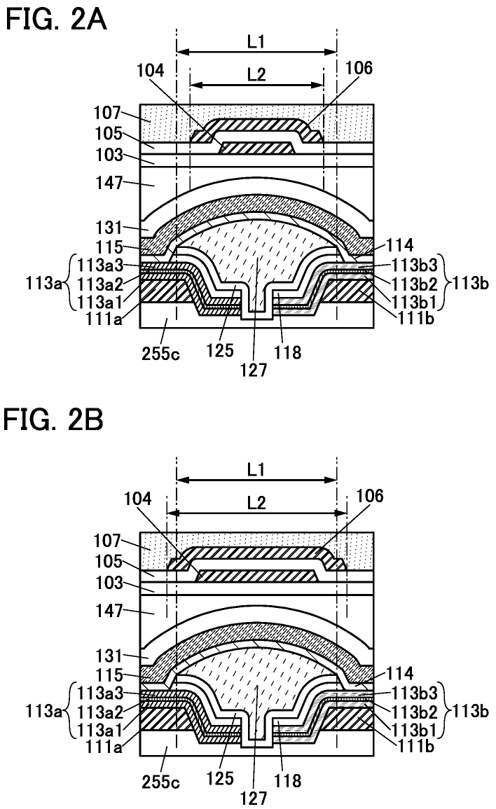

Next, a structure of a touch sensor is described with reference to FIG. 2A and FIG. 2B. Note that FIG. 2A and FIG. 2B are each an enlarged view of a region interposed between the first layer 113a and the second layer 113b illustrated in FIG. 1B. Hereinafter, the description is made with reference to FIG. 2A, FIG. 2B, and the like; however, the same applies to a region interposed between the first layer 113a and the third layer 113c, a region interposed between the second layer 113b and the third layer 113c, and the like that are not illustrated in FIG. 2A and FIG. 2B.

The conductive layer 104 is provided over the insulating layer 103. The insulating layer 105 is provided to cover the conductive layer 104 and the insulating layer 103. The conductive layer 106 is provided over the insulating layer 105. The insulating layer 103 is provided over the resin layer 147 that is provided over the protective layer 131. The conductive layer 106 and the insulating layer 105 are bonded to the substrate 102 with the adhesive layer 107.

One or both of the conductive layer 104 and the conductive layer 106 function as an electrode/electrodes of a touch sensor. Here, an example where a touch sensor is formed by the conductive layer 104 and the conductive layer 106 which are formed with the insulating layer 105 therebetween.

The conductive layer 104 and the conductive layer 106 included in the touch sensor are formed directly on the resin layer 147, whereby the thickness of the display apparatus 100 can be made extremely small. Since the conductive layer 104 and the conductive layer 106 of the display apparatus 100 are not provided on the substrate 102 side, bonding of the substrate 102 and the substrate 101 does not need high accuracy, which leads to an improvement in the manufacturing yield. The substrate 102 only needs a light-transmitting property, and the degree of freedom in selecting materials is extremely high.

FIG. 1B illustrates a portion where the conductive layer 104 and the conductive layer 106 overlap with each other. For example, a portion where the conductive layer 104 and the conductive layer 106 intersect with each other can be used. A structure of a connection portion where the conductive layer 104 and the conductive layer 106 are electrically connected to each other is also illustrated. In the connection portion, the conductive layer 104 and the conductive layer 106 are electrically connected to each other through an opening provided in the insulating layer 105. The connection portion can be used as a portion where two conductive layers 104 with island shapes are electrically connected to each other with the conductive layer 106.

In FIG. 2A, the conductive layer 104 and the conductive layer 106 are provided to avoid a light-emitting region of the light-emitting device 130a and a light-emitting region of the light-emitting device 130b. In other words, the conductive layer 104 and the conductive layer 106 overlap with a region interposed between two adjacent light-emitting devices or a region interposed between two adjacent EL layers.

Furthermore, the conductive layer 104 and the conductive layer 106 each include a region overlapping with the insulating layer 127. Here, as illustrated in FIG. 2A, the length L2 of the conductive layer 106 in the X1-X2 direction is preferably smaller than the length L1 of the insulating layer 127 in the X1-X2 direction. In other words, a side surface of the conductive layer 104 and a side surface of the conductive layer 106 are preferably positioned inside the side surface of the insulating layer 127 (also referred to as the end portion of the insulating layer 127) in a cross-sectional view. With such a structure, the conductive layer 104 and the conductive layer 106 can be provided not to hinder light emission of the light-emitting device; thus, the display apparatus can be provided with the touch sensor without a reduction in the aperture ratio of the display apparatus 100. Thus, a low-resistance conductive material such as a metal or an alloy can be used for the conductive layer 104 and the conductive layer 106 without using a conductive material having a light-transmitting property, so that the sensitivity of the touch sensor can be increased.

As described above, when the display apparatus of one embodiment of the present invention has an MML structure, a display apparatus with both a high aperture ratio and a high resolution can be obtained. Furthermore, by providing the conductive layer 104 and the conductive layer 106 as described above, a touch sensor can be provided while a high aperture ratio is maintained.

Although both the conductive layer 104 and the conductive layer 106 overlap with the region interposed between two adjacent light-emitting devices in FIG. 2A, one embodiment of the present invention is not limited thereto. A structure may be employed where any one of the conductive layer 104 and the conductive layer 106 overlaps with the region interposed between two adjacent light-emitting devices or the region interposed between two adjacent EL layers. Alternatively, a structure may be employed where any one of the conductive layer 104 and the conductive layer 106 includes the region overlapping with the insulating layer 127.

Although FIG. 2A illustrates the structure where the length L2 of the conductive layer 106 in the X1-X2 direction is smaller than the length L1 of the insulating layer 127 in the X1-X2 direction, the present invention is not limited thereto. As illustrated in FIG. 2B, a structure where the length L2 of the conductive layer 106 in the X1-X2 direction is larger than the length L1 of the insulating layer 127 in the X1-X2 direction, that is, a structure where part of the conductive layer 104 and part of the conductive layer 106 do not overlap with the insulating layer 127, can also be employed. Note that a region where the conductive layer 104 and the conductive layer 106 do not overlap with the insulating layer 127 is preferably small in terms of preventing a reduction in the aperture ratio of the display apparatus.

A conductive film containing a metal or an alloy can be used as the conductive layer 104 and the conductive layer 106. As each of the conductive layer 104 and the conductive layer 106, a conductive film containing metals such as aluminum, titanium, chromium, nickel, copper, yttrium, zirconium, molybdenum, silver, tantalum, and tungsten, an alloy containing any of these metals as its main component, and the like can be given. A single layer or a stacked-layer structure including a film containing any of these materials can be used. With the use of a conductive film containing a relatively low-resistance metal or a relatively low-resistance alloy as the conductive layer 104 and the conductive layer 106 as described above, the sensitivity of the touch sensor can be increased.

In the case where a conductive material such as a metal or an alloy is used for the conductive layer 104 and the conductive layer 106, reflection of external light due to the conductive layer 104 and the conductive layer 106 might be recognized when the display apparatus is seen from a display surface side (the substrate 102 side in FIG. 1). Therefore, a circularly polarizing plate (not illustrated) is preferably provided over the substrate 102 to suppress reflection of external light.

As the insulating layer 105, an inorganic insulating film or an organic insulating film can be used. For example, resins such as an acrylic resin and an epoxy resin, and inorganic insulating materials such as silicon oxide, silicon oxynitride, silicon nitride oxide, silicon nitride, and aluminum oxide can be given. The insulating layer 105 may have either a single layer or a stacked-layer structure.

The insulating layer 103 preferably contains an inorganic insulating material. For example, an oxide or a nitride such as silicon oxide, silicon oxynitride, silicon nitride oxide, silicon nitride, aluminum oxide, aluminum oxynitride, or hafnium oxide can be given.

The resin layer 147 preferably contains an organic insulating material. For example, an acrylic resin, a polyimide resin, an epoxy resin, a polyamide resin, a polyimide-amide resin, a siloxane resin, a benzocyclobutene-based resin, a phenol resin, and precursors of these resins can be given.

When a stacked-layer structure where the protective layer 131, the resin layer 147, and the insulating layer 103 are stacked is employed as described above, even in the case where a defect such as a pinhole exists in the protective layer 131, for example, the defect can be filled with the resin layer 147 with high step coverage. Moreover, when the insulating layer 103 is formed over a flat top surface of the resin layer 147, an insulating film with few defects can be formed as the insulating layer 103. Furthermore, when a film containing an inorganic insulating material is used as the insulating layer 103, the insulating layer 103 functions as an etching stopper when the conductive layer 104 is processed (etched), which prevents the resin layer 147 from being etched.

For the adhesive layer 107, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-component-mixture-type resin may be used. An adhesive sheet or the like may be used.

A light-blocking layer may be provided on the surface of the substrate 102 on the adhesive layer 107 side. Any of a variety of optical members can be arranged on the outer surface of the substrate 102. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 102. For example, a glass layer or a silica layer (SiOₓ layer) is preferably provided as the surface protective layer to inhibit the surface contamination and generation of a scratch. The surface protective layer may be formed using DLC (diamond like carbon), aluminum oxide (AlOₓ), a polyester-based material, a polycarbonate-based material, or the like. For the surface protective layer, a material having a high transmitting property with respect to visible light is preferably used. The surface protective layer is preferably formed using a material with high hardness.

For the substrate 101 and the substrate 102, glass, quartz, ceramic, sapphire, a resin, a metal, an alloy, a semiconductor, or the like can be used. The substrate on the side from which light from the light-emitting device is extracted is formed using a material that transmits the light. When the substrate 101 and the substrate 102 are formed using a flexible material, the flexibility of the display apparatus can be increased. Furthermore, a polarizing plate may be used as the substrate 101 and the substrate 102.

For each of the substrate 101 and the substrate 102, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 101 and the substrate 102.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of the films having high optical isotropy include a triacetyl cellulose (TAC, also referred to as cellulose triacetate) film, a cycloolefin polymer (COP) film, a cycloolefin copolymer (COC) film, and an acrylic film.

In the case where a film is used for the substrate and the film absorbs water, the shape of a display apparatus might be changed, e.g., creases might be generated. Thus, for the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

Note that thin films included in the display apparatus (e.g., insulating films, semiconductor films, and conductive films) can be formed by a sputtering method, a CVD method, a vacuum evaporation method, a PLD method, an ALD method, or the like. Examples of a CVD method include a PECVD method and a thermal CVD method. As an example of the thermal CVD method, a metal organic chemical vapor deposition (MOCVD: Metal Organic CVD) method can be given.

Alternatively, thin films included in the display apparatus (e.g., insulating films, semiconductor films, and conductive films) can be formed by a method such as spin coating, dipping, spray coating, ink-jetting, dispensing, screen printing, offset printing, a doctor knife method, slit coating, roll coating, curtain coating, or knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the light-emitting layer, the electron-transport layer, and the electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

Thin films included in the display apparatus can be processed by a photolithography method or the like. Alternatively, thin films may be processed by a nanoimprinting method, a sandblasting method, a lift-off method, or the like. Alternatively, island-shaped thin films may be directly formed by a film formation method using a shielding mask such as a metal mask.

There are the following two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Alternatively, ultraviolet rays, KrF laser light, ArF laser light, or the like can be used. In addition, light exposure may be performed by liquid immersion exposure technique. As the light used for the light exposure, extreme ultraviolet (EUV) light or X-rays may be used. Furthermore, instead of the light used for the light exposure, an electron beam can also be used. It is preferable to use extreme ultraviolet light, X-rays, or an electron beam because they can perform extremely fine processing. Note that in the case of performing exposure by scanning of a beam such as an electron beam, a photomask is not necessarily used.

For etching of thin films, a dry etching method, a wet etching method, a sandblasting method, or the like can be used.

As described above, in the method for manufacturing a display apparatus of this embodiment, the island-shaped EL layers are formed not by using a metal mask having a fine pattern but by processing an EL layer formed over the entire surface. Thus, the size of the island-shaped EL layer or even the size of the subpixel can be smaller than that obtained through the formation with a metal mask. Accordingly, a high-resolution display apparatus or a display apparatus with a high aperture ratio, which has been difficult to achieve, can be manufactured.

### [Variation Example 1 of Display Apparatus]

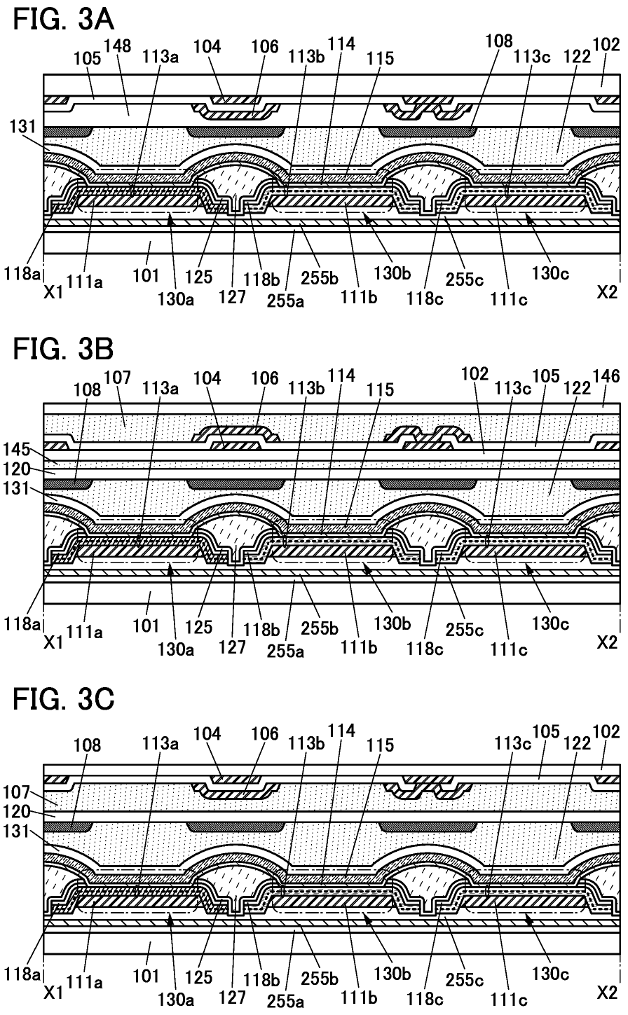

Next, variation examples of the display apparatus 100 where the structure of the touch sensor and the like are changed are described with reference to FIG. 3A to FIG. 5B. Here, FIG. 3A to FIG. 5B each correspond to a cross-sectional view taken along the dashed-dotted line X1-X2 in FIG. 1A. Note that description of FIG. 1B and the like can be referred to for reference numerals in the structures illustrated in FIG. 3A to FIG. 5B which are the same as those in the structure illustrated in FIG. 1B.

Although FIG. 1B illustrates the structure in which a touch sensor is provided on the substrate 101 side, the present invention is not limited thereto. For example, as illustrated in FIG. 3A, a structure may be employed in which the substrate 101 is provided with a display portion and the substrate 102 is provided with a touch sensor.

In FIG. 3A, the conductive layer 104 is provided over the substrate 102, the insulating layer 105 is provided to cover the conductive layer 104, the conductive layer 106 is provided over the insulating layer 105, a resin layer 148 is provided over the conductive layer 106, and a light-blocking layer 108 is provided over the resin layer 148. The substrate 102 and the substrate 101 are bonded to each other with an adhesive layer 122. Thus, the adhesive layer 122 is in contact with the protective layer 131, the resin layer 148, and the light-blocking layer 108. Note that the resin layer 148 can be formed using a material similar to that for the resin layer 147, and the adhesive layer 122 can be formed using a material similar to that for the adhesive layer 107.

The light-blocking layer 108 is provided on a surface of the substrate 102 on the substrate 101 side. By providing the light-blocking layer 108, light emitted from the light-emitting device 130 can be inhibited from leaking to an adjacent subpixel. The light-blocking layer 108 has an opening at least in a position overlapping with the light-emitting device 130. Like the conductive layer 104 and the conductive layer 106, the light-blocking layer 108 preferably includes a region overlapping with the insulating layer 127. In other words, at least part of the light-blocking layer 108 overlaps with a region interposed between two adjacent light-emitting devices or a region interposed between two adjacent EL layers. Providing the light-blocking layer 108 as described above can provide the light-blocking layer 108 without a reduction in the aperture ratio.

For the light-blocking layer 108, a material that blocks light emitted from the light-emitting devices can be used. The light-blocking layer 108 preferably absorbs visible light. For the light-blocking layer 108, a black matrix can be formed using a metal material or a resin material containing pigment (e.g., carbon black) or dye, for example. Alternatively, the light-blocking layer 108 may have a stacked-layer structure including two or more of a red color filter, a green color filter, and a blue color filter. Note that a structure where the light-blocking layer 108 is not provided may be employed.

Although FIG. 1B and FIG. 3A each illustrate a structure where a display portion and a touch sensor are provided between a pair of the substrate 101 and the substrate 102, the present invention is not limited thereto. For example, as illustrated in FIG. 3B, a structure may be employed where a display portion is provided between the substrate 101 and a substrate 120, and a touch sensor is provided between the substrate 102 and a substrate 146.

In the display apparatus illustrated in FIG. 3B, the light-emitting device 130 is provided over the substrate 101, the protective layer 131 is provided over the light-emitting device 130, the light-blocking layer 108 is provided over the substrate 120, and the substrate 101 and the substrate 120 are bonded to each other with the adhesive layer 122. Here, the adhesive layer 122 is in contact with the protective layer 131, the substrate 120, and the light-blocking layer 108. The conductive layer 104 is provided over the substrate 102, the insulating layer 105 is provided to cover the conductive layer 104, the conductive layer 106 is provided over the insulating layer 105, and the substrate 102 and the substrate 146 are bonded to each other with the adhesive layer 107. The substrate 120 and the substrate 102 are bonded to each other with an adhesive layer 145. Note that the substrate 120 and the substrate 146 can be formed using a material similar to that for the substrate 102, and the adhesive layer 145 can be formed using a material similar to that for the adhesive layer 107.

As illustrated in FIG. 3C, a structure may be employed where a display portion is provided between the substrate 101 and the substrate 120, a touch sensor is provided over the substrate 102, and the substrate 120 and the substrate 102 are bonded to each other with the adhesive layer 107. In this case, the adhesive layer 107 is in contact with the substrate 120, the insulating layer 105, and the conductive layer 106. With such a structure, the number of required substrates can be reduced by one as compared with the display apparatus illustrated in FIG. 3B; thus, a thin display apparatus compared to the display apparatus illustrated in FIG. 3B can be provided.

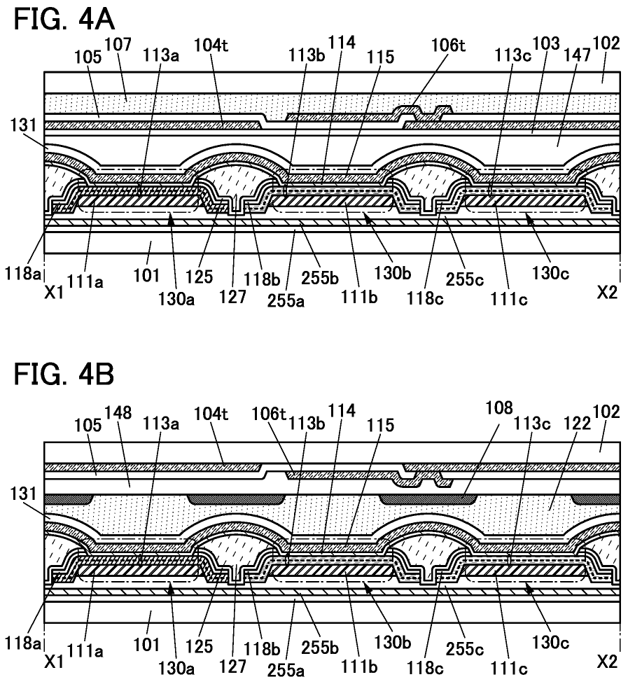

An example of a case where a light-transmitting conductive film is used as an electrode of a touch sensor is described with reference to FIG. 4A and FIG. 4B.

A display apparatus illustrated in FIG. 4A is different from the display apparatus illustrated in FIG. 1B in that a light-transmitting conductive film is used as an electrode of a touch sensor.

In the display apparatus illustrated in FIG. 4A, a conductive layer 104t and a conductive layer 106t are provided respectively instead of the conductive layer 104 and the conductive layer 106 in the structure of the display apparatus illustrated in FIG. 1B. Note that in the display apparatus illustrated in FIG. 4A, the conductive layer 104t and the conductive layer 106t are provided also in a region overlapping with the light-emitting device 130. Note that in FIG. 4A, an opening is provided in part of the insulating layer 105, and a connection portion where the conductive layer 104t and the conductive layer 106t are electrically connected to each other through the opening is also illustrated.

The conductive layer 104t and the conductive layer 106t each contain a conductive material which has a property of transmitting visible light. For the conductive layer 104t and the conductive layer 106t, a material having a light-transmitting property with respect to at least light emitted from the light-emitting device 130 can be used.

Since the conductive layer 104t and the conductive layer 106t each have a light-transmitting property, they can be provided to overlap with the light-emitting device 130. Accordingly, the layout flexibility of the conductive layer 104t and the conductive layer 106t serving as electrodes of the touch sensor can be increased.

The display apparatus using a light-transmitting conductive film as the electrode of the touch sensor is not limited to the display apparatus illustrated in FIG. 4A. For example, as illustrated in FIG. 4B, a structure where the conductive layer 104t and the conductive layer 106t each having a light-transmitting property are used as electrodes of the touch sensor may be employed in the display apparatus illustrated in FIG. 3A.

Note that in the display apparatus 100 illustrated in each of FIG. 4A and FIG. 4B, any one of the conductive layer 104t and the conductive layer 106t may be replaced with a conductive layer containing a metal or an alloy. In that case, a light-transmitting conductive layer can be provided to overlap with the light-emitting device 130, and the conductive layer containing a metal or an alloy can be provided at a position not overlapping with the light-emitting device 130. When a low-resistance conductive layer is used as part of the conductive layer included in the touch sensor, the electric resistance can be reduced and the sensitivity can be improved.

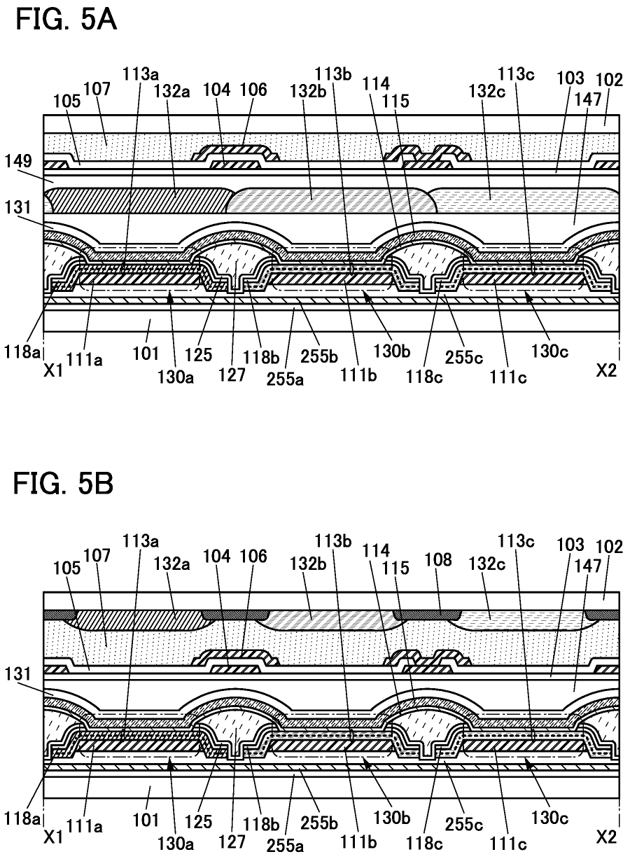

An example of a case where coloring layers are provided to overlap with subpixels is described with reference to FIG. 5A and FIG. 5B.

The display apparatus illustrated in FIG. 5A is different from the display apparatus illustrated in FIG. 1B in that a coloring layer 132a is provided to overlap with the light-emitting device 130a, a coloring layer 132b is provided to overlap with the light-emitting device 130b, and a coloring layer 132c is provided to overlap with the light-emitting device 130c. Hereinafter, the coloring layer 132a to the coloring layer 132c are collectively referred to as a “coloring layer 132” in some cases.

In the display apparatus illustrated in FIG. 5A, the coloring layer 132a, the coloring layer 132b, and the coloring layer 132c are provided over the resin layer 147, and a resin layer 149 is provided to cover the coloring layer 132a, the coloring layer 132b, and the coloring layer 132c. Note that the resin layer 149 preferably contains an organic insulating material like the resin layer 147. The insulating layer 103 is provided over the resin layer 149. Here, the coloring layer 132a, the coloring layer 132b, and the coloring layer 132c are provided between the light-emitting device 130 and the touch sensor, for example, only need to be provided between the common electrode 115 and the insulating layer 105.

The coloring layer 132a can transmit at least part of light in a wavelength range emitted from the light-emitting device 130a, the coloring layer 132b can transmit at least part of light in a wavelength range emitted from the light-emitting device 130b, and the coloring layer 132c can transmit at least part light in a wavelength range emitted from the light-emitting device 130c. For example, in the case where the light-emitting device 130a emits red light, the light-emitting device 130b emits green light, and the light-emitting device 130c emits blue light, a structure can be employed where the coloring layer 132a has a function of transmitting light with intensity in a red wavelength range, the coloring layer 132b has a function of transmitting light with intensity in a green wavelength range, and the coloring layer 132c has a function of transmitting light with intensity in a blue wavelength range.

By providing the coloring layer 132 as described above, reflection of external light can be significantly reduced. Moreover, when the light-emitting device has a microcavity structure, reflection of external light can be further reduced. By reducing reflection of external light in this manner, reflection of external light can be sufficiently suppressed without using an optical member such as a circularly polarizing plate for the display apparatus illustrated in FIG. 5A. Since a circularly polarizing plate is not used for the display apparatus, attenuation of light emitted from the light-emitting device 130 can be reduced, leading to lowering the power consumption of the display apparatus.

The adjacent coloring layers 132 preferably include an overlapping region. Specifically, a region not overlapping with the light-emitting device 130 preferably includes the region where the adjacent coloring layers 132 overlap with each other. For example, as illustrated in FIG. 5A, the coloring layer 132a is provided to overlap with part of the coloring layer 132b in a region interposed between the light-emitting device 130a and the light-emitting device 130b. In that case, a portion where the coloring layer 132a and the coloring layer 132b overlap with each other preferably overlaps with the insulating layer 127. Note that the same applies to the coloring layer 132a and the coloring layer 132c, and the coloring layer 132b and the coloring layer 132c.

In this manner, when the coloring layers 132 that transmit light of different colors overlap with each other, the coloring layers 132 in the region where the coloring layers 132 overlap with each other can function as light-blocking layers. This can further reduce reflection of external light. Without being limited thereto, a structure may be employed where a light-blocking layer is provided between adjacent coloring layers. In that case, the light-blocking layer preferably overlaps with the insulating layer 127. For the light-blocking layer, a material similar to that for the light-blocking layer 108 can be used.

As illustrated in FIG. 5A, the coloring layer 132 is preferably provided in contact with the top surface of the resin layer 147 functioning as a planarization film. Owing to this, the coloring layer 132 can be formed on a surface with high planarity; thus, the coloring layer 132 can be inhibited from having unevenness depending on the formation surface. Thus, diffused reflection of part of light emitted from the light-emitting device 130 at the unevenness of the coloring layer 132 can be reduced, so that display quality of the display apparatus can be improved. By providing the resin layer 147 over the protective layer 131, even the case where a defect such as a pinhole exists in the protective layer 131, for example, the defect can be filled with the resin layer 147 with high step coverage.

Although FIG. 5A illustrates the structure where the coloring layer 132 is provided between the light-emitting device 130 and the touch sensor, the present invention is not limited thereto. For example, as illustrated in FIG. 5B, a structure may be employed where the coloring layer 132 is provided over the touch sensor.

In this case, as illustrated in FIG. 5B, a structure can be employed where the coloring layers 132a, 132b, and 132c are provided in contact with the substrate 102. Here, the coloring layer 132 is provided in contact with the substrate 102 and the adhesive layer 107. The light-blocking layer 108 may be provided between the coloring layers 132. The coloring layer 132 is preferably provided to overlap with part of the light-blocking layer 108. Since the resin layer 149 is not necessarily provided in the display apparatus illustrated in FIG. 5B, the size of the display apparatus can be reduced.

### [Variation Example 2 of Display Apparatus]

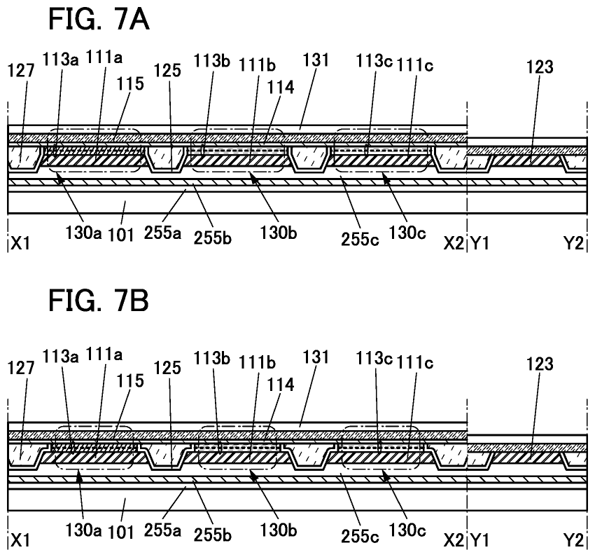

Next, variation examples of the display apparatus 100 in which structures of a display portion and a connection portion are changed are described with reference to FIG. 7A to FIG. 9C. Here, FIG. 7A to FIG. 9C each correspond to a cross-sectional view taken along the dashed-dotted line X1-X2 and a cross-sectional view taken along the dashed-dotted line Y1-Y2 in FIG. 1A. In FIG. 7A to FIG. 9C, a structure above the protective layer 131 is not illustrated. A touch sensor with a structure illustrated in FIG. 1B, FIG. 3A to FIG. 4B, and the like can be provided as appropriate above the protective layer 131.

FIG. 7A illustrates an example in which the end portion of the top surface of the pixel electrode 111a and the end portion of the first layer 113a are aligned or substantially aligned with each other. FIG. 7A illustrates an example in which the end portion of the first layer 113a is positioned inward from the end portion of the bottom surface of the pixel electrode 111a. FIG. 7B illustrates an example in which the end portion of the first layer 113a is positioned inward from the end portion of the top surface of the pixel electrode 111a. In FIG. 7A and FIG. 7B, the end portion of the first layer 113a is positioned over the pixel electrode 111a.

As illustrated in FIG. 7A and FIG. 7B, in the case where the end portion of the first layer 113a is positioned over the pixel electrode 111a, a reduction in the thickness of the first layer 113a at or near the end portion of the pixel electrode 111a can be inhibited to make the thickness of the first layer 113a uniform.

In the case where end portions are aligned or substantially aligned with each other and the case where top surface shapes are the same or substantially the same, it can be said that outlines of stacked layers at least partly overlap with each other in a top view. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “end portions are substantially aligned with each other” or “top surface shapes are substantially the same”.

The end portion of the first layer 113a may have both a portion positioned outward from the end portion of the pixel electrode 111a and a portion positioned inward from the end portion of the pixel electrode 111a.

As illustrated in FIG. 7A and FIG. 7B, the side surfaces of the pixel electrodes 111a, 111b, and 111c, the first layer 113a, the second layer 113b, and the third layer 113c are covered with the insulating layer 125 and the insulating layer 127. Thus, the common layer 114 (or the common electrode 115) can be inhibited from being in contact with the side surfaces of the pixel electrodes 111a, 111b, and 111c, the first layer 113a, the second layer 113b, and the third layer 113c, whereby a short circuit of the light-emitting device can be inhibited. Thus, the reliability of the light-emitting device can be increased.

Also in the display apparatuses illustrated in FIG. 7A and FIG. 7B, as in the above-described structure, at least part of the conductive layer 104 and part of the conductive layer 106 preferably overlap with a region interposed between two adjacent light-emitting devices or a region interposed between two adjacent EL layers. Furthermore, at least part of the conductive layer 104 and part of the conductive layer 106 preferably include a region overlapping with the insulating layer 127. With such a structure, a touch sensor can be provided while a high aperture ratio of the display apparatus is maintained.

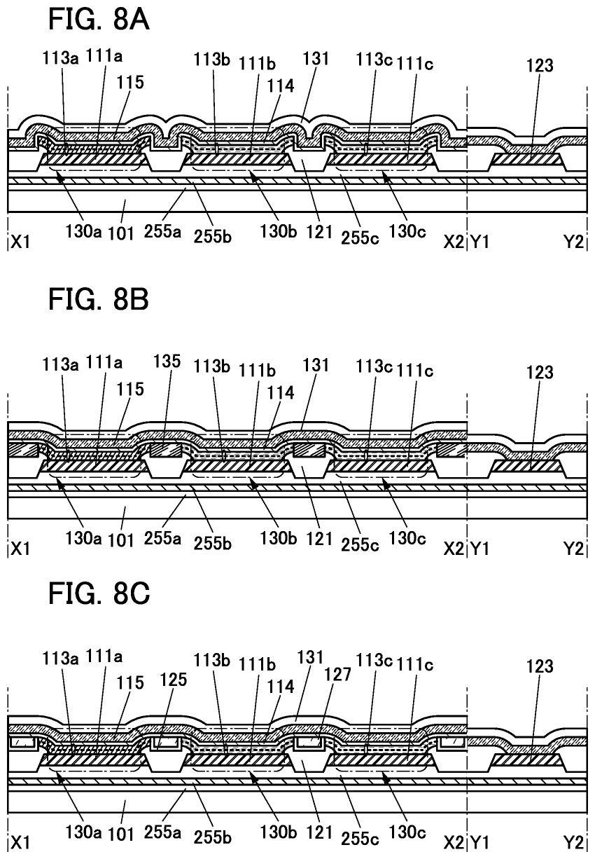

As illustrated in FIG. 8A to FIG. 8C, the insulating layer 121 covering the end portions of the top surfaces of the pixel electrodes 111a, 111b, and 111c may be provided. The first layer 113a, the second layer 113b, and the third layer 113c can each have a structure where a portion that is over and in contact with the pixel electrode and a portion that is over and in contact with the insulating layer 121. The insulating layer 121 can have a single-layer structure or a stacked-layer structure using one or both of an inorganic insulating film and an organic insulating film.

Examples of an organic insulating material that can be used for the insulating layer 121 include an acrylic resin, an epoxy resin, a polyimide resin, a polyamide resin, a polyimide-amide resin, a polysiloxane resin, a benzocyclobutene-based resin, and a phenol resin. As an inorganic insulating film that can be used as the insulating layer 121, the inorganic insulating film that can be used as the protective layer 131 can be used.

When an inorganic insulating film is used as the insulating layer 121, impurities are less likely to enter the light-emitting devices than the case of using an organic insulating film; thus, the reliability of the light-emitting devices can be improved. Furthermore, the insulating layer 121 can be thinner, so that high resolution can be easily achieved. Meanwhile, when an organic insulating film is used as the insulating layer 121, higher step coverage than the case of using an inorganic insulating film can be obtained; thus, an influence of the shape of the pixel electrodes can be small. Therefore, a short circuit in the light-emitting devices can be prevented. Specifically, when an organic insulating film is used as the insulating layer 121, the insulating layer 121 can be processed into a tapered shape or the like.

Note that the insulating layer 121 is not necessarily provided. The aperture ratio of subpixel can be sometimes increased without providing the insulating layer 121. Alternatively, the distance between subpixels can be shortened and the resolution or the definition of the display apparatus can be sometimes increased.

Note that FIG. 8A illustrates an example in which the common layer 114 is formed over the insulating layer 121 in a region between the first layer 113a and the second layer 113b, a region between the second layer 113b and the third layer 113c, and the like. As illustrated in FIG. 8B, a gap 135 may be formed in the region.

The gap 135 contains, for example, any one or more selected from air, nitrogen, oxygen, carbon dioxide, and Group 18 elements (typified by helium, neon, argon, xenon, and krypton, for example). Alternatively, a resin or the like may fill the gap 135.

As illustrated in FIG. 8C, the insulating layer 125 may be provided to cover a top surface of the insulating layer 121 and the side surfaces of the first layer 113a, the second layer 113b, and the third layer 113c, and the insulating layer 127 may be provided over the insulating layer 125.

Also in the display apparatuses illustrated in FIG. 8A to FIG. 8C, as in the above-described structure, at least part of the conductive layer 104 and part of the conductive layer 106 preferably overlap with a region interposed between two adjacent light-emitting devices or a region interposed between two adjacent EL layers. Furthermore, at least part of the conductive layer 104 and part of the conductive layer 106 preferably include a region overlapping with the insulating layer 121. With such a structure, a touch sensor can be provided while a high aperture ratio of the display apparatus is maintained.

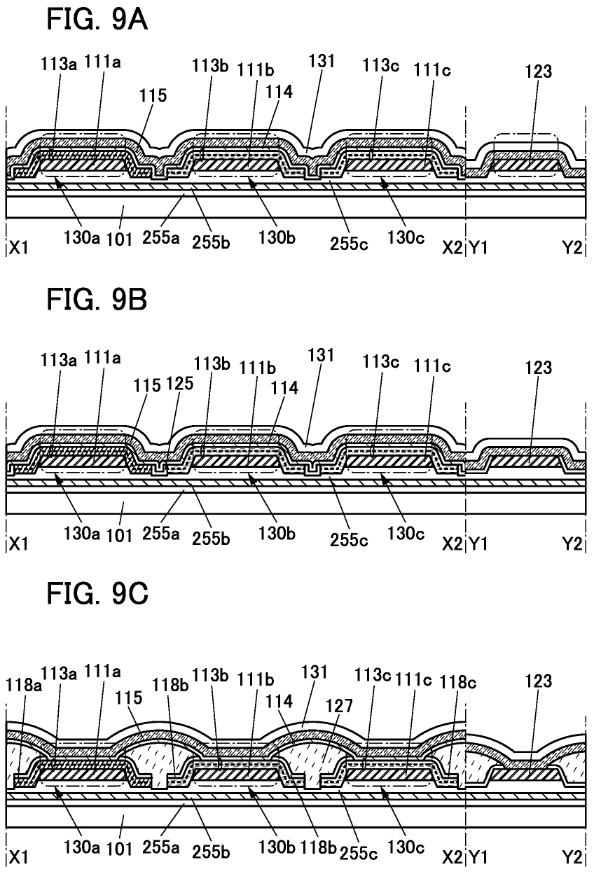

Note that as illustrated in FIG. 9A, the display apparatus does not necessarily include the insulating layer 125 and the insulating layer 127. FIG. 9A illustrates an example in which the common layer 114 is provided in contact with a top surface of the insulating layer 255c and the side and top surfaces of the first layer 113a, the second layer 113b, and the third layer 113c. Note that as illustrated in FIG. 8B, the gap 135 may be provided in the region between the first layer 113a and the second layer 113b, the region between the second layer 113b and the third layer 113c, and the like.

Note that one of the insulating layer 125 and the insulating layer 127 is not necessarily provided. When the insulating layer 125 having a single-layer structure using an inorganic material is formed, for example, the insulating layer 125 can be used as a protective insulating layer for the EL layer. Thus, the reliability of the display apparatus can be improved. For another example, when the insulating layer 127 having a single-layer structure using an organic material is formed, the insulating layer 127 can fill a gap between adjacent island-shaped EL layers for planarization. In this way, the coverage with the common electrode 115 (upper electrode) formed over the island-shaped EL layer and the insulating layer 127 can be increased.

FIG. 9B illustrates an example of a case where the insulating layer 127 is not provided. Note that although FIG. 9B illustrates an example in which the common layer 114 is provided in the depressed portion of the insulating layer 125, gaps may be formed in the regions.

The insulating layer 125 includes a region in contact with the side surface of the island-shaped EL layer and functions as a protective insulating layer for the EL layer. By providing the insulating layer 125, entry of impurities (e.g., oxygen and moisture) from the side surface of the island-shaped EL layer into its inside can be inhibited, and thus a highly reliable display apparatus can be obtained.

FIG. 9C illustrates an example of a case where the insulating layer 125 is not provided. In the case where the insulating layer 125 is not provided, the insulating layer 127 can be in contact with the side surface of the island-shaped EL layer. The insulating layer 127 can be provided to fill gaps between the island-shaped EL layers included in the light-emitting devices.

In this case, an organic material that causes less damage to the EL layer is preferably used for the insulating layer 127. For example, for the insulating layer 127, it is preferable to use an organic material such as polyvinyl alcohol (PVA), polyvinyl butyral, polyvinyl pyrrolidone, polyethylene glycol, polyglycerin, pullulan, water-soluble cellulose, or alcohol-soluble polyamide resin.

Also in the display apparatuses illustrated in FIG. 9A to FIG. 9C, as in the above-described structure, at least part of the conductive layer 104 and part of the conductive layer 106 preferably overlap with a region interposed between two adjacent light-emitting devices or a region interposed between two adjacent EL layers. With such a structure, a touch sensor can be provided while a high aperture ratio of the display apparatus is maintained.

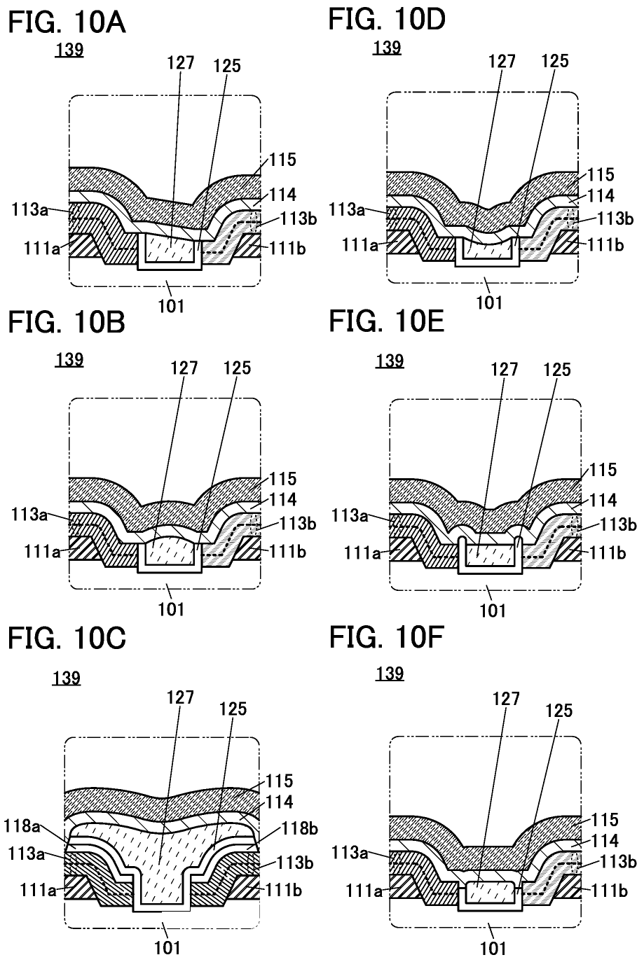

FIG. 10A to FIG. 10F each illustrate a cross-sectional structure of a region 139 including the insulating layer 127 and its surroundings.

FIG. 10A illustrates an example in which the first layer 113a and the second layer 113b have different thicknesses. The height of the top surface of the insulating layer 125 agrees with or substantially agrees with the height of the top surface of the first layer 113a on the first layer 113a side, and agrees with or substantially agrees with the height of top surface of the second layer 113b on the second layer 113b side. The top surface of the insulating layer 127 has a gentle slope such that the side closer to the first layer 113a is higher and the side closer to the second layer 113b is lower. In this manner, the heights of the insulating layer 125 and the insulating layer 127 preferably agree with the heights of the top surfaces of the adjacent EL layers. Alternatively, the heights of the insulating layer 125 and the insulating layer 127 may agree with the height of the top surface of any adjacent EL layer so that their top surfaces have a flat portion.

In FIG. 10B, the top surface of the insulating layer 127 includes a region whose height is higher than the heights of the top surface of the first layer 113a and the top surface of the second layer 113b. As illustrated in FIG. 10B, it can be said that the top surface of the insulating layer 127 has a shape that is bulged in the center and its vicinity, i.e., a shape including a convex curved surface, in a cross-sectional view.

In a cross-sectional view of FIG. 10C, the top surface of the insulating layer 127 has a shape that is gently bulged toward the center, i.e., has a convex curved surface, and has a shape that is recessed in the center and its vicinity, i.e., has a concave curved surface. The insulating layer 127 includes a region whose height is higher than the heights of the top surface of the first layer 113a and the top surface of the second layer 113b. The region 139 of the display apparatus includes a region where the first layer 113a, the mask layer 118a, the insulating layer 125, and the insulating layer 127 are stacked in this order. The region 139 of the display apparatus includes a region where the second layer 113b, the mask layer 118b, the insulating layer 125, and the insulating layer 127 are stacked in this order.

In FIG. 10D, the top surface of the insulating layer 127 includes a region whose height is lower than the heights of the top surface of the first layer 113a and the top surface of the second layer 113b. In a cross-sectional view, the top surface of the insulating layer 127 has a shape such that its center and the vicinity thereof are recessed, i.e., a shape including a concave curved surface.

In FIG. 10E, the top surface of the insulating layer 125 includes a region whose height is higher than the heights of the top surface of the first layer 113a and the top surface of the second layer 113b. That is, the insulating layer 125 protrudes from the formation surface of the common layer 114 and forms a projected portion.

In formation of the insulating layer 125, for example, in the case where the insulating layer 125 is formed so that its height agrees with or substantially agrees with the height of the mask layer, a shape such that the insulating layer 125 protrudes is sometimes formed as illustrated in FIG. 10E.

In FIG. 10F, the top surface of the insulating layer 125 includes a region whose height is lower than the heights of the top surface of the first layer 113a and the top surface of the second layer 113b. That is, the insulating layer 125 forms a depressed portion on the formation surface of the common layer 114.

As described above, the insulating layer 125 and the insulating layer 127 can have a variety of shapes.

The display apparatus of one embodiment of the present invention has a structure where at least part of an electrode of a touch sensor overlaps with a region interposed between two adjacent light-emitting devices or a region interposed between two adjacent EL layers. Furthermore, at least part of an electrode of a touch sensor preferably includes a region overlapping with an organic resin film provided between two adjacent EL layers. With such a structure, a touch sensor can be provided while a high aperture ratio of the display apparatus is maintained. Thus, a display apparatus with both a high aperture ratio and a high resolution can be provided.

This embodiment can be combined with the other embodiments as appropriate.

### Embodiment 2

In this embodiment, a structure example of a light-emitting device that can be used in a display apparatus of one embodiment of the present invention is described.

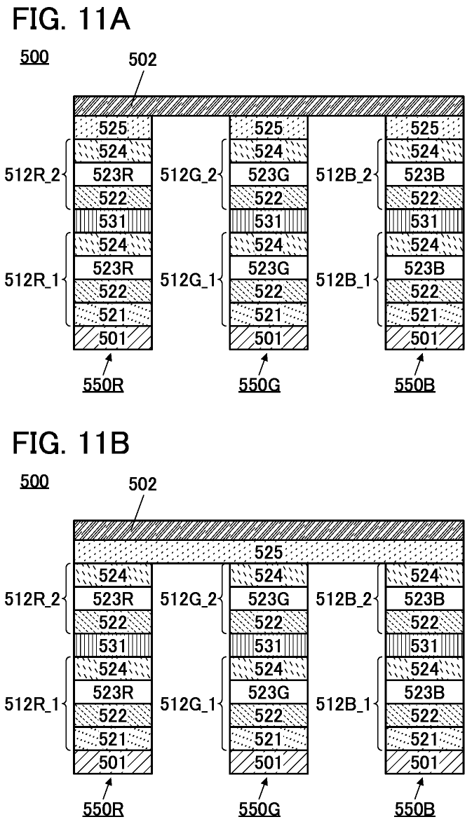

FIG. 11A illustrates a schematic cross-sectional view of a display apparatus 500. The display apparatus 500 includes a light-emitting device 550R that emits red light, a light-emitting device 550G that emits green light, and a light-emitting device 550B that emits blue light.

The light-emitting device 550R has a structure in which between a pair of electrodes (an electrode 501 and an electrode 502), two light-emitting units (a light-emitting unit 512R_1 and a light-emitting unit 512R_2) are stacked with a charge-generation layer 531 therebetween. Similarly, the light-emitting device 550G includes a light-emitting unit 512G_1, the charge-generation layer 531, and a light-emitting unit 512G_2 between the pair of electrodes, and the light-emitting device 550B includes a light-emitting unit 512B_1, the charge-generation layer 531, and a light-emitting unit 512B_2 between the pair of electrodes.

The electrode 501 functions as a pixel electrode and is provided in every light-emitting device. The electrode 502 functions as a common electrode and is shared by a plurality of light-emitting devices.

As illustrated in FIG. 11A, the light-emitting unit 512R_1 includes a layer 521, a layer 522, a light-emitting layer 523R, and a layer 524. The light-emitting unit 512R_2 includes the layer 522, the light-emitting layer 523R, and the layer 524. The light-emitting device 550R includes a layer 525 between the light-emitting unit 512R_2 and the electrode 502. Note that the layer 525 can also be regarded as part of the light-emitting unit 512R_2.

In the case where the electrode 501 functions as an anode and the electrode 502 functions as a cathode, the layer 521 includes, for example, a layer containing a substance with a high hole-injection property (a hole-injection layer). The layer 522 includes, for example, one or both of a layer containing a substance with a high hole-transport property (a hole-transport layer) and a layer containing a substance with a high electron-blocking property (an electron-blocking layer). The layer 524 includes, for example, one or both of a layer containing a substance with a high electron-transport property (an electron-transport layer) and a layer containing a substance with a high hole-blocking property (a hole-blocking layer). The layer 525 includes, for example, a layer containing a substance with a high electron-injection property (an electron-injection layer).

In the case where the electrode 501 functions as a cathode and the electrode 502 functions as an anode, for example, the layer 521 includes an electron-injection layer, the layer 522 includes one or both of an electron-transport layer and a hole-blocking layer, the layer 524 includes one or both of a hole-transport layer and an electron-blocking layer, and the layer 525 includes a hole-injection layer.

Note that the structure (material, thickness, and the like) of each of the layer 522, the light-emitting layer 523R, and the layer 524 may be the same or different between the light-emitting unit 512R_1 and the light-emitting unit 512R_2.

FIG. 11A illustrates the layer 521 and the layer 522 separately; however, one embodiment of the present invention is not limited thereto. For example, the layer 522 may be omitted when the layer 521 has functions of both a hole-injection layer and a hole-transport layer or the layer 521 has functions of both an electron-injection layer and an electron-transport layer.

In the case of manufacturing a light-emitting device with a tandem structure, two light-emitting units are stacked with the charge-generation layer 531 therebetween. The charge-generation layer 531 includes at least a charge-generation region. The charge-generation layer 531 has a function of injecting electrons into one of the light-emitting unit 512R_1 and the light-emitting unit 512R_2 and injecting holes into the other when voltage is applied between the electrode 501 and the electrode 502.

The light-emitting layer 523R included in the light-emitting device 550R contains a light-emitting substance (also referred to as a light-emitting material) that emits red light, a light-emitting layer 523G included in the light-emitting device 550G contains a light-emitting substance that emits green light, and a light-emitting layer 523B included in the light-emitting device 550B contains a light-emitting substance that emits blue light. Note that the light-emitting device 550G and the light-emitting device 550B have a structure in which the light-emitting layer 523R included in the light-emitting device 550R is replaced with the light-emitting layer 523G and the light-emitting layer 523B, respectively, and the other components are similar to those of the light-emitting device 550R.

Note that the structure (material, thickness, and the like) of each of the layer 521, the layer 522, the layer 524, and the layer 525 may be the same between the light-emitting devices of two or more colors or among the light-emitting devices of all colors, or different from one another among the light-emitting devices of all colors.

A structure in which a plurality of light-emitting units are connected in series with the charge-generation layer 531 therebetween as in the light-emitting device 550R, the light-emitting device 550G, and the light-emitting device 550B is referred to as a tandem structure in this specification. By contrast, a structure in which one light-emitting unit is included between a pair of electrodes is referred to as a single structure. Note that a tandem structure may be referred to as a stack structure. The tandem structure enables a light-emitting device capable of high-luminance light emission. Furthermore, the tandem structure can reduce the amount of current needed for obtaining the same luminance as compared with the single structure; thus, the reliability of the light-emitting device can be improved.

The light-emitting device 550R, the light-emitting device 550G, and the light-emitting device 550B have an SBS structure in which at least light-emitting layers are separately formed for light-emitting devices. The SBS structure allows optimization of materials and structures of light-emitting devices and thus can extend freedom of choice of the materials and the structures, which makes it easy to improve the luminance and the reliability.

The display apparatus 500 of one embodiment of the present invention employs a light-emitting device with a tandem structure and has the SBS structure. Thus, the display apparatus 500 can take advantages of both the tandem structure and the SBS structure. In the light-emitting devices included in the display apparatus 500 illustrated in FIG. 11A, a structure where two light-emitting units are formed in series is employed, and this structure may be referred to as a two-unit tandem structure. In addition, in the light-emitting device 550R with a two-unit tandem structure illustrated in FIG. 11A, a structure is employed where a second light-emitting unit including a red-light-emitting layer is stacked over a first light-emitting unit including a red-light-emitting layer. Similarly, in the light-emitting device 550G with a two-unit tandem structure illustrated in FIG. 11A, a structure is employed where a second light-emitting unit including a green-light-emitting layer is stacked over a first light-emitting unit including a green-light-emitting layer, and in the light-emitting device 550B, a structure is employed where a second light-emitting unit including a blue-light-emitting layer is stacked over a first light-emitting unit including a blue-light-emitting layer.

FIG. 11B is a variation example of the display apparatus 500 illustrated in FIG. 11A. The display apparatus 500 illustrated in FIG. 11B is an example in which the layer 525 is shared by a plurality of light-emitting devices, like the electrode 502. In this case, the layer 525 can be referred to as a common layer. By providing one or more common layers among a plurality of light-emitting devices in this manner, the manufacturing process can be simplified, resulting in a reduction in manufacturing cost.

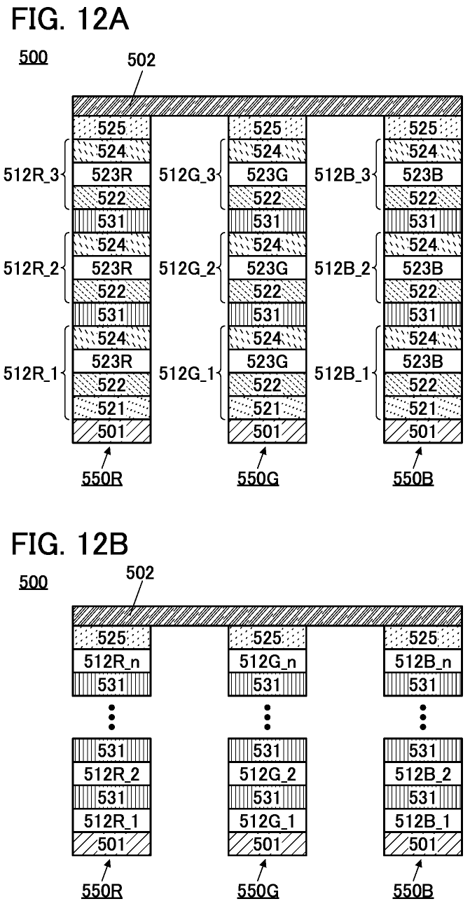

The display apparatus 500 illustrated in FIG. 12A is an example in which three light-emitting units are stacked. In the light-emitting device 550R in FIG. 12A, a light-emitting unit 512R_3 is further stacked over the light-emitting unit 512R_2 with the charge-generation layer 531 therebetween. The light-emitting unit 512R_3 has a structure similar to that of the light-emitting unit 512R_2. The same applies to a light-emitting unit 512G_3 included in the light-emitting device 550G and a light-emitting unit 512B_3 included in the light-emitting device 550B. Note that in the case where the light-emitting device includes a plurality of charge-generation layers 531, two or more or all of the plurality of charge-generation layers 531 may have the same structure (material, thickness, and the like) or different structures.

FIG. 12B illustrates an example of a case where n light-emitting units (n is an integer greater than or equal to 2) are stacked.

When the number of stacked light-emitting units is increased in the above manner, luminance obtained from the light-emitting device with the same amount of current can be increased in accordance with the number of stacked layers. Moreover, increasing the number of stacked light-emitting units can reduce current necessary for obtaining the same luminance; thus, power consumption of the light-emitting device can be reduced in accordance with the number of stacked layers.

Next, materials that can be used for the light-emitting device is described.

A conductive film transmitting visible light is used as the electrode through which light is extracted, which is either the electrode 501 or the electrode 502. A conductive film that reflects visible light is preferably used as the electrode through which light is not extracted. In the case where a display apparatus includes a light-emitting device emitting infrared light, it is preferable that a conductive film transmitting visible light and infrared light be used as the electrode through which light is extracted, and a conductive film reflecting visible light and infrared light be used as the electrode through which light is not extracted.

A conductive film transmitting visible light may be used as the electrode through which light is not extracted. In that case, the electrode is preferably provided between a reflective layer and the light-emitting unit that is the closest to the reflective layer. In other words, light emitted by the light-emitting device may be reflected by the reflective layer to be extracted from the display apparatus.

As a material that forms the pair of electrodes of the light-emitting device, a metal, an alloy, an electrically conductive compound, a mixture thereof, and the like can be used as appropriate. Specifically, as the material, a metal such as aluminum, magnesium, titanium, chromium, manganese, iron, cobalt, nickel, copper, gallium, zinc, indium, tin, molybdenum, tantalum, tungsten, palladium, gold, platinum, silver, yttrium, or neodymium, or an alloy containing an appropriate combination of any of these metals can be given. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Alternatively, as the material, an element belonging to Group 1 or Group 2 of the periodic table, which is not described above as an example (e.g., lithium, cesium, calcium, or strontium), a rare earth metal such as europium or ytterbium, an alloy containing an appropriate combination of any of these, graphene, or the like can be given.

The light-emitting devices preferably employ a microcavity structure. Thus, one of the pair of electrodes included in the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

The transflective electrode can also have a stacked-layer structure of a conductive layer that can be used as a reflective electrode and a conductive layer that can be used as an electrode having a visible-light-transmitting property (also referred to as a transparent electrode).

The light transmittance of the transparent electrode is higher than or equal to 40%. For example, an electrode having a visible light (light at wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity less than or equal to 1×10⁻² Ωcm.

The light-emitting device includes at least a light-emitting layer. In addition, the light-emitting device may further include, as a layer other than the light-emitting layer, a layer containing a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance exhibiting an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for a hole-transport layer and will be described later. As the electron-transport material, it is possible to use a material with a high electron-transport property which can be used for an electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With this structure, high efficiency, low-voltage driving, and a long lifetime of a light-emitting device can be achieved at the same time.

The hole-injection layer is a layer that injects holes from an anode to the hole-transport layer and contains a material with a high hole-injection property. Examples of a material with a high hole-injection property include an aromatic amine compound and a composite material containing a hole-transport material and an acceptor material (electron-accepting material).

As the hole-transport material, it is possible to use a material with a high hole-transport property which can be used for a hole-transport layer and will be described later.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. An organic acceptor material containing fluorine can also be used. Alternatively, organic acceptor materials such as a quinodimethane derivative, a chloranil derivative, and a hexaazatriphenylene derivative can be used.

For example, a hole-transport material and a material containing an oxide of a metal belonging to any of Group 4 to Group 8 of the periodic table (typically, molybdenum oxide) may be used as the material with a high hole-injection property.

A hole-transport layer is a layer transporting holes, which are injected from an anode by a hole-injection layer, to a light-emitting layer. The hole-transport layer is a layer that contains a hole-transport material. As the hole-transport material, a substance having a hole mobility greater than or equal to 1×10⁻⁶ cm²/Vs is preferable. Note that other substances can also be used as long as they have a property of transporting more holes than electrons. As the hole-transport material, materials with a high hole-transport property, such as a π-electron rich heteroaromatic compound (e.g., a carbazole derivative, a thiophene derivative, and a furan derivative) and an aromatic amine (a compound having an aromatic amine skeleton), are preferable.

The electron-blocking layer is provided in contact with the light-emitting layer. The electron-blocking layer is a layer that has a hole-transport property and contains a material capable of blocking electrons. Any of the materials having an electron-blocking property among the above hole-transport materials can be used for the electron-blocking layer.

The electron-blocking layer has a hole-transport property, and thus can also be referred to as a hole-transport layer. A layer having an electron-blocking property among the hole-transport layers can also be referred to as an electron-blocking layer.

An electron-transport layer is a layer transporting electrons, which are injected from a cathode by an electron-injection layer, to a light-emitting layer. The electron-transport layer is a layer that contains an electron-transport material. As the electron-transport material, a substance having an electron mobility greater than or equal to 1×10⁻⁶ cm²/Vs is preferable. Note that other substances can also be used as long as they have a property of transporting more electrons than holes. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound such as a nitrogen-containing heteroaromatic compound.

The hole-blocking layer is provided in contact with the light-emitting layer. The hole-blocking layer is a layer that has an electron-transport property and contains a material capable of blocking holes. Any of the materials having a hole-blocking property among the above electron-transport materials can be used for the hole-blocking layer.

The hole-blocking layer has an electron-transport property, and thus can also be referred to as an electron-transport layer. A layer having a hole-blocking property among the electron-transport layers can also be referred to as a hole-blocking layer.

An electron-injection layer is a layer that injects electrons from a cathode to an electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

A difference between the LUMO level of the material with a high electron-injection property and the work function value of the material used for a cathode is preferably small (specifically, smaller than or equal to 0.5 eV).

For the electron-injection layer, an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate can be used, for example. The electron-injection layer may have a stacked-layer structure of two or more layers. The stacked-layer structure can be, for example, a structure where lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of an organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer containing a material with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the electron-injection layer can be suitably used for the electron-injection buffer layer.

The charge-generation layer preferably includes a layer containing a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

Note that there is no particular limitation on the light-emitting material of the light-emitting layer in the display apparatus 500 illustrated in FIG. 11A. For example, in FIG. 11A, a structure where the two light-emitting layers 523R included in the light-emitting device 550R each contain a phosphorescent material, the two light-emitting layers 523G included in the light-emitting device 550G each contain a fluorescent material, and the two light-emitting layers 523B included in the light-emitting device 550B each contain a fluorescent material can be employed.

Alternatively, in FIG. 11A, a structure where the two light-emitting layers 523R included in the light-emitting device 550R each contain a phosphorescent material, the two light-emitting layers 523G included in the light-emitting device 550G each contain a phosphorescent material, and the two light-emitting layers 523B included in the light-emitting device 550B each contain a fluorescent material can be employed.

In the display apparatus of one embodiment of the present invention, a structure where a fluorescent material is used for all the light-emitting layers included in the light-emitting devices 550R, 550G, and 550B or a structure where a phosphorescent material is used for all the light-emitting layers included in the light-emitting devices 550R, 550G, and 550B may be employed.

Alternatively, in FIG. 11A, a structure where the light-emitting layer 523R included in the light-emitting unit 512R_1 contains a phosphorescent material and the light-emitting layer 523R included in the light-emitting unit 512R_2 contains a fluorescent material, or a structure where the light-emitting layer 523R included in the light-emitting unit 512R_1 contains a fluorescent material and the light-emitting layer 523R included in the light-emitting unit 512R_2 contains a phosphorescent material, i.e., a structure where a light-emitting layer in a first unit and a light-emitting layer in a second unit contain different light-emitting materials may be employed. Note that although the light-emitting unit 512R_1 and the light-emitting unit 512R_2 are explicitly described here, and the same structure can also be applied to the light-emitting unit 512G_1 and the light-emitting unit 512G_2, and the light-emitting unit 512B_1 and the light-emitting unit 512B_2.

This embodiment can be combined with the other embodiments as appropriate.

### Embodiment 3

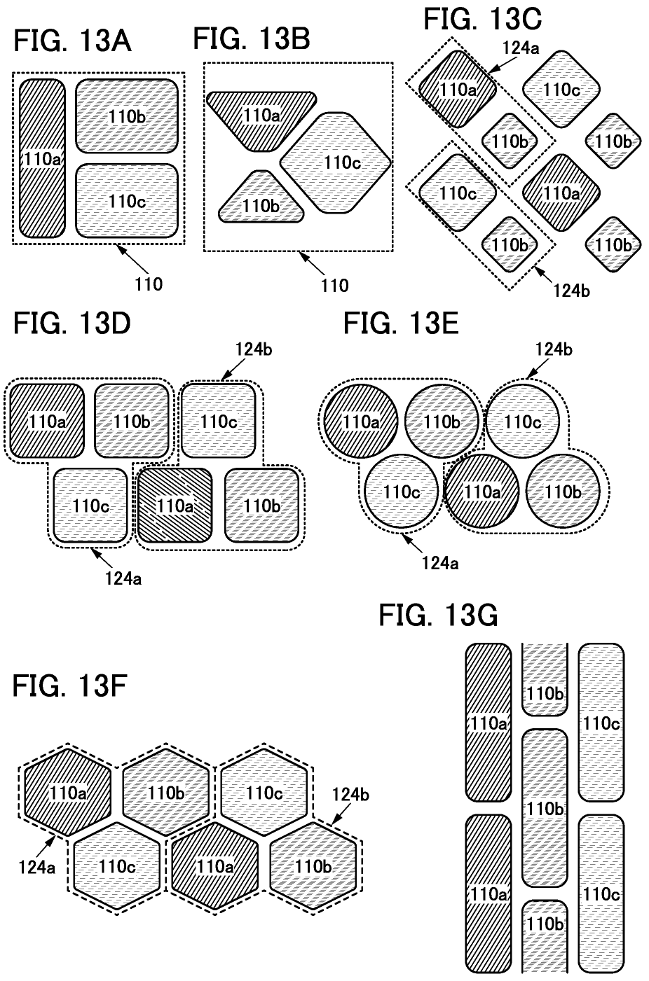

In this embodiment, a display apparatus of one embodiment of the present invention is described with reference to FIG. 13 to FIG. 15.

### [Pixel Layout]

In this embodiment, pixel layouts different from that in FIG. 1A are mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

The range of the circuit layout for forming the subpixels is not limited to the range of the subpixels illustrated in a diagram and may be placed outside the subpixels.

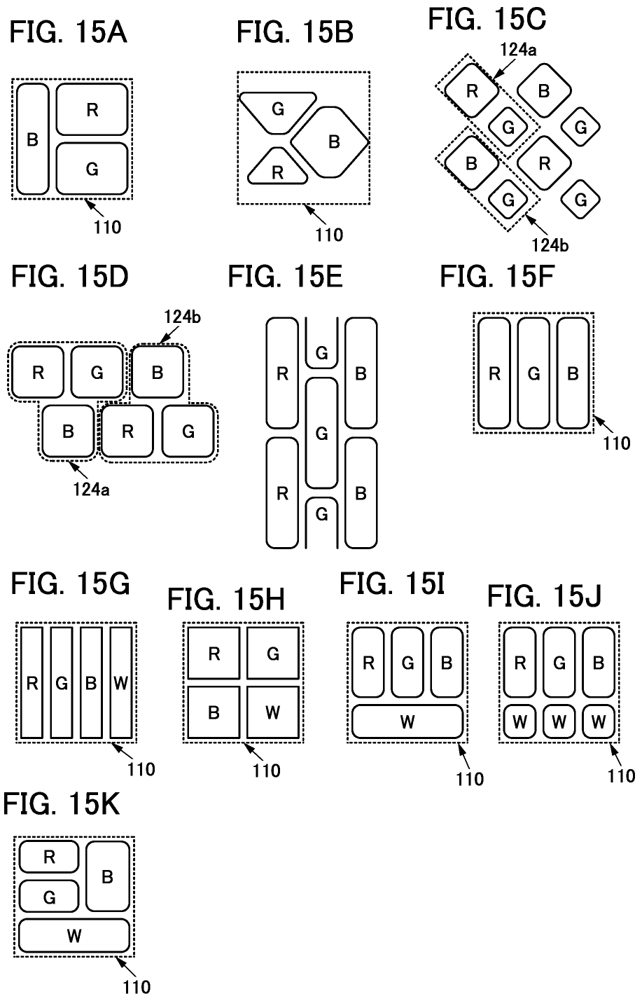

The pixel 110 illustrated in FIG. 13A employs S-stripe arrangement. The pixel 110 illustrated in FIG. 13A is composed of three subpixels 110a, 110b, and 110c. For example, as illustrated in FIG. 15A, the subpixel 110a may be a blue subpixel B, the subpixel 110b may be a red subpixel R, and the subpixel 110c may be a green subpixel G.

The pixel 110 illustrated in FIG. 13B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 15B, the subpixel 110a may be the green subpixel G, the subpixel 110b may be the red subpixel R, and the subpixel 110c may be the blue subpixel B.

Pixels 124a and 124b illustrated in FIG. 13C employ PenTile arrangement. FIG. 13C illustrates an example in which the pixels 124a each including the subpixel 110a and the subpixel 110b and the pixels 124b each including the subpixel 110b and the subpixel 110c are alternately arranged. For example, as illustrated in FIG. 15C, the subpixel 110a may be the red subpixel R, the subpixel 110b may be the green subpixel G, and the subpixel 110c may be the blue subpixel B.

The pixels 124a and 124b illustrated in FIG. 13D to FIG. 13F employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 15D, the subpixel 110a may be the red subpixel R, the subpixel 110b may be the green subpixel G, and the subpixel 110c may be the blue subpixel B.

FIG. 13D illustrates an example in which each subpixel has a rough tetragonal top surface shape with rounded corners, FIG. 13E illustrates an example in which each subpixel has a circular top surface shape, and FIG. 13F illustrates an example in which each subpixel has a rough hexagonal top surface shape with rounded corners.

In FIG. 13F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110a, three subpixels 110b and three subpixels 110c are arranged to surround the subpixel 110a, so that the subpixel 110a, the subpixel 110b, and the subpixel 110c are alternately arranged.

FIG. 13G illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. For example, as illustrated in FIG. 15E, the subpixel 110a may be the red subpixel R, the subpixel 110b may be the green subpixel G, and the subpixel 110c may be the blue subpixel B.

In a photolithography method, as a pattern to be formed by processing becomes finer, the influence of light diffraction becomes more difficult to ignore; accordingly, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel sometimes has a polygonal shape with rounded corners, an elliptical shape, a circular shape, or the like.

Furthermore, in the method for manufacturing the display apparatus of one embodiment of the present invention, the EL layer is processed into an island shape using a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of the resist material. An insufficiently cured resist film may have a shape different from a desired shape by processing. As a result, the top surface of the EL layer sometimes has a polygonal shape with rounded corners, an elliptical shape, a circular shape, or the like. For example, when a resist mask with a square top surface is intended to be formed, a resist mask with a circular top surface may be formed, and the top surface of the EL layer may be circular.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

Also in the pixel 110 illustrated in FIG. 1A, which employs stripe arrangement, for example, the subpixel 110a can be the red subpixel R, the subpixel 110b can be the green subpixel G, and the subpixel 110c can be the blue subpixel B as illustrated in FIG. 15F.

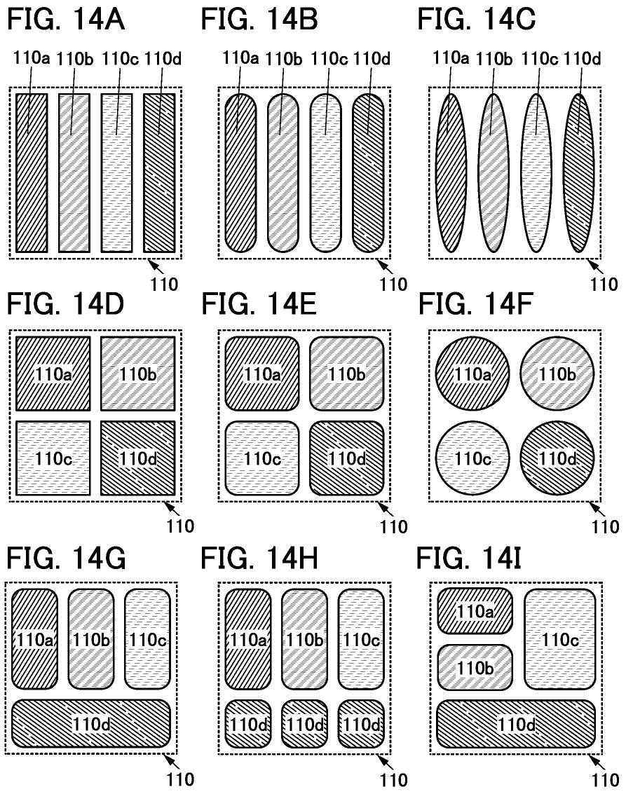

As illustrated in FIG. 14A to FIG. 14I, the pixel can include four types of subpixels.

The pixels 110 illustrated in FIG. 14A to FIG. 14C each employ stripe arrangement.

FIG. 14A illustrates an example in which each subpixel has a rectangular top surface shape, FIG. 14B illustrates an example in which each subpixel has a top surface shape formed by combining two half circles and a rectangle, and FIG. 14C illustrates an example in which each subpixel has an elliptical top surface shape.

The pixels 110 illustrated in FIG. 14D to FIG. 14F each employ matrix arrangement.

FIG. 14D illustrates an example in which each subpixel has a square top surface shape, FIG. 14E illustrates an example in which each subpixel has a rough square top surface shape with rounded corners, and FIG. 14F illustrates an example in which each subpixel has a circular top surface shape.

FIG. 14G and FIG. 14H each illustrate an example in which one pixel 110 is composed of two rows and three columns.

The pixel 110 illustrated in FIG. 14G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 14H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Aligning the positions of the subpixels in the upper row and the lower row as illustrated in FIG. 14H enables dust and the like that would be produced in the manufacturing process to be removed efficiently. Thus, a display apparatus with high display quality can be provided.

FIG. 14I illustrates an example where one pixel 110 is composed of three rows and two columns.

The pixel 110 illustrated in FIG. 14I includes the subpixel 110a in the upper row (first row), the subpixel 110b in the center row (second row), the subpixel 110c across the first row and the second row, and one subpixel (the subpixel 110d) in the lower row (third row). In other words, the pixel 110 includes the subpixels 110a and 110b in the left column (first column), the subpixel 110c in the right column (second column), and the subpixel 110d across these two columns.

The pixels 110 illustrated in FIG. 14A to FIG. 14I are each composed of the four subpixels 110a, 110b, 110c, and 110d. The subpixels 110a, 110b, 110c, and 110d include light-emitting devices that emit light of different colors. As the subpixels 110a, 110b, 110c, and 110d, subpixels of four colors of R, G, B, and white (W), subpixels of four colors of R, G, B, and Y, subpixels of R, G, B, and infrared light (IR), and the like can be given.

For example, as illustrated in FIG. 15G to FIG. 15K, the subpixel 110a can be the subpixel R emitting red light, the subpixel 110b can be the subpixel G emitting green light, the subpixel 110c can be the subpixel B emitting blue light, and the subpixel 110d can be a subpixel W emitting white light. Alternatively, the subpixel 110d can be a subpixel Y emitting yellow light or a subpixel IR emitting near-infrared light. In the case of such a structure, stripe arrangement is employed as the layout of R, G, and B in the pixels 110 illustrated in FIG. 14G and FIG. 14H, leading to higher display quality. In addition, what is called S-stripe arrangement is employed as the layout of R, G, and B in the pixel 110 illustrated in FIG. 14I, leading to higher display quality. Note that the number of types of subpixels is not limited to four, and five or more types of subpixels may be used.

As described above, the pixel composed of the subpixels each including the light-emitting device can employ any of a variety of layouts in the display apparatus of one embodiment of the present invention.

This embodiment can be combined with the other embodiments as appropriate.

### Embodiment 4

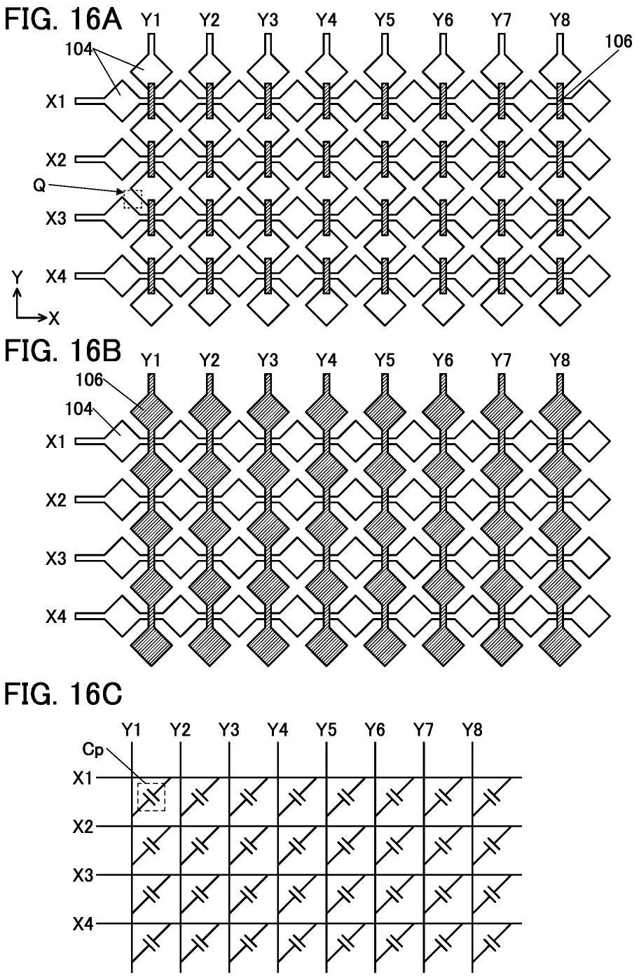

In this embodiment, a structure example of a touch sensor used for a display apparatus of one embodiment of the present invention is described with reference to FIG. 16 to FIG. 20. Here, a capacitive touch sensor is described.

Typical examples of a capacitive touch sensor include a self-capacitive touch sensor and a mutual capacitive touch sensor.

In a self-capacitive touch sensor, a structure where an electrode to which a capacitor is connected forms a segment, and a plurality of the segments are arranged in a matrix is used. A self-capacitive touch sensor is a method for obtaining positional data by detecting an increase in the capacitance of the electrode when an object to be sensed such as a finger approaches the electrode.

In a mutual capacitive touch sensor, a structure where a plurality of first wirings and a plurality of second wirings are arranged in directions intersecting with each other is used. A mutual capacitive touch sensor is a method for obtaining positional data by detecting a change in capacitance formed at an intersection portion of the first wiring and the second wiring when an object to be sensed approaches.

Described below is a structure of a touch sensor that can be employed for a mutual capacitive type.

### [Structure Example of Touch Sensor]

FIG. 16A is a schematic top view illustrating an example of a conductive layer included in a touch sensor. The touch sensor illustrated in FIG. 16A includes the conductive layer 104 and the conductive layer 106.

The touch sensor includes a plurality of wirings extending in the X direction and arranged in the Y direction (a wiring X1 to a wiring X4) and a plurality of wirings extending in the Y direction and arranged in the X direction (a wiring Y1 to a wiring Y8). Hereinafter, an expression “wiring Xn” is used when matters that are common to the wiring X1 to the wiring X4 are described, and an expression “wiring Ym” is used when matters that are common to the wiring Y1 to the wiring Y8 are described.

The wiring Xn is formed by the conductive layer 104. The wiring Xn has a shape in which portions elongated in the X direction and rhombic portions are alternately connected to each other.

The wiring Ym includes the conductive layer 104 and the conductive layer 106. The wiring Ym is formed of a plurality of rhombic conductive layers 104 and the conductive layers 106 elongated in the Y direction, which connect the conductive layers 104.

The wiring Xn and the wiring Ym intersect with each other by a narrow portion formed of the conductive layer 104 of the wiring Xn and a narrow portion formed of the conductive layer 106 of the wiring Ym.

Note that as illustrated in FIG. 16B, the wiring Xn may be formed of the conductive layer 104 and the wiring Ym may be formed of the conductive layer 106.

Although FIG. 16A and FIG. 16B illustrate examples in which four wirings Xn and eight wirings Ym are included, the number of wirings is not limited thereto and can be set as appropriate depending on the size of a display portion of a display apparatus or required wiring density of a touch sensor.

FIG. 16C illustrates a circuit diagram illustrating a structure of the touch sensor. Since capacitive coupling is generated between the wiring Xn and the wiring Ym, capacitance Cp is formed therebetween. The capacitance Cp is sometimes referred to as mutual capacitance between the wiring Xn and the wiring Ym. Here, a circuit supplied with a pulse potential is connected to the wiring Xn, and a circuit for obtaining the potential of the wiring Ym, such as an A-D converter circuit or a sense amplifier, is connected to the wiring Ym.

Since the capacitive coupling is formed between the wiring Xn and the wiring Ym, when a pulse potential is supplied to the wiring Xn, a pulse potential is generated in the wiring Ym. The amplitude of the pulse potential generated in the wiring Ym is proportional to the intensity of the capacitive coupling between the wiring Xn and the wiring Ym (i.e., the capacitance of Cp). Here, when an object to be sensed such as a finger approaches the vicinity of the intersection portion of the wiring Xn and the wiring Ym, capacitance is formed between the wiring Xn and the object to be sensed and between the wiring Ym and the object to be sensed; as a result, the intensity of the capacitive coupling between the wiring Xn and the wiring Ym becomes relatively small. Thus, when a pulse potential is supplied to the wiring Xn, the amplitude of a pulse potential generated in the wiring Ym is decreased.

When a pulse potential is supplied to the wiring X1, pulse potentials generated in the wiring Y1 to the wiring Y8 are obtained. Similarly, pulse potentials are supplied to the wiring X2, the wiring X3, and the wiring X4 in this order, and pulse potentials generated in the wiring Y1 to the wiring Y8 at this time are obtained. Thus, positional data of the object to be sensed can be obtained.

### [Structure Example 1 of Electrode Shape]

Hereinafter, more specific examples of top surface shapes of electrodes of the wiring Xn and the wiring Ym are described.

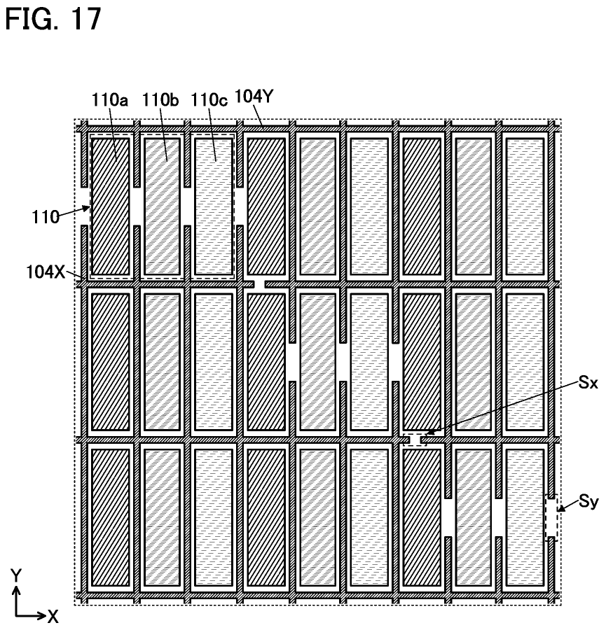

FIG. 17 illustrates an enlarged view of a region Q in FIG. 16A. The region Q is a region where a rhombic portion of the wiring Xn, a rhombic portion of the wiring Ym, and a boundary therebetween are included.

FIG. 17 illustrates top surface shapes of a conductive layer 104X that forms the wiring Xn and a conductive layer 104Y that forms the wiring Ym. The conductive layer 104X and the conductive layer 104Y each have a lattice-shaped top surface. In other words, the conductive layer 104X and the conductive layer 104Y each have a top surface shape having a plurality of openings. The conductive layer 104X and the conductive layer 104Y may be formed over different surfaces, but it is particularly preferable that the conductive layer 104X and the conductive layer 104Y be positioned on the same plane and formed by processing the same conductive film.

FIG. 17 also illustrates the pixel 110. The pixel 110 includes the subpixel 110a, the subpixel 110b, and the subpixel 110c. For example, the subpixel 110a may be the blue subpixel B, the subpixel 110b may be the red subpixel R, and the subpixel 110c may be the green subpixel G.

The conductive layer 104X and the conductive layer 104Y are provided between adjacent subpixels in a plan view. In other words, each of the subpixel 110a, the subpixel 110b, and the subpixel 110c is provided in a position overlapping with an opening included in the conductive layer 104X or the conductive layer 104Y. Here, an example in which one subpixel is provided in a position overlapping with one opening included in the conductive layer 104X or the conductive layer 104Y in a plan view is illustrated. Note that without limitation to this, a structure where a plurality of subpixels are provided in a position overlapping with one opening may be employed.

The lattice-shaped top surface of each of the conductive layer 104X and the conductive layer 104Y is formed by portions extending in the X direction, portions extending in the Y direction, and their intersection portions. The conductive layer 104X and the conductive layer 104Y are separated from each other by notches Sx provided in the portions extending in the X direction of the lattice-shaped conductive layer and notches Sy provided in the portions extending in the Y direction of the lattice-shaped conductive layer. Such a structure can make a distance between the conductive layer 104X and the conductive layer 104Y small, whereby the capacitance value therebetween can be increased.

Although a notch can be provided at the intersection portion of the lattice, it is preferable that the notch Sx and the notch Sy be respectively provided in the portion extending in the X direction and the portion extending in the Y direction of the lattice as illustrated in FIG. 17, in which case, the patterns of the conductive layer 104X and the conductive layer 104Y can be less likely to be recognized when seen from the display surface side.

As illustrated in FIG. 17, around the subpixel 110a, the subpixel 110b, and the subpixel 110c, a structure where part of the conductive layer 104X or part of the conductive layer 104Y is always provided adjacent to the subpixel 110a, the subpixel 110b, and the subpixel 110c is employed. With such a structure, the patterns of the conductive layer 104X and the conductive layer 104Y can be less likely to be recognized when seen from the display surface side.

In FIG. 17, the conductive layer 104X and the conductive layer 104Y each have a lattice-shaped top surface having vertically long openings. The subpixel 110a, the subpixel 110b, and the subpixel 110c are each provided to overlap with one opening. In the pixel 110 illustrated in FIG. 17, the subpixel 110a, the subpixel 110c, and the subpixel 110b are each arranged in the Y direction as in FIG. 1A. Note that in the pixel 110, the positions of the subpixel 110a, the subpixel 110b, and the subpixel 110c are not limited thereto, and positions of any two of the subpixels can be interchanged.

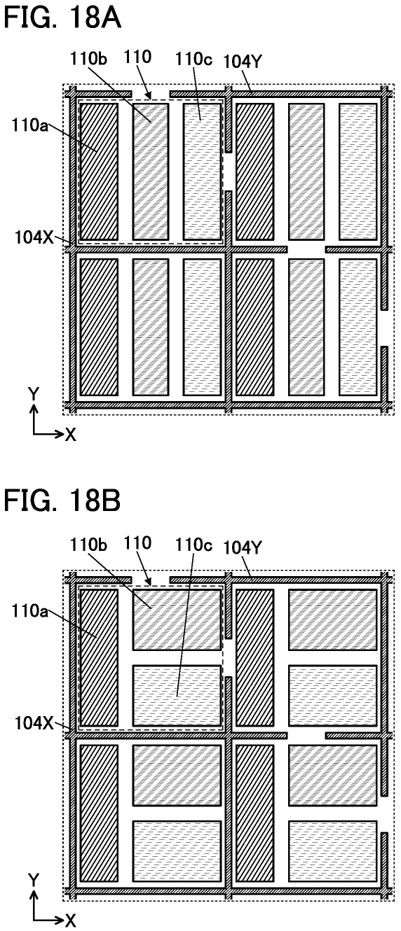

Note that the positions of the pixel and the touch sensor of the present invention are not limited to the positions illustrated in FIG. 17. For example, as illustrated in FIG. 18A, the subpixel 110a, the subpixel 110b, and the subpixel 110c may be collectively provided in one opening included in the conductive layer 104X and the conductive layer 104Y. That is, a structure may be employed in which not one subpixel but a pixel including a plurality of subpixels are arranged in one opening included in the conductive layer 104X and the conductive layer 104Y.

In FIG. 18A, the pixel 110 employs stripe arrangement similar to that in FIG. 1A; however, one embodiment of the present invention is not limited thereto. For example, as illustrated in FIG. 18B, the pixel 110 may employ S-stripe arrangement illustrated in FIG. 13A. For example, the subpixel 110a may be the blue subpixel B, the subpixel 110b may be the red subpixel R, and the subpixel 110c may be the green subpixel G.

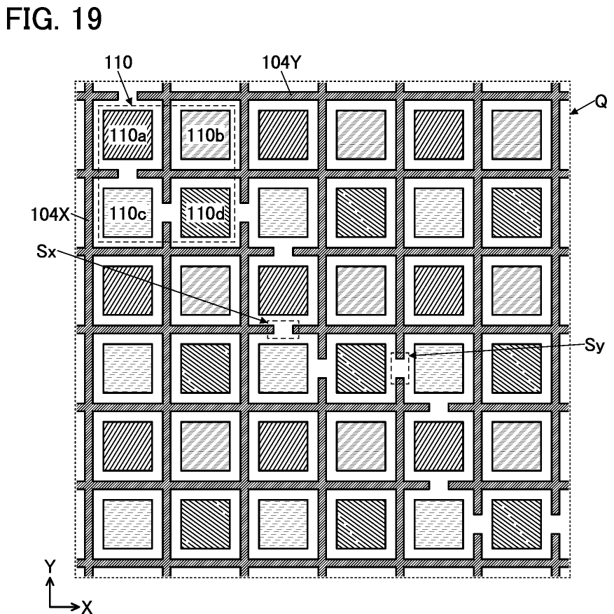

Alternatively, the pixel 110 may include four or more subpixels. As illustrated in FIG. 19, the pixel 110 may have a structure where the subpixel 110a, the subpixel 110b, the subpixel 110c, and the subpixel 110d are included. In the display apparatus illustrated in FIG. 19, the pixels 110 are arranged in a matrix as in FIG. 14D. The subpixel 110a and the subpixel 110b are alternately arranged in the X direction. The subpixel 110c and the subpixel 110d are alternately arranged in the X direction. The subpixel 110a and the subpixel 110c are alternately arranged in the Y direction. The subpixel 110b and the subpixel 110d are alternately arranged in the Y direction. For example, the subpixel 110a may be the red subpixel R, the subpixel 110b may be the green subpixel G, the subpixel 110c may be the blue subpixel B, and the subpixel 110d may be the white subpixel W. Note that in the pixel 110, the positions of the subpixel 110a, the subpixel 110b, the subpixel 110c, and the subpixel 110d are not limited thereto, and positions of any two of the four subpixels can be interchanged.

FIG. 19 illustrates an example in which one subpixel is provided in a position overlapping with one opening included in the conductive layer 104X or the conductive layer 104Y in a plan view. In the display apparatus illustrated in FIG. 19, the opening has a substantially square shape.

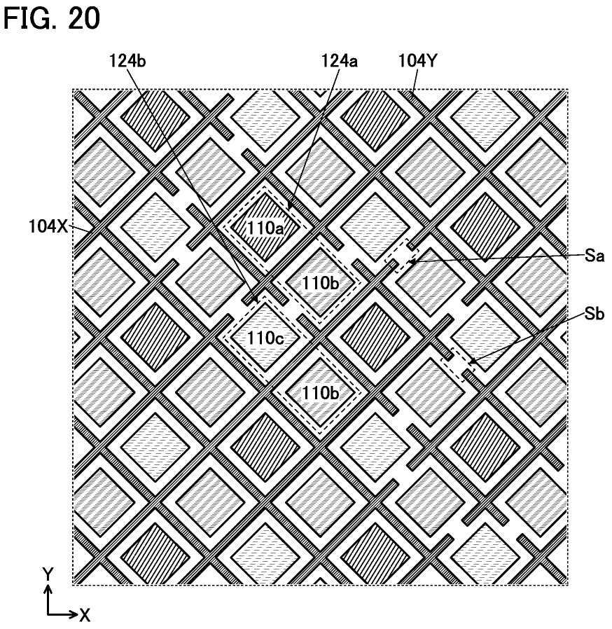

Alternatively, as illustrated in FIG. 20, the arrangement direction of the pixels 110 may be tilted at 45°. Specifically, the display apparatus illustrated in FIG. 20 employs PenTile arrangement as in FIG. 13C. In FIG. 20, the pixels 124a each including the subpixel 110a and the subpixel 110b and the pixels 124b each including the subpixel 110b and the subpixel 110c are provided. In addition, a column where the pixels 124a are arranged and a column where the pixels 124b are arranged are alternately provided. For example, the subpixel 110a may be the red subpixel R, the subpixel 110b may be the green subpixel G, and the subpixel 110c may be the blue subpixel B. Note that in that case, the green subpixel G may be smaller than the other subpixels as illustrated in FIG. 13C.

As the arrangement of the conductive layer 104X and the conductive layer 104Y, the arrangement illustrated in FIG. 19 is tilted at 45°. The conductive layer 104X and the conductive layer 104Y each have a lattice-shaped top surface inclined to, for example, the outline of a display portion of a display apparatus or the extending direction of a wiring connected to the pixel.

The conductive layer 104X and the conductive layer 104Y are separated from each other by notches Sa provided in portions extending from the lower left to the upper right of the lattice-shaped conductive layer and notches Sb provided in portions extending from the upper left to the lower right of the lattice-shaped conductive layer.

Here, the conductive layer 104X and the conductive layer 104Y can be separated linearly by using either the notches Sa or the notches Sb in the case of separating the conductive layer 104X and the conductive layer 104Y. However, it is preferable that the notches Sa and the notches Sb be used in combination and the conductive layer 104X and the conductive layer 104Y be separated so that a boundary therebetween has a zigzag shape as illustrated in FIG. 20, in which case, the patterns of the conductive layer 104X and the conductive layer 104Y can be less likely to be recognized when seen from the display surface side. Moreover, since the boundary between the conductive layer 104X and the conductive layer 104Y has a zigzag shape, the boundary therebetween can be long; thus, an effect of increasing the capacitance between the conductive layer 104X and the conductive layer 104Y can also be produced.

The touch sensor with the above structure is preferable because display quality of an image can be further improved.

This embodiment can be combined with the other embodiments as appropriate.

### Embodiment 5

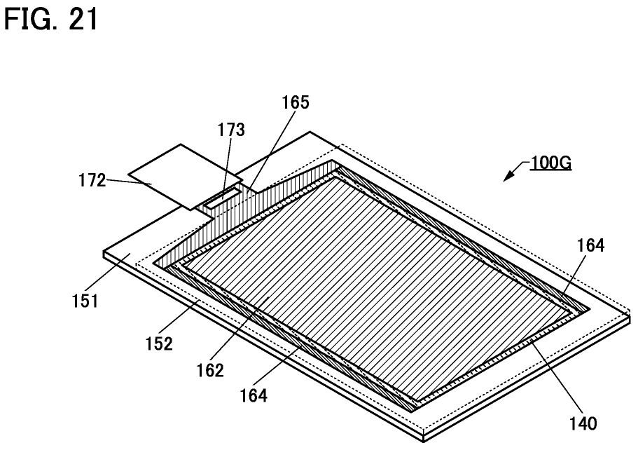

In this embodiment, display apparatuses of one embodiment of the present invention are described with reference to FIG. 21 to FIG. 24.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer and the like, digital signage, and a large game machine such as a pachinko machine.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices that can be worn on a head, such as a VR device like a head-mounted display and a glasses-type AR device.

### [Display Apparatus 100G]

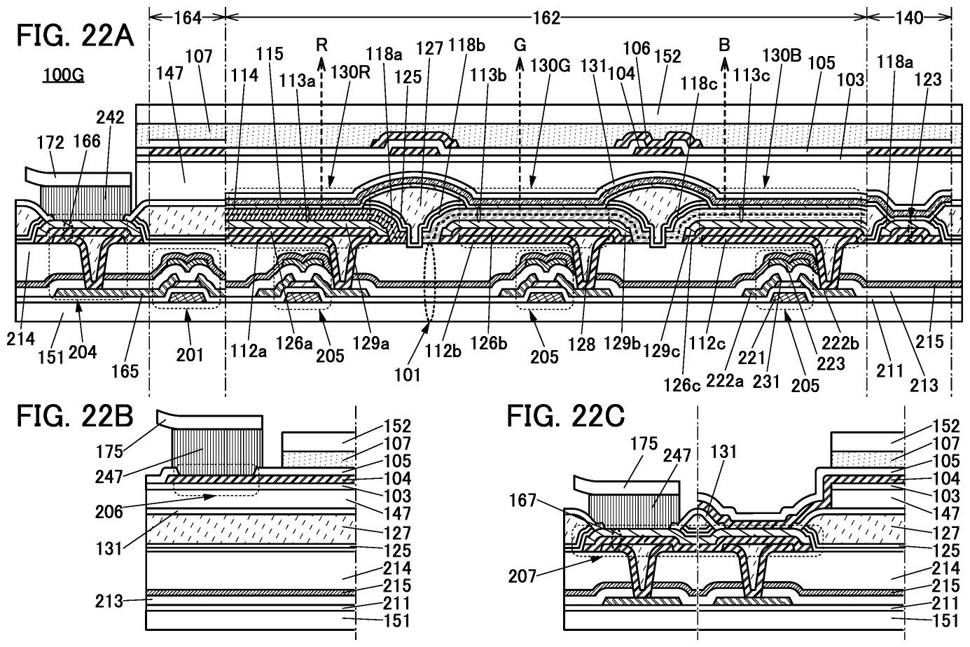

FIG. 21 illustrates a perspective view of a display apparatus 100G, and FIG. 22A illustrates a cross-sectional view of the display apparatus 100G.

In the display apparatus 100G, a substrate 152 and a substrate 151 are bonded to each other. In FIG. 21, the substrate 152 is denoted by a dashed line

The display apparatus 100G includes a display portion 162, the connection portion 140, a circuit 164, a wiring 165, and the like. FIG. 21 illustrates an example where an IC 173 and an FPC 172 are mounted on the display apparatus 100G. Thus, the structure illustrated in FIG. 21 can be regarded as a display module including the display apparatus 100G, the IC (integrated circuit), and the FPC.

The connection portion 140 is provided outside the display portion 162. The connection portion 140 can be provided along one or more sides of the display portion 162. The number of connection portions 140 can be one or more. FIG. 21 illustrates an example where the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 21 illustrates an example where the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100G and the display module are not necessarily provided with an IC. The IC may be mounted on the FPC by a COF method or the like.

FIG. 22A illustrates an example of cross sections of part of a region including the FPC 172, part of the circuit 164, part of the display portion 162, part of the connection portion 140, and part of a region including an end portion of the display apparatus 100G.

The display apparatus 100G illustrated in FIG. 22A includes a transistor 201, a transistor 205, a light-emitting device 130R that emits red light, a light-emitting device 130G that emits green light, a light-emitting device 130B that emits blue light, a touch sensor, and the like between the substrate 151 and the substrate 152.

The stacked-layer structure of each of the light-emitting devices 130R, 130G, and 130B is the same as that illustrated in FIG. 1B except for the structure of the pixel electrode. Embodiment 1 can be referred to for the details of the light-emitting devices. For example, the light-emitting device 130R, the light-emitting device 130G, and the light-emitting device 130B correspond to the light-emitting device 130a, the light-emitting device 130b, and the light-emitting device 130c, respectively, illustrated in FIG. 1B. The touch sensor also has a structure similar to that in FIG. 1B, and includes the conductive layer 104, the conductive layer 106, the insulating layer 105, and the like.

Since the first layer 113a, the second layer 113b, and the third layer 113c are separated and apart from each other in the display apparatus 100G, generation of crosstalk between adjacent subpixels can be inhibited even when the display apparatus 100G has high resolution. Accordingly, the display apparatus can have high resolution and high display quality.

The light-emitting device 130R includes a conductive layer 112a, a conductive layer 126a over the conductive layer 112a, and a conductive layer 129a over the conductive layer 126a. All of the conductive layers 112a, 126a, and 129a can be referred to as pixel electrodes, or one or two of them can be referred to as pixel electrodes.

The light-emitting device 130G includes a conductive layer 112b, a conductive layer 126b over the conductive layer 112b, and a conductive layer 129b over the conductive layer 126b.

The light-emitting device 130B includes a conductive layer 112c, a conductive layer 126c over the conductive layer 112c, and a conductive layer 129c over the conductive layer 126c.

The conductive layer 112a is connected to a conductive layer 222b included in the transistor 205 through an opening provided in an insulating layer 214. An end portion of the conductive layer 126a is positioned outward from an end portion of the conductive layer 112a. The end portion of the conductive layer 126a and an end portion of the conductive layer 129a are aligned or substantially aligned with each other. For example, a conductive layer functioning as a reflective electrode can be used as the conductive layer 112a and the conductive layer 126a, and a conductive layer functioning as a transparent electrode can be used as the conductive layer 129a.

Detailed description of the conductive layers 112b, 126b, and 129b of the light-emitting device 130G and the conductive layers 112c, 126c, and 129c of the light-emitting device 130B is omitted because these conductive layers are similar to the conductive layers 112a, 126a, and 129a of the light-emitting device 130R.

In each of the conductive layers 112a, 112b, and 112c, a depressed portion is formed to cover the openings provided in the insulating layer 214. A layer 128 is embedded in each of the depressed portions.

The layer 128 has a planarization function for the depressed portions of the conductive layers 112a, 112b, and 112c. The conductive layers 126a, 126b, and 126c electrically connected to the conductive layers 112a, 112b, and 112c, respectively, are provided over the conductive layers 112a, 112b, and 112c and the layer 128. Thus, regions overlapping with the depressed portions of the conductive layers 112a, 112b, and 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For example, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the layer 128. A photosensitive resin can also be used for the layer 128. As the photosensitive resin, a positive photosensitive material or a negative photosensitive material can be used.

When a photosensitive resin is used, the layer 128 can be formed through only light-exposure and development processes, reducing the influence of dry etching, wet etching, or the like on the surfaces of the conductive layers 112a, 112b, and 112c. When the layer 128 is formed using a negative photosensitive resin, the layer 128 can sometimes be formed using the same photomask (light-exposure mask) as the photomask used for forming the opening in the insulating layer 214.

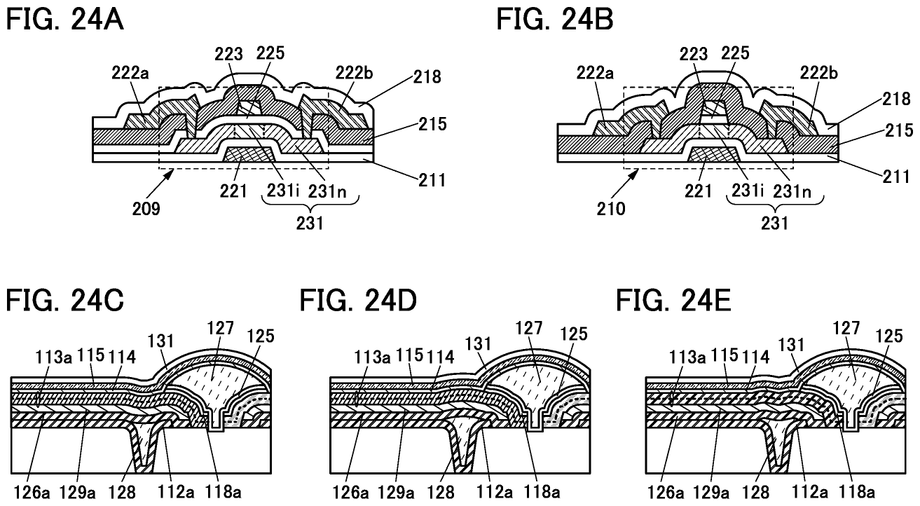

Note that FIG. 22A illustrates an example where a top surface of the layer 128 includes a flat portion, the shape of the layer 128 is not particularly limited. FIG. 24C to FIG. 24E illustrate variation examples of the layer 128.

As illustrated in FIG. 24C and FIG. 24E, the top surface of the layer 128 can have a shape such that its center and the vicinity thereof are recessed, i.e., a shape including a concave curved surface, in a cross-sectional view.

As illustrated in FIG. 24D, the top surface of the layer 128 can have a shape such that its center and the vicinity thereof bulge, i.e., a shape including a convex curved surface shape, in a cross-sectional view.

The top surface of the layer 128 may include one or both of a convex curved surface and a concave curved surface. The number of convex curved surfaces and the number of concave curved surfaces included in the top surface of the layer 128 are not limited and can each be one or more.

The height of the top surface of the layer 128 and the height of the top surface of the conductive layer 112a may agree with or substantially agree with each other, or may be different from each other. For example, the height of the top surface of the layer 128 may be either lower or higher than the height of a top surface of the conductive layer 112a.

FIG. 24C can be regarded as illustrating an example where the layer 128 fits in the depressed portion of the conductive layer 112a. By contrast, as illustrated in FIG. 24E, the layer 128 may exist also outside the depressed portion of the conductive layer 112a, that is, the layer 128 may be formed to have a top surface wider than the depressed portion.

Top and side surfaces of the conductive layer 126a and top and side surfaces of the conductive layer 129a are covered with the first layer 113a. Similarly, top and side surfaces of the conductive layer 126b and top and side surfaces of the conductive layer 129b are covered with the second layer 113b. Moreover, top and side surfaces of the conductive layer 126c and top and side surfaces of the conductive layer 129c are covered with the third layer 113c. Accordingly, regions provided with the conductive layers 126a, 126b, and 126c can be entirely used as the light-emitting regions of the light-emitting devices 130R, 130G, and 130B, increasing the aperture ratio of the pixels.

The side surfaces of the first layer 113a, the second layer 113b, and the third layer 113c are each covered with the insulating layers 125 and 127. The mask layer 118a is positioned between the first layer 113a and the insulating layer 125. The mask layer 118b is positioned between the second layer 113b and the insulating layer 125, and the mask layer 118c is positioned between the third layer 113c and the insulating layer 125. The common layer 114 is provided over the first layer 113a, the second layer 113b, the third layer 113c, and the insulating layers 125 and 127. The common electrode 115 is provided over the common layer 114. The common layer 114 and the common electrode 115 are each one continuous film shared by the plurality of light-emitting devices.

The protective layer 131 is provided over each of the light-emitting devices 130R, 130G, and 130B. The protective layer 131 covering the light-emitting devices can inhibit an impurity such as water from entering the light-emitting devices, and increase the reliability of the light-emitting devices.

Like the display apparatus 100 illustrated in FIG. 1B, in the display apparatus 100G, the resin layer 147, the insulating layer 103, the conductive layer 104, the insulating layer 105, and the conductive layer 106 are provided over the protective layer 131. Also in the display apparatus 100G, as in the above embodiment, at least part of the conductive layer 104 and part of the conductive layer 106 preferably overlap with a region interposed between two adjacent light-emitting devices or a region interposed between two adjacent EL layers. Furthermore, at least part of the conductive layer 104 and part of the conductive layer 106 preferably include a region overlapping with the insulating layer 127. With such a structure, a touch sensor can be provided while a high aperture ratio of the display apparatus is maintained. Note that the description of Embodiment 1 can be referred to for the components of the touch sensor.

The insulating layer 105 and the conductive layer 106 are bonded to the substrate 152 with the adhesive layer 107. A solid sealing structure, a hollow sealing structure, or the like can be employed to seal the light-emitting devices. In FIG. 22A, a solid sealing structure is employed in which a space between the substrate 152 and the substrate 151 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting devices. The space may be filled with a resin other than the frame-shaped adhesive layer 107.

The conductive layer 123 is provided over the insulating layer 214 in the connection portion 140. An example is described in which the conductive layer 123 has a stacked-layer structure of a conductive film obtained by processing the same conductive film as the conductive layers 112a, 112b, and 112c; a conductive film obtained by processing the same conductive film as the conductive layers 126a, 126b, and 126c; and a conductive film obtained by processing the same conductive film as the conductive layers 129a, 129b, and 129c. An end portion of the conductive layer 123 is covered with the mask layer 118a, the insulating layer 125, and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are directly in contact with each other to be electrically connected to each other.

The display apparatus 100G has a top-emission structure. Light emitted by the light-emitting device is emitted toward the substrate 152. For the substrate 152, a material having a high property of transmitting visible light is preferably used. The pixel electrode contains a material reflecting visible light, and a counter electrode (the common electrode 115) contains a material transmitting visible light.

A stacked-layer structure from the substrate 151 and the components thereover up to the insulating layer 214 corresponds to the substrate 101 and the layer including the transistors above the substrate 101 in Embodiment 1.

The transistor 201 and the transistor 205 are formed over the substrate 151. These transistors can be manufactured using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be either a single layer or two or more layers.

A material in which impurities such as water and hydrogen are less likely to diffuse is preferably used for at least one of the insulating layers covering the transistors. This allows the insulating layer to function as a barrier layer. Such a structure can effectively inhibit diffusion of impurities into the transistors from the outside and increase the reliability of a display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably has a function of an etching protective layer. Accordingly, a depressed portion can be prevented from being formed in the insulating layer 214 in processing the conductive layer 112a, the conductive layer 126a, the conductive layer 129a, or the like. Alternatively, a depressed portion may be provided in the insulating layer 214 in processing the conductive layer 112a, the conductive layer 126a, the conductive layer 129a, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure where the semiconductor layer where a channel is formed is provided between two gates is used for the transistor 201 and the transistor 205. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

The semiconductor layer of the transistor preferably includes a metal oxide (also referred to as an oxide semiconductor). That is, a transistor including a metal oxide in its channel formation region (hereinafter, also referred to as an OS transistor) is preferably used for the display apparatus of this embodiment.

As the oxide semiconductor having crystallinity, a CAAC (c-axis aligned crystalline)-OS, an nc (nanocrystalline)-OS, and the like can be given.

Alternatively, a transistor using silicon in its channel formation region (a Si transistor) may be used. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) can be used. The LTPS transistor has high field-effect mobility and favorable frequency characteristics.

With the use of Si transistors such as LTPS transistors, a circuit required to be driven at a high frequency (e.g., a source driver circuit) can be formed on the same substrate as the display portion. Thus, external circuits mounted on the display apparatus can be simplified, and component cost and mounting cost can be reduced.

An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). In other words, the off-state current of an OS transistor is lower than that of a Si transistor by approximately ten orders of magnitude.

To increase the emission luminance of the light-emitting device included in the pixel circuit, the amount of current fed through the light-emitting device needs to be increased. For this, it is necessary to increase the source-drain voltage of a driving transistor included in the pixel circuit. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting device can be increased, so that the emission luminance of the light-emitting device can be increased.

When transistors operate in a saturation region, a change in source-drain current with respect to a change in gate-source voltage can be smaller in an OS transistor than in a Si transistor. Accordingly, when an OS transistor is used as the driving transistor in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, with use of an OS transistor as a driving transistor, a stable current can be fed through the light-emitting device, for example, even when a variation in current-voltage characteristics of the light-emitting device occurs. In other words, when the OS transistor operates in the saturation region, the source-drain current hardly changes with an increase in the source-drain voltage; hence, the emission luminance of the light-emitting device can be stable.

As described above, with the use of an OS transistor as a driving transistor included in the pixel circuit, it is possible to achieve “inhibition of black floating”, “increase in emission luminance”, “increase in the number of gray levels”, “inhibition of variation in light-emitting devices”, and the like.

The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) be used for the semiconductor layer. Alternatively, it is preferable to use an oxide containing indium, tin, and zinc. Further alternatively, it is preferable to use an oxide containing indium, gallium, tin, and zinc. Alternatively, an oxide containing indium (In), aluminum (Al), and zinc (Zn) (also referred to as IAZO) is preferably used. Alternatively, an oxide containing indium (In), aluminum (Al), gallium (Ga), and zinc (Zn) (also referred to as IAGZO) is preferably used.

When the semiconductor layer is In-M-Zn oxide, the atomic ratio of In is preferably greater than or equal to the atomic ratio of M in the In-M-Zn oxide. Examples of the atomic ratio of the metal elements in such In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistor included in the circuit 164 and the transistor included in the display portion 162 may have the same structure or different structures. One structure or two or more types of structures may be employed for a plurality of transistors included in the circuit 164. Similarly, one structure or two or more types of structures may be employed for a plurality of transistors included in the display portion 162.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. Note that a structure where an LTPS transistor and an OS transistor are combined is referred to as LTPO in some cases. Note that as a more preferable example, it is preferable to use an OS transistor as a transistor or the like functioning as a switch for controlling electrical continuity between wirings and an LTPS transistor as a transistor or the like for controlling current.

For example, one of the transistors included in the display portion 162 functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. Accordingly, the amount of current flowing through the light-emitting device can be increased in the pixel circuit.

Another transistor included in the display portion 162 functions as a switch for controlling selection and non-selection of the pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. With this structure, the leakage current that might flow through the transistor and the leakage current that might flow between adjacent light-emitting devices (also referred to as lateral leakage current, side leakage current, or the like) can be extremely low. With the structure, a viewer can notice any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with little light leakage or the like that might occur in black display can be achieved.

The structure of the OS transistor is not limited to the structure illustrated in FIG. 22A. For example, the structures illustrated in FIG. 24A and FIG. 24B may be employed.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of the low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 24A illustrates an example of the transistor 209 in which the insulating layer 225 covers the top and side surfaces of the semiconductor layer 231. The conductive layer 222a and the conductive layer 222b are each connected to the low-resistance region 231n through openings provided in the insulating layer 225 and the insulating layer 215. One of the conductive layer 222a and the conductive layer 222b functions as a source, and the other functions as a drain.

Meanwhile, in the transistor 210 illustrated in FIG. 24B, the insulating layer 225 overlaps with the channel formation region 231i of the semiconductor layer 231 and does not overlap with the low-resistance regions 231n. The structure illustrated in FIG. 24B can be formed by processing the insulating layer 225 using the conductive layer 223 as a mask, for example. In FIG. 24B, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layers 112a, 112b, and 112c, a conductive film obtained by processing the same conductive film as the conductive layers 126a, 126b, and 126c, and a conductive film obtained by processing the same conductive film as the conductive layers 129a, 129b, and 129c. The conductive layer 166 is exposed on a top surface of the connection portion 204. Thus, the connection portion 204 and the FPC 172 can be electrically connected to each other through the connection layer 242.

A structure where a light-blocking layer is provided on a surface of the substrate 152 on the substrate 151 side may be employed. The light-blocking layer can be provided between adjacent light-emitting devices, in the connection portion 140, and in the circuit 164, for example. A variety of optical members can be arranged on the outer surface of the substrate 152.

The material that can be used for the substrate 101 and the substrate 102 can be used for each of the substrate 151 and the substrate 152.

As the connection layer 242, an anisotropic conductive film (ACF), an anisotropic conductive paste (ACP), or the like can be used.

FIG. 22A illustrates a structure where a signal and power are supplied from the FPC 172 to the display portion 162 and the like through the connection portion 204. Similarly, as illustrated in FIG. 22B, it is preferable that a signal and power be supplied or a signal be read to the touch sensor, from an FPC 175 through a connection portion 206. Although not illustrated in FIG. 22B, a structure in which an IC for a touch sensor is mounted on the FPC 175 can also be employed.

The connection portion 206 is provided in a region of the substrate 151 not overlapping with the substrate 152. In the connection portion 206, the conductive layer 104 provided over the insulating layer 103 is electrically connected to the FPC 175 through a connection layer 247. Here, the conductive layer 104 functions as a wiring electrically connected to the touch sensor. On a top surface of the connection portion 206, an opening is provided in the insulating layer 105, and the conductive layer 104 is exposed. Thus, the connection portion 206 and the FPC 175 can be electrically connected to each other through the connection layer 247.

The FPC 175 can have a structure similar to that of the FPC 172. The connection layer 247 can have a structure similar to that of the connection layer 242.

Although the conductive layer 104 is provided over the insulating layer 103 and the conductive layer 104 and the connection layer 247 are connected to each other in FIG. 22B, the present invention is not limited thereto. For example, as illustrated in FIG. 22C, a structure where the conductive layer 104 is dropped over the insulating layer 214, and then the conductive layer 104 and the connection layer 247 are electrically connected to each other may be employed.

In a connection portion 207 illustrated in FIG. 22C, the conductive layer 104 is electrically connected to the FPC 175 through a conductive layer 167 and the connection layer 247. Here, an example is described in which the conductive layer 167 has a stacked-layer structure of a conductive film obtained by processing the same conductive film as the conductive layers 112a, 112b, and 112c; a conductive film obtained by processing the same conductive film as the conductive layers 126a, 126b, and 126c; and a conductive film obtained by processing the same conductive film as the conductive layers 129a, 129b, and 129c. The conductive layer 167 is exposed on a top surface of the connection portion 207. Thus, the connection portion 207 and the FPC 175 can be electrically connected to each other through the connection layer 247.

With the structure illustrated in FIG. 22C, a stacked-layer structure of the FPC 175, the connection layer 247, and the conductive layer 167 in the connection portion 207 can be similar to a stacked-layer structure of the FPC 172, the connection layer 242, and the conductive layer 166 in the connection portion 204. Thus, the connection between the FPC 175 and the conductive layer 167 can be performed in a manner similar to that of the connection between the FPC 172 and the conductive layer 166; thus, the connection between the FPC 175 and the conductive layer 167 can be performed relatively easily.

Although FIG. 22C illustrates a structure in which the FPC 172 and the FPC 175 are separately provided, the present invention is not limited thereto. A structure in which the connection portion 204 and the connection portion 207 are provided in proximity to each other may be employed so that the connection layer 242 and the connection layer 247, and the FPC 172 and the FPC 175 are each integrated. With such a structure, the FPC for display and the FPC for a touch sensor can be collectively provided; thus, these mounting areas can be reduced, the size of a display apparatus or an electronic device using the display apparatus can be small, and a narrow frame can be achieved.

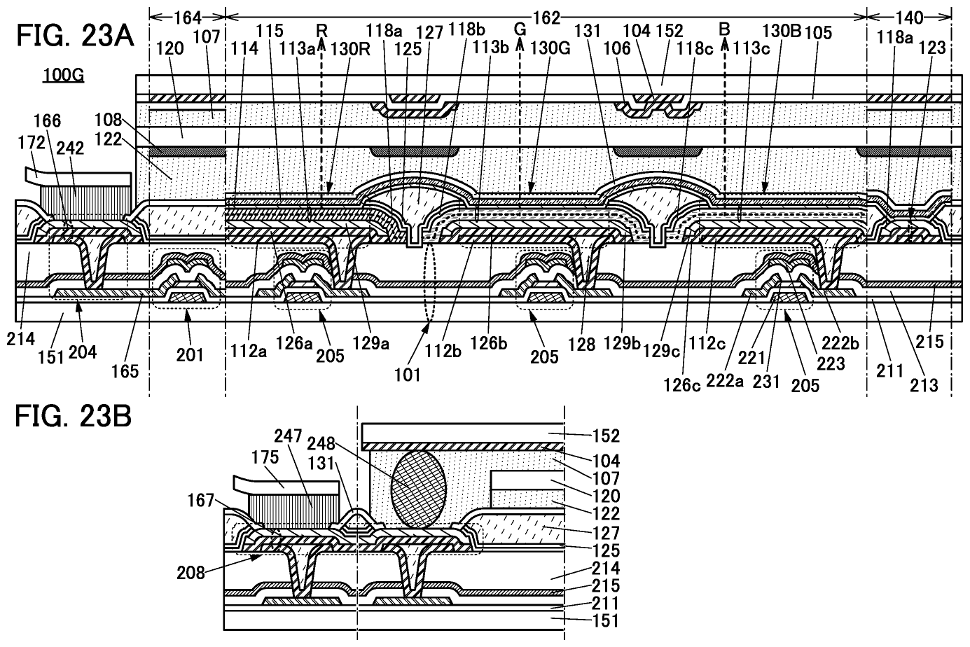

In FIG. 22A, the structure of the touch sensor is similar to the structure illustrated in FIG. 1B; however, the present invention is not limited thereto, and the touch sensor described in the above embodiment can be used as appropriate. For example, as illustrated in FIG. 23A, the touch sensor may have a structure similar to that illustrated in FIG. 3C. In the display apparatus 100G illustrated in FIG. 23A, a layer including a light-emitting device and a transistor is provided between the substrate 151 and the substrate 120, and a touch sensor is provided over the substrate 152. In addition, the light-blocking layer 108 may be provided on the surface of the substrate 120 on the substrate 151 side. Here, the substrate 120 and the substrate 151 are bonded to each other with the adhesive layer 122. In this case, the adhesive layer 122 is in contact with the substrate 120, the light-blocking layer 108, and the protective layer 131. The substrate 120 and the substrate 152 are bonded to each other with the adhesive layer 107. In this case, the adhesive layer 107 is in contact with the substrate 120, the insulating layer 105, and the conductive layer 106.

In the display apparatus illustrated in FIG. 23A, a structure is employed where a connection portion 208, the conductive layer 104, and a conductive particle 248 are provided in a region where the substrate 152 and the substrate 151 overlap with each other and the substrate 120 overlaps with neither the substrate 152 nor the substrate 151 as illustrated in FIG. 23B. In the connection portion 208 illustrated in FIG. 23B, the conductive layer 104 is electrically connected to the conductive layer 167 through the conductive particle 248. When the conductive particle 248 is provided in this manner, the conductive layer 104 and the conductive layer 167 that are provided over different substrates can be electrically connected to each other. The conductive layer 167 is exposed on atop surface of the connection portion 208. Thus, the connection portion 208 and the FPC 175 can be electrically connected to each other through the connection layer 247.

As the conductive particle 248, a resin or a substance where a surface of a particle such as silica is covered with a metal material can be used. Nickel or gold is preferably used as the metal material because the contact resistance can be reduced. It is also preferable to use a particle coated with layers of two or more kinds of metal materials, such as a particle coated with nickel and further with gold.

This embodiment can be combined with the other embodiments as appropriate.

### Embodiment 6

In this embodiment, a structure example of a transistor that can be used in the display apparatus of one embodiment of the present invention is described. Specifically, the case of using a transistor containing silicon as a semiconductor where a channel is formed is described.

One embodiment of the present invention is a display apparatus including a light-emitting device and a pixel circuit. For example, three kinds of light-emitting devices emitting light of red (R), green (G), and blue (B) are included in the display apparatus, whereby a full-color display apparatus can be achieved.

Transistors containing silicon in their semiconductor layers where channels are formed are preferably used as all transistors included in the pixel circuit for driving the light-emitting device. As silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors containing silicon, such as LTPS transistors, a circuit required to be driven at a high frequency (e.g., a source driver circuit) can be formed on the same substrate as the display portion. Thus, external circuits mounted on the display apparatus can be simplified, whereby component cost and mounting cost can be reduced.

It is preferable to use transistors including a metal oxide (hereinafter also referred to as an oxide semiconductor) in their semiconductors where channels are formed (such transistors are hereinafter also referred to as OS transistors) as at least one of the transistors included in the pixel circuit. An OS transistor has extremely higher field-effect mobility than a transistor containing amorphous silicon. In addition, an OS transistor has an extremely low leakage current between a source and a drain in an off state (hereinafter, also referred to as off-state current), and charge accumulated in a capacitor that is connected in series to the transistor can be retained for a long period. Furthermore, power consumption of the display apparatus can be reduced with the use of an OS transistor.

When an LTPS transistor is used as one or more of the transistors included in the pixel circuit and an OS transistor is used as the rest, a display apparatus with low power consumption and high driving capability can be achieved. In a more favorable example, it is preferable that an OS transistor be used as a transistor or the like functioning as a switch for controlling electrical continuity between wirings and an LTPS transistor be used as a transistor or the like for controlling current.

For example, one of the transistors provided in the pixel circuit functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In this case, the amount of current flowing through the light-emitting device can be increased in the pixel circuit.

Another transistor provided in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, power consumption can be reduced by stopping the driver in displaying a still image.

More specific structure examples are described below with reference to drawings.

### [Structure Example 2 of Display Apparatus]

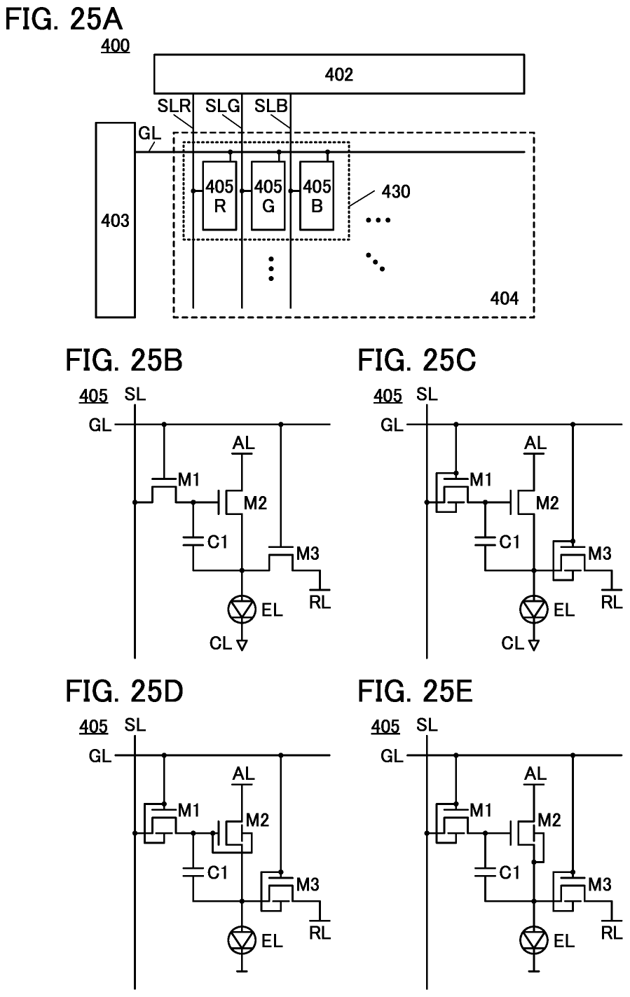

FIG. 25A illustrates a block diagram of a display apparatus 400. The display apparatus 400 includes a display portion 404, a driver circuit portion 402, a driver circuit portion 403, and the like.

The display portion 404 includes a plurality of pixels 430 arranged in a matrix. The pixels 430 each include a subpixel 405R, a subpixel 405G, and a subpixel 405B. The subpixel 405R, the subpixel 405G, and the subpixel 405B each include a light-emitting device functioning as a display device.

The pixel 430 is electrically connected to a wiring GL, a wiring SLR, a wiring SLG, and a wiring SLB. The wiring SLR, the wiring SLG, and the wiring SLB are each electrically connected to the driver circuit portion 402. The wiring GL is electrically connected to the driver circuit portion 403. The driver circuit portion 402 functions as a source line driver circuit (also referred to as a source driver), and the driver circuit portion 403 functions as a gate line driver circuit (also referred to as a gate driver). The wiring GL functions as a gate line, and the wiring SLR, the wiring SLG, and the wiring SLB each function as a source line.

The subpixel 405R includes a light-emitting device emitting red light. The subpixel 405G includes a light-emitting device emitting green light. The subpixel 405B includes a light-emitting device emitting blue light. Thus, the display apparatus 400 can perform full-color display. Note that the pixel 430 may include a subpixel including a light-emitting device emitting light of another color. For example, the pixel 430 may include, in addition to the three subpixels, a subpixel including a light-emitting device emitting white light, a subpixel including a light-emitting device emitting yellow light, or the like.

The wiring GL is electrically connected to the subpixel 405R, the subpixel 405G, and the subpixel 405B arranged in a row direction (an extending direction of the wiring GL). The wiring SLR, the wiring SLG, and the wiring SLB are electrically connected to the subpixels 405R, the subpixels 405G, and the subpixels 405B (not illustrated) arranged in a column direction (an extending direction of the wiring SLR and the like), respectively.

### [Structure Example of Pixel Circuit]

FIG. 25B illustrates an example of a circuit diagram of a pixel 405 that can be used as the subpixel 405R, the subpixel 405G, and the subpixel 405B. The pixel 405 includes a transistor M1, a transistor M2, a transistor M3, a capacitor C1, and a light-emitting device EL. The wiring GL and a wiring SL are electrically connected to the pixel 405. The wiring SL corresponds to any of the wiring SLR, the wiring SLG, and the wiring SLB illustrated in FIG. 25A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 405, the anode potential is a potential higher than the cathode potential. The reset potential supplied to the wiring RL can be a potential such that a potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 402 and a plurality of transistors included in the driver circuit portion 403, and OS transistors can be used as the other transistors. For example, OS transistors can be used as the transistors provided in the display portion 404, and LTPS transistors can be used as the transistors provided in the driver circuit portion 402 and the driver circuit portion 403.

As the OS transistor, a transistor including an oxide semiconductor in its semiconductor layer where a channel is formed can be used. The semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin. It is particularly preferable to use an oxide containing indium, gallium, and zinc for the semiconductor layer of the OS transistor. Alternatively, it is preferable to use an oxide containing indium, tin, and zinc. Further alternatively, it is preferable to use an oxide containing indium, gallium, tin, and zinc.

A transistor using an oxide semiconductor having a wider band gap and smaller carrier density than silicon can achieve an extremely low off-state current. Thus, such a low off-state current enables long-term retention of charge accumulated in a capacitor that is connected to the transistor in series. Therefore, it is particularly preferable to use a transistor including an oxide semiconductor as each of the transistor M1 and the transistor M3 each of which is connected to the capacitor C1 in series. The use of the transistor including an oxide semiconductor as each of the transistor M1 and the transistor M3 can prevent leakage of charge retained in the capacitor C1 through the transistor M1 or the transistor M3. Furthermore, since charge retained in the capacitor C1 can be retained for a long time, a still image can be displayed for a long time without rewriting data in the pixel 405.

Note that although the transistor is illustrated as an n-channel transistor in FIG. 25B, a p-channel transistor can also be used.

The transistors included in the pixel 405 are preferably formed to be arranged over the same substrate.

Transistors each including a pair of gates overlapping with each other with a semiconductor layer therebetween can be used as the transistors included in the pixel 405.

In the transistor including a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 405 illustrated in FIG. 25C is an example of a case where a transistor including a pair of gates is used as each of the transistor M1 and the transistor M3. In each of the transistor M1 and the transistor M3, the pair of gates are electrically connected to each other. Such a structure can shorten the period in which data is written to the pixel 405.

The pixel 405 illustrated in FIG. 25D is an example of a case where a transistor including a pair of gates (hereinafter referred to as a first gate and a second gate in some cases) is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and the display quality can be increased.

FIG. 25D illustrates a case where the first gate and the second gate of the transistor M2 are electrically connected to each other, but the present invention is not limited thereto. As illustrated in FIG. 25E, the first gate of the transistor M2 may be electrically connected to the other of the source and the drain of the transistor M1 and one electrode of the capacitor C1, and the second gate of the transistor M2 may be electrically connected to the other of the source and the drain of the transistor M2, one of the source and the drain of the transistor M3, the other electrode of the capacitor C1, and one electrode of the light-emitting device EL.

### [Structure Example of Transistor]

Cross-sectional structure examples of a transistor that can be used in the above display apparatus are described below.

### Structure Example 1

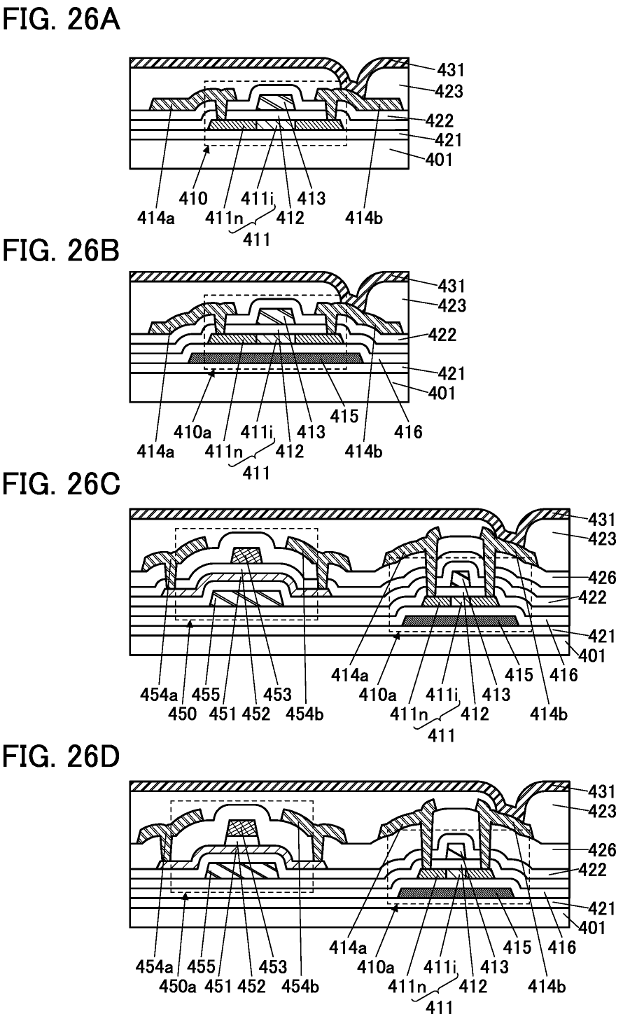

FIG. 26A is a cross-sectional view including a transistor 410.

The transistor 410 is provided over a substrate 401 and contains polycrystalline silicon in its semiconductor layer. For example, the transistor 410 corresponds to the transistor M2 in the pixel 405. In other words, FIG. 26A illustrates an example in which one of a source and a drain of the transistor 410 is electrically connected to a conductive layer 431 of the light-emitting device.

The transistor 410 includes a semiconductor layer 411, an insulating layer 412, a conductive layer 413, and the like. The semiconductor layer 411 includes a channel formation region 411i and low-resistance regions 411n. The semiconductor layer 411 contains silicon. The semiconductor layer 411 preferably contains polycrystalline silicon. Part of the insulating layer 412 functions as a gate insulating layer. Part of the conductive layer 413 functions as a gate electrode.

Note that the semiconductor layer 411 can contain a metal oxide exhibiting semiconductor characteristics (also referred to as an oxide semiconductor). In this case, the transistor 410 can be referred to as an OS transistor.

The low-resistance region 411n is a region containing an impurity element. For example, in the case where the transistor 410 is an n-channel transistor, phosphorus, arsenic, or the like is added to the low-resistance region 411n. Meanwhile, in the case where the transistor 410 is a p-channel transistor, boron, aluminum, or the like is added to the low-resistance region 411n. In addition, in order to control the threshold voltage of the transistor 410, the above-described impurity may be added to the channel formation region 411i.

An insulating layer 421 is provided over the substrate 401. The semiconductor layer 411 is provided over the insulating layer 421. The insulating layer 412 is provided to cover the semiconductor layer 411 and the insulating layer 421. The conductive layer 413 is provided at a position that is over the insulating layer 412 and overlaps with the semiconductor layer 411.

An insulating layer 422 is provided to cover the conductive layer 413 and the insulating layer 412. A conductive layer 414a and a conductive layer 414b are provided over the insulating layer 422. The conductive layer 414a and the conductive layer 414b are each electrically connected to the low-resistance region 411n in the opening portion provided in the insulating layer 422 and the insulating layer 412. Part of the conductive layer 414a functions as one of a source electrode and a drain electrode and part of the conductive layer 414b functions as the other of the source electrode and the drain electrode. An insulating layer 423 is provided to cover the conductive layer 414a, the conductive layer 414b, and the insulating layer 422.

The conductive layer 431 functioning as a pixel electrode is provided over the insulating layer 423. The conductive layer 431 is provided over the insulating layer 423 and is electrically connected to the conductive layer 414b through an opening provided in the insulating layer 423. Although not illustrated here, an EL layer and a common electrode can be stacked over the conductive layer 431.

### Structure Example 2

FIG. 26B illustrates a transistor 410a including a pair of gate electrodes. The transistor 410a illustrated in FIG. 26B is different from FIG. 26A mainly in including a conductive layer 415 and an insulating layer 416.

The conductive layer 415 is provided over the insulating layer 421. The insulating layer 416 is provided to cover the conductive layer 415 and the insulating layer 421. The semiconductor layer 411 is provided such that at least the channel formation region 411i overlaps with the conductive layer 415 with the insulating layer 416 therebetween.

In the transistor 410a illustrated in FIG. 26B, part of the conductive layer 413 functions as a first gate electrode, and part of the conductive layer 415 functions as a second gate electrode. At this time, part of the insulating layer 412 functions as a first gate insulating layer, and part of the insulating layer 416 functions as a second gate insulating layer.

Here, to electrically connect the first gate electrode to the second gate electrode, the conductive layer 413 is electrically connected to the conductive layer 415 through an opening portion provided in the insulating layer 412 and the insulating layer 416 in a region not illustrated. To electrically connect the second gate electrode to a source or a drain, the conductive layer 415 is electrically connected to the conductive layer 414a or the conductive layer 414b through an opening portion provided in the insulating layer 422, the insulating layer 412, and the insulating layer 416 in a region not illustrated.

In the case where LTPS transistors are used as all of the transistors included in the pixel 405, the transistor 410 illustrated in FIG. 26A as an example or the transistor 410a illustrated in FIG. 26B as an example can be used. In this case, the transistors 410a may be used as all of the transistors included in the pixels 405, the transistors 410 may be used as all of the transistors, or the transistors 410a and the transistors 410 may be used in combination.

### Structure Example 3

Described below is an example of a structure including both a transistor containing silicon in its semiconductor layer and a transistor containing a metal oxide in its semiconductor layer.

FIG. 26C illustrates a schematic cross-sectional view including the transistor 410a and a transistor 450.

Structure example 1 described above can be referred to for the structure of the transistor 410a. Although an example using the transistor 410a is illustrated here, a structure including the transistor 410 and the transistor 450 or a structure including all the transistor 410, the transistor 410a, and the transistor 450 may alternatively be employed.

The transistor 450 is a transistor containing a metal oxide in its semiconductor layer. The structure illustrated in FIG. 26C is an example in which the transistor 450 and the transistor 410a respectively correspond to the transistor M1 and the transistor M2, in the pixel 405, for example. That is, FIG. 26C illustrates an example in which one of a source and a drain of the transistor 410a is electrically connected to the conductive layer 431.

Moreover, FIG. 26C illustrates an example in which the transistor 450 includes a pair of gates.

The transistor 450 includes a conductive layer 455, the insulating layer 422, a semiconductor layer 451, an insulating layer 452, a conductive layer 453, and the like. Part of the conductive layer 453 functions as a first gate of the transistor 450, and part of the conductive layer 455 functions as a second gate of the transistor 450. In this case, part of the insulating layer 452 functions as a first gate insulating layer of the transistor 450, and part of the insulating layer 422 functions as a second gate insulating layer of the transistor 450.

The conductive layer 455 is provided over the insulating layer 412. The insulating layer 422 is provided to cover the conductive layer 455. The semiconductor layer 451 is provided over the insulating layer 422. The insulating layer 452 is provided to cover the semiconductor layer 451 and the insulating layer 422. The conductive layer 453 is provided over the insulating layer 452 and includes a region overlapping with the semiconductor layer 451 and the conductive layer 455.

An insulating layer 426 is provided to cover the insulating layer 452 and the conductive layer 453. A conductive layer 454a and a conductive layer 454b are provided over the insulating layer 426. The conductive layer 454a and the conductive layer 454b are electrically connected to the semiconductor layer 451 in openings provided in the insulating layer 426 and the insulating layer 452. Part of the conductive layer 454a functions as one of a source electrode and a drain electrode and part of the conductive layer 454b functions as the other of the source electrode and the drain electrode. The insulating layer 423 is provided to cover the conductive layer 454a, the conductive layer 454b, and the insulating layer 426.

Here, the conductive layer 414a and the conductive layer 414b electrically connected to the transistor 410a are preferably formed by processing the same conductive film as the conductive layer 454a and the conductive layer 454b, respectively. FIG. 26C illustrates a structure where the conductive layer 414a, the conductive layer 414b, the conductive layer 454a, and the conductive layer 454b are formed on the same plane (i.e., in contact with a top surface of the insulating layer 426) and contain the same metal element. In this case, the conductive layer 414a and the conductive layer 414b are electrically connected to the low-resistance regions 411n through openings provided in the insulating layer 426, the insulating layer 452, the insulating layer 422, and the insulating layer 412. This is preferable because the manufacturing process can be simplified.

Moreover, the conductive layer 413 functioning as the first gate electrode of the transistor 410a and the conductive layer 455 functioning as the second gate electrode of the transistor 450 are preferably formed by processing the same conductive film. FIG. 26C illustrates a structure where the conductive layer 413 and the conductive layer 455 are formed on the same plane (i.e., in contact with a top surface of the insulating layer 412) and contain the same metal element. This is preferable because the manufacturing process can be simplified.

In the structure in FIG. 26C, the insulating layer 452 functioning as the first gate insulating layer of the transistor 450 covers an end portion of the semiconductor layer 451; however, the insulating layer 452 may be processed to have the same or substantially the same top surface shape as the conductive layer 453 as in a transistor 450a illustrated in FIG. 26D.

Note that in this specification and the like, the expression “top surface shapes are substantially the same” means that at least outlines of stacked layers partly overlap with each other. For example, the case of processing the upper layer and the lower layer using the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes are substantially the same”.

Although the example in which the transistor 410a corresponds to the transistor M2 and is electrically connected to the pixel electrode is shown here, one embodiment of the present invention is not limited thereto. For example, a structure in which the transistor 450 or the transistor 450a corresponds to the transistor M2 may be employed. In that case, the transistor 410a corresponds to the transistor M1, the transistor M3, or another transistor.

This embodiment can be combined with any of the other embodiments as appropriate.

### Embodiment 7

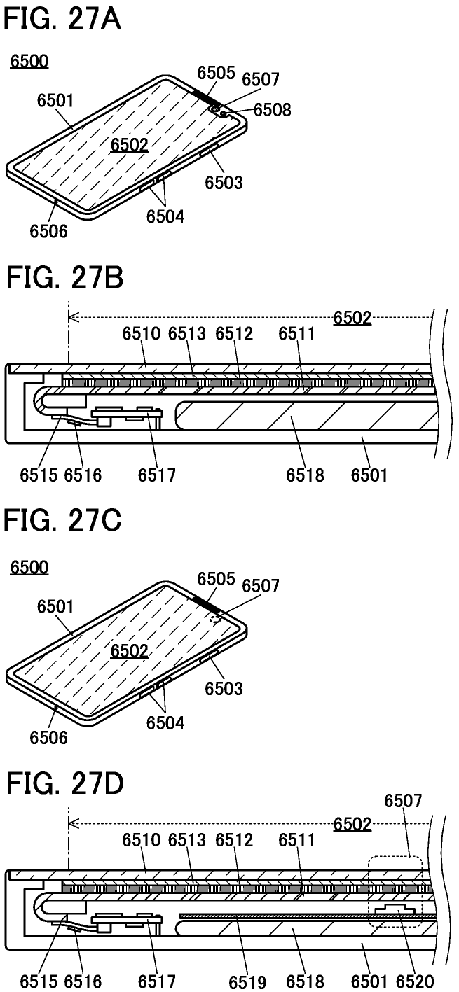

In this embodiment, electronic devices of one embodiment of the present invention are described with reference to FIG. 27 to FIG. 29.

Electronic devices of this embodiment each include the display apparatus of one embodiment of the present invention in a display portion. The display apparatus of one embodiment of the present invention can be easily increased in resolution and definition and can achieve high display quality. Thus, the display apparatus of one embodiment of the present invention can be used for a display portion of a variety of electronic devices. As described in the above embodiment, the display apparatus of one embodiment of the present invention can have a high aperture ratio and can be provided with a touch sensor.

Examples of the electronic devices include electronic devices with a relatively large screen, such as a television device, a desktop or laptop personal computer, a monitor of a computer or the like, digital signage, and a large game machine such as a pachinko machine; a digital camera; a digital video camera; a digital photo frame; a mobile phone; a portable game machine; a portable information terminal; and an audio reproducing device.

In particular, the display apparatus of one embodiment of the present invention can have high resolution, and thus can be suitably used for an electronic device having a relatively small display portion. Examples of such an electronic device include a watch-type or a bracelet-type information terminal (wearable device), and a wearable device that can be worn on a head, such as a device for VR like a head-mounted display, a glasses-type device for AR, and a device for MR (Mixed Reality).

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 27A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 27B is a schematic cross-sectional view including an end portion of the housing 6501 on the microphone 6506 side.

A protection member 6510 having a light-transmitting property is provided on a display surface side of the housing 6501, and a display apparatus 6511, an optical member 6512, a touch sensor panel 6513, a printed circuit board 6517, a battery 6518, and the like are provided in a space surrounded by the housing 6501 and the protection member 6510. In the case where a touch sensor is included in the display portion 6502 as described in the above embodiments, the touch sensor panel 6513 can be omitted.

The display apparatus 6511, the optical member 6512, and the touch sensor panel 6513 are fixed to the protection member 6510 with an adhesive layer (not illustrated).

Part of the display apparatus 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display apparatus 6511. Thus, an extremely lightweight electronic device can be achieved. Since the display apparatus 6511 is extremely thin, the battery 6518 with high capacity can be mounted while an increase in the thickness of the electronic device is suppressed. Moreover, part of the display apparatus 6511 is folded back so that a connection portion with the FPC 6515 is provided on the back side of a pixel portion, whereby an electronic device with a narrow bezel can be achieved.

In the electronic device 6500 illustrated in FIG. 27A and FIG. 27B, the camera 6507 is provided in a notch provided in the display portion 6502, but the present invention is not limited thereto. As illustrated in FIG. 27C and FIG. 27D, the camera 6507 may be provided to overlap with the display portion 6502. Note that FIG. 27C corresponds to FIG. 27A, FIG. 27D corresponds to FIG. 27B, and the description of FIG. 27A and FIG. 27B can be referred to for the structures of FIG. 27C and FIG. 27D with the same reference numerals.

As illustrated in FIG. 27D, a housing 6519 may be provided over the battery 6518, and a sensor portion 6520 included in the camera 6507 may be provided over the housing 6519. As the sensor portion 6520, a package including an image sensor chip or a sensor module can be used, for example. The specific structure of the sensor portion 6520 can be referred to for an embodiment described later. By providing the camera 6507, the user can take an image data in a state where the user sees on the display portion 6502. In addition, personal authentication can be performed by taking an image of the face of the user.

Here, the display apparatus illustrated in FIG. 5A or FIG. 5B is preferably used for the display portion 6502. As described above, the display apparatus illustrated in FIG. 5A or FIG. 5B can suppress reflection of external light without using an optical member such as a circularly polarizing plate. Thus, a structure can be employed where at least part of the optical member 6512 (e.g., a circularly polarizing plate) is omitted in the electronic device 6500. With such a structure, light entering the sensor portion 6520 can be prevented from being attenuated by the circularly polarizing plate or the like. Thus, even when the sensor portion 6520 is provided below the display portion 6502, sufficient sensing can be performed.

Moreover, a structure may be employed where the number of pixels in a region overlapping with the sensor portion 6520 in the display portion 6502 is reduced. Such a structure can increase the intensity of light entering the sensor portion 6520 and improve the sensitivity of sensing.

The sensor portion 6520 is preferably provided to be fixed to the housing 6519. In this case, the position of the light-receiving portion of the sensor portion 6520 is fixed, enabling more accurate sensing. Note that the housing 6519 may be fixed to the housing 6501, or the housing 6519 may be unified with the housing 6501.

With the structure illustrated in FIG. 27C and FIG. 27D, the camera 6507 can be provided in the electronic device 6500, without providing a notch on the display portion 6502.

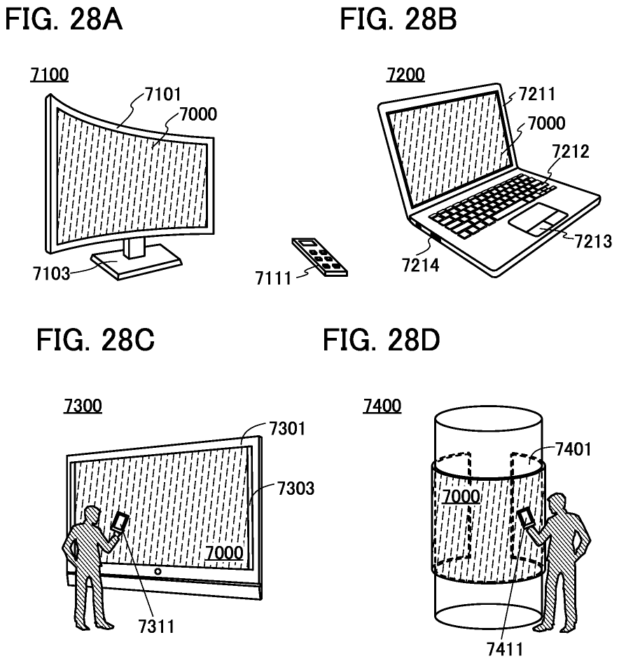

FIG. 28A illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 28A can be performed with an operation switch provided in the housing 7101 and a separate remote control 7111. Alternatively, the display portion 7000 may be provided with a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 28B illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 28C and FIG. 28D illustrate examples of digital signage.

Digital signage 7300 illustrated in FIG. 28C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 28D is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in FIG. 28C and FIG. 28D.

A larger area of the display portion 7000 can increase the amount of information that can be provided at a time. The larger display portion 7000 attracts more attention, so that the effectiveness of the advertisement can be increased, for example.

The use of a touch panel for the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 28C and FIG. 28D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

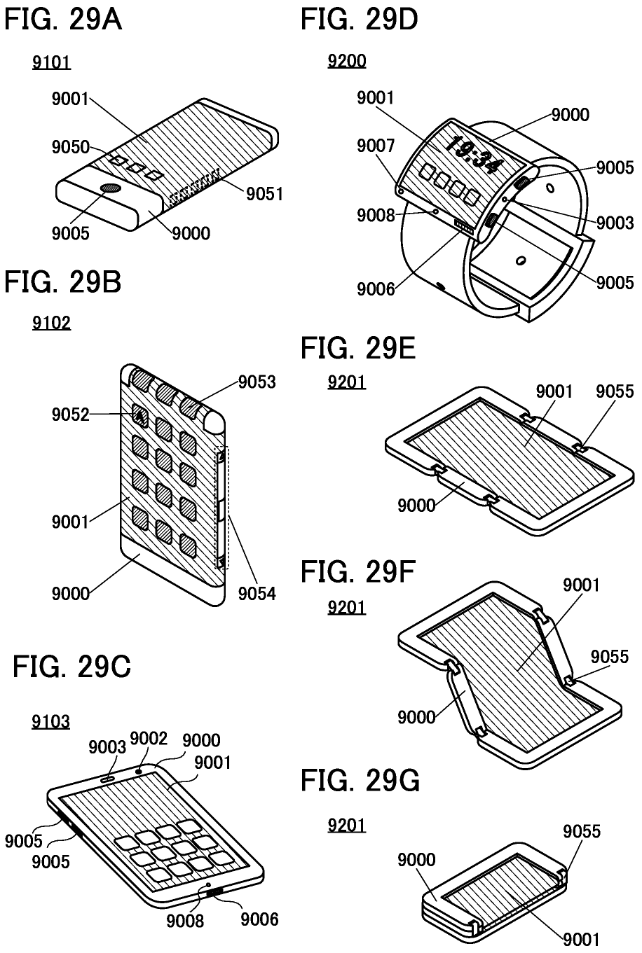

Electronic devices illustrated in FIG. 29A to FIG. 29G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays), a microphone 9008, and the like.

The display apparatus of one embodiment of the present invention can be used for the display portion 9001 in FIG. 29A to FIG. 29G.

The electronic devices illustrated in FIG. 29A to FIG. 29G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 29A to FIG. 29G are described below.

FIG. 29A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 29A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 29B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 29C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on a bottom surface of the housing 9000.

FIG. 29D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 29E to FIG. 29G are perspective views each illustrating a foldable portable information terminal 9201. FIG. 29E is a perspective view of an opened state of the portable information terminal 9201, FIG. 29G is a perspective view of a folded state thereof, and FIG. 29F is a perspective view of a state in the middle of change from one of FIG. 29E and FIG. 29G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

The display portion 9001 may include the display apparatus illustrated in FIG. 5A or FIG. 5B. Thus, the portable information terminal 9201 can be manufactured without providing an optical member such as a circularly polarizing plate on the display portion 9001. The curvature radius can be reduced by employing a structure without providing a circularly polarizing plate with a relatively large thickness for the display portion 9001.

This embodiment can be combined with the other embodiments as appropriate.

### Embodiment 8

In this embodiment, examples of a package and a sensor module each including an image sensor chip are described. The package and the sensor module each including an image sensor chip can be used for the sensor portion 6520 or the like illustrated in FIG. 27D.

Here, the image sensor chip includes a pixel portion in which a plurality of light-receiving elements are arranged in a matrix, a driver circuit controlling the pixel portion, and the like. A photodiode in which a photoelectric conversion layer is formed in a silicon substrate can be used as the light-receiving element.

Note that the photodiode can also be formed using a compound semiconductor. The use of the compound semiconductor, which can change the bandgap depending on the combination of constituent elements and the atomic ratio of the elements, enables formation of a photodiode having sensitivity to infrared light. For example, to form a photodiode having sensitivity to light from visible light to mid-infrared light, InGaAs or the like may be used for the photoelectric conversion layer.

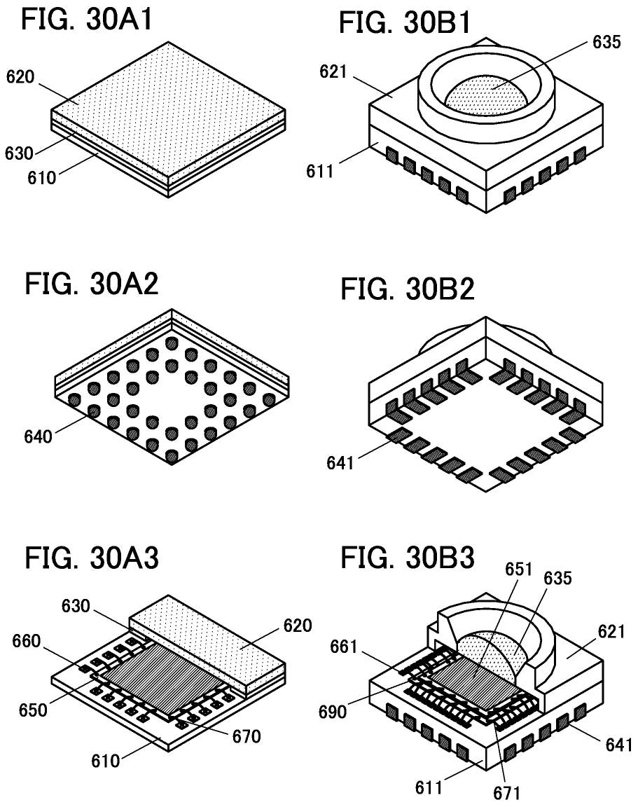

FIG. 30A1 is an external perspective view of the top surface side of a package in which an image sensor chip is placed. The package includes a package substrate 610 to which an image sensor chip 650 is fixed, a cover glass 620, an adhesive 630 for bonding them, and the like.

FIG. 30A2 is an external perspective view of the bottom surface side of the package. A BGA (Ball grid array) in which solder balls are used as bumps 640 on the bottom surface of the package is employed. Note that, other than the BGA, an LGA (Land grid array), a PGA (Pin Grid Array), or the like may be employed.

FIG. 30A3 is a perspective view of the package, in which parts of the cover glass 620 and the adhesive 630 are not illustrated. Electrode pads 660 are formed over the package substrate 610, and the electrode pads 660 and the bumps 640 are electrically connected to each other via through-holes. The electrode pads 660 are electrically connected to the image sensor chip 650 through wires 670.

FIG. 30B1 is an external perspective view of the top surface side of a sensor module including an image sensor chip in a package with a built-in lens. The sensor module includes a package substrate 611 to which an image sensor chip 651 is fixed, a lens cover 621, a lens 635, and the like. Furthermore, an IC chip 690 having functions of a driver circuit, a signal conversion circuit, and the like of the light-receiving element is provided between the package substrate 611 and the image sensor chip 651; thus, the structure as an SiP (System in package) is included.

FIG. 30B2 is an external perspective view of the bottom surface side of the sensor module. A QFN (Quad flat no-lead package) structure where lands 641 for mounting are provided on the bottom surface and side surfaces of the package substrate 611 is employed. Note that this structure is only an example, and a QFP (Quad flat package) or the above-mentioned BGA may also be provided.

FIG. 30B3 is a perspective view of the module, in which parts of the lens cover 621 and the lens 635 are not illustrated. The lands 641 are electrically connected to electrode pads 661, and the electrode pads 661 are electrically connected to the image sensor chip 651 or the IC chip 690 through wires 671.

The image sensor chip placed in a package having the above form can be easily mounted on a printed circuit board and the like; therefore, the image sensor chip can be incorporated into a variety of semiconductor devices and electronic devices.

Furthermore, noise may be generated in the output of the image sensor chip by interference of incident light. In this case, it is preferable to perform image processing on the output of the image sensor chip to reduce a noise. The image processing can be performed with the use of AI, for example.

This embodiment can be combined with the description of the other embodiments as appropriate.

### REFERENCE NUMERALS

AL: wiring, CL: wiring, Cp: capacitance, GL: wiring, RL: wiring, Sa: notch, Sb: notch, SL: wiring, SLB: wiring, SLG: wiring, SLR: wiring, Sx: notch, Sy: notch, 100G: display apparatus, 100: display apparatus, 101: substrate, 102: substrate, 103: insulating layer, 104t: conductive layer, 104X: conductive layer, 104Y: conductive layer, 104: conductive layer, 105: insulating layer, 106t: conductive layer, 106: conductive layer, 107: adhesive layer, 108: light-blocking layer, 110a: subpixel, 110b: subpixel, 110c: subpixel, 110d: subpixel, 110: pixel, 111a: pixel electrode, 111b: pixel electrode, 111c: pixel electrode, 112a: conductive layer, 112b: conductive layer, 112c: conductive layer, 113a: first layer, 113a1: first light-emitting unit, 113a2: charge-generation layer, 113a3: second light-emitting unit, 113b: second layer, 113b1: first light-emitting unit, 113b2: charge-generation layer, 113b3: second light-emitting unit, 113c: third layer, 113c1: first light-emitting unit, 113c2: charge-generation layer, 113c3: second light-emitting unit, 114: common layer, 115: common electrode, 118a: mask layer, 118b: mask layer, 118c: mask layer, 118: mask layer, 120: substrate, 121: insulating layer, 122: adhesive layer, 123: conductive layer, 124a: pixel, 124b: pixel, 125: insulating layer, 126a: conductive layer, 126b: conductive layer, 126c: conductive layer, 127: insulating layer, 128: layer, 129a: conductive layer, 129b: conductive layer, 129c: conductive layer, 130a: light-emitting device, 130B: light-emitting device, 130b: light-emitting device, 130c: light-emitting device, 130G: light-emitting device, 130R: light-emitting device, 130: light-emitting device, 131: protective layer, 132a: coloring layer, 132b: coloring layer, 132c: coloring layer, 132: coloring layer, 135: gap, 139: region, 140: connection portion, 145: adhesive layer, 146: substrate, 147: resin layer, 148: resin layer, 149: resin layer, 151: substrate, 152: substrate, 162: display portion, 164: circuit, 165: wiring, 166: conductive layer, 167: conductive layer, 172: FPC, 173: IC, 175: FPC, 201: transistor, 204: connection portion, 205: transistor, 206: connection portion, 207: connection portion, 208: connection portion, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 242: connection layer, 247: connection layer, 248: conductive particle, 255a: insulating layer, 255b: insulating layer, 255c: insulating layer, 400: display apparatus, 401: substrate, 402: driver circuit portion, 403: driver circuit portion, 404: display portion, 405B: subpixel, 405G: subpixel, 405R: subpixel, 405: pixel, 410a: transistor, 410: transistor, 411i: channel formation region, 411n: low-resistance region, 411: semiconductor layer, 412: insulating layer, 413: conductive layer, 414a: conductive layer, 414b: conductive layer, 415: conductive layer, 416: insulating layer, 421: insulating layer, 422: insulating layer, 423: insulating layer, 426: insulating layer, 430: pixel, 431: conductive layer, 450a: transistor, 450: transistor, 451: semiconductor layer, 452: insulating layer, 453: conductive layer, 454a: conductive layer, 454b: conductive layer, 455: conductive layer, 500: display apparatus, 501: electrode, 502: electrode, 512B_1: light-emitting unit, 512B_2: light-emitting unit, 512B_3: light-emitting unit, 512G_1: light-emitting unit, 512G_2: light-emitting unit, 512G_3: light-emitting unit, 512R_1: light-emitting unit, 512R_2: light-emitting unit, 512R_3: light-emitting unit, 521: layer, 522: layer, 523B: light-emitting layer, 523G: light-emitting layer, 523R: light-emitting layer, 524: layer, 525: layer, 531: charge-generation layer, 550B: light-emitting device, 550G: light-emitting device, 550R: light-emitting device, 610: package substrate, 611: package substrate, 620: cover glass, 621: lens cover, 630: adhesive, 635: lens, 640: bump, 641: land, 650: image sensor chip, 651: image sensor chip, 660: electrode pad, 661: electrode pad, 670: wire, 671: wire, 690: IC chip, 6500: electronic device, 6501: housing, 6502: display portion, 6503: power source button, 6504: button, 6505: speaker, 6506: microphone, 6507: camera, 6508: light source, 6510: protection member, 6511: display apparatus, 6512: optical member, 6513: touch sensor panel, 6515: FPC, 6516: IC, 6517: printed circuit board, 6518: battery, 6519: housing, 6520: sensor portion, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting device comprising a first pixel electrode, a first EL layer over the first pixel electrode, and a common electrode over the first EL layer;
a second light-emitting device comprising a second pixel electrode, a second EL layer over the second pixel electrode, and the common electrode over the second EL layer;
a first conductive layer over the common electrode;
first insulating layer over the first conductive layer; and
a second conductive layer over the first insulating layer;
wherein the first light-emitting device and the second light-emitting device are adjacent to each other,
wherein any one or both of the first conductive layer and the second conductive layer overlap a region interposed between the first EL layer and the second EL layer,
wherein one side surface of the first EL layer and one side surface of the second EL layer face each other,
wherein the first light-emitting device and the second light-emitting device are configured to emit light with different colors from each other,
wherein the first EL layer comprises:
a first light-emitting unit over the first pixel electrode;
a first charge-generation layer over the first light-emitting unit; and
a second light-emitting unit over the first charge-generation layer, and
wherein the second EL layer comprises:
a third light-emitting unit over the second pixel electrode;
a second charge-generation layer over the third light-emitting unit; and
a fourth light-emitting unit over the second charge-generation layer.

2. The display apparatus according to claim 1, further comprising a second insulating layer and a third insulating layer over the second insulating layer,
wherein the second insulating layer comprises an inorganic material,
wherein the third insulating layer comprises an organic material,
wherein each of a part of the second insulating layer and a part of the third insulating layer is interposed between an end portion of a side surface of the first EL layer and an end portion of a side surface of the second EL layer, and
wherein another part of the third insulating layer and each of a part of a top surface of the first EL layer and a part of a top surface of the second EL layer overlap each other with the second insulating layer therebetween.

3. The display apparatus according to claim 2, wherein the third insulating layer and any one or both of the first conductive layer and the second conductive layer overlap each other.

4. The display apparatus according to claim 2, wherein each of a side surface of the first conductive layer and a side surface of the second conductive layer is inside an end portion of the third insulating layer in a cross-sectional view.

5. The display apparatus according to claim 2, wherein the common electrode is over the third insulating layer.

6. The display apparatus according to claim 1, further comprising a first substrate and a second substrate,
wherein each of the first light-emitting device and the second light-emitting device is over the first substrate, and
wherein the second substrate is bonded to a plane of the first substrate where the first insulating layer and the second conductive layer are provided with an adhesive layer therebetween.

7. The display apparatus according to claim 1,
wherein the first light-emitting device comprises a common layer between the first EL layer and the common electrode, and
wherein the second light-emitting device comprises the common layer between the second EL layer and the common electrode.

8. The display apparatus according to claim 1, wherein a distance between the first pixel electrode and the second pixel electrode is less than or equal to 8 μm.

9. The display apparatus according to claim 1, further comprising a first coloring layer and a second coloring layer,
wherein the first coloring layer and the first light-emitting device overlap each other,
wherein the second coloring layer and the second light-emitting device overlap each other,
wherein the first coloring layer is configured to transmit light in at least a part of a wavelength range emitted from the first light-emitting device, and
wherein the second coloring layer is configured to transmit light in at least a part of a wavelength range emitted from the second light-emitting device.

10. The display apparatus according to claim 9, wherein each of the first coloring layer and the second coloring layer is between the common electrode and the first insulating layer.
